(19) United States
(12) Patent Application Publication
(10) Pub. No.: US 2003/0129117 A1
(43) Pub. Date: Jul. 10, 2003

(54) Synthesis and characterization of a highly stable amorphous silicon hydride as the product of a catalytic hydrogen plasma reaction

(76) Inventor: Randell L. Mills, Cranbury, NJ (US)

Correspondence Address: MANELLI DENISON & SELTER, 2000 M STREET NW SUITE 700, WASHINGTON, DC, 20036-3307, US

(21) Appl. No.: 10/331,725

(22) Filed: Dec. 31, 2002

Related U.S. Application Data
(60) Provisional application No. 60/343,585, filed on Jan. 2, 2002.

(51) Int. Cl. C23C 16/00; C01B 33/04

(52) U.S. Cl. 423/347; 427/569; 427/255.28

(57) ABSTRACT

This invention relates to a highly stable silicon hydride (SiH(1/p)) surface coating formed from high binding energy hydride ions. SiH(1/p) may be synthesized in a cell for the catalysis of atomic hydrogen to form novel hydrogen species and/or compositions of matter containing new forms of hydrogen. The reaction may be maintained by a microwave plasma of a source of atomic hydrogen, a source of catalyst, and a source of silicon.

This application claims priority to U.S. Ser. No. 60/343,585, the complete disclosure of which is incorporated herein by reference.

### I. INTRODUCTION

The invention relates to synthesis of a crystalline or amorphous silicon hydride and the crystalline or amorphous silicon hydride.

### II. BACKGROUND OF THE INVENTION

It was reported previously that a chemically generated or assisted plasma source has been developed [1-68, numbers in brackets refer to reference numbers in the Reference list disclosed herein below]. One such source operates by incandescently heating a hydrogen dissociator to provide atomic hydrogen and heats a catalyst such that it becomes gaseous and reacts with the atomic hydrogen to produce a plasma called a resonant transfer or rt-plasma. It was extraordinary, that intense EUV emission was observed [reference numbers 13, 15, 18-19, 23-24, 27, 30, 37, 42, 45, 49, 53-54, 56-58] at low temperatures (e.g. ≈10³ K) and an extraordinary low field strength of about 1-2 V/cm from atomic hydrogen and certain atomized elements or certain gaseous ions which singly. or multiply ionize at integer multiples of the potential energy of atomic hydrogen, 27.2 eV. This is two orders of magnitude lower than the starting voltages measured for gas glow discharges [69-70]. A number of independent experimental observations confirm a novel reaction of atomic hydrogen which produces hydrogen in fractional quantum states that are at lower energies than the traditional “ground” (n=1) state, a chemically generated or assisted plasma (rt-plasma), and produces novel hydride compounds. These include extreme ultraviolet (EUV) spectroscopy [2-5, 7, 11, 13, 15-16, 18-20, 23-24, 26-27, 33-38, 40-42, 45, 49, 53-55, 57-58], characteristic emission from catalysis and the hydride ion products [4-5, 11, 13, 15, 18-19, 27, 30-31, 37, 42, 45, 53], lower-energy hydrogen emission [3, 7, 20, 33-36, 40-41], plasma formation [13, 15, 18-19, 23-24, 27, 30, 37, 42, 45, 49, 53-54, 56-58], Balmer α line broadening [1-7, 11, 13, 15-16, 18-19, 21, 24, 26-27, 30, 32-36, 39, 49, 53], population inversion of hydrogen lines [2, 4-5, 11, 13, 15-16, 19, 24, 30], elevated electron temperature [3, 6, 7, 21, 26, 32-35], anomalous plasma afterglow duration [23, 56-57], power generation [2, 7, 26, 30, 34-36, 38-39, 44, 46, 58, 65-67], and analysis of chemical compounds [1, 6, 8-10, 25, 28, 31, 44, 50, 59-63]. The reaction has applications as a new light source, a new field of hydrogen chemistry, and a new source of energy with direct plasma to electric power conversion possible [2, 14, 22, 29].

The theory given previously [12, 17, 47, 48, 52, 64, 68] is based on applying Maxwell's equations to the Schrödinger equation. The familiar Rydberg equation (Eq. (1)) arises for the hydrogen excited states for n>1 in Eq. (2).

$${E}_{n} = - \frac{{e}^{2}}{{n}^{2} 8 {πϵ}_{0} {a}_{H}} = - \frac{13.598 eV}{{n}^{2}} \qquad ( 1 )$$

n=1, 2, 3, . . . (2)

An additional result is that atomic hydrogen may undergo a catalytic reaction with certain atoms and ions which singly or multiply ionize at integer multiples of the potential energy of atomic hydrogen, m·27.2 eV wherein m is an integer. The reaction involves a nonradiative energy transfer to form a hydrogen atom that is lower in energy than unreacted atomic hydrogen that corresponds to a fractional principal quantum number. That is

$$n = \frac{1}{2} , \frac{1}{3} , \frac{1}{ 4} , . . . , \frac{1}{p} ; p is an integer \qquad ( 3 )$$

replaces the well known parameter n=integer in the Rydberg equation for hydrogen excited states. The n=1 state of hydrogen and the

$$n = \frac{1}{integer}$$

states of hydrogen are nonradiative, but a transition between two nonradiative states is possible via a nonradiative energy transfer, say n=1 to n=½. Thus, a catalyst provides a net positive enthalpy of reaction of m·27.2 eV (i.e. it resonantly accepts the nonradiative energy transfer from hydrogen atoms and releases the energy to the surroundings to affect electronic transitions to fractional quantum energy levels). As a consequence of the nonradiative energy transfer, the hydrogen atom becomes unstable and emits further energy until it achieves a lower-energy nonradiative state having a principal energy level given by Eqs. (1) and (3). Processes such as hydrogen molecular bond formation that occur without photons and that require collisions are common [71]. Also, some commercial phosphors are based on resonant nonradiative energy transfer involving multipole coupling [72].

The catalyst products H(1/p) were predicted to be a highly reactive intermediates which further react to form a novel hydride ions H⁻(1/p) with predicted binding energies E_{B} given by the following formula [27, 37, 42, 59, 68]:

$${E}_{B} = \frac{{\overline{h}}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {\overline{h}}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} ) \qquad ( 4 )$$

where p is an integer greater than one, s=½, [symbol] is Planck's constant bar, μₒ is the permeability of vacuum, mₑ is the mass of the electron, μₑ is the reduced electron mass given by

$${μ}_{e} = \frac{{m}_{e} {m}_{p}}{\frac{{m}_{e}}{\sqrt{\frac{3}{4}}} + {m}_{p}}$$

where mₚ is the mass of the proton, a_{H} is the radius of the hydrogen atom, aₒ is the Bohr radius, and e is the elementary charge. The ionic radius is

$${r}_{1} = \frac{{a}_{0}}{p} ( 1 + \sqrt{s ( s + 1 )} ) s = \frac{1}{2} \qquad ( 5 )$$

Rb⁺ to Rb²⁺ and 2K⁺ to K+K²⁺ each fulfill the catalyst criterion—a chemical or physical process with an enthalpy change equal to an integer multiple of to the potential energy of atomic hydrogen, 27.2 eV. Mills et al. have reported an energetic catalytic reaction involving a resonant energy transfer between hydrogen atoms and Rb⁺ or 2K⁺ to form an rt-plasma with a very stable novel hydride ion product [13, 27, 37, 42]. Its predicted binding energy of 3.0468 eV with the fine structure was observed at 407.1 nm, and its predicted bound-free hyperfine structure lines E_{HF}=j²3.00213×10⁻⁵+3.0563 eV (j is an integer) matched those observed for j=1 to j=38 to within a 1 part per 10⁵. Hydride ions with high binding energies and upfield shifted peaks have been observed by XPS and by solid state magic-angle spinning proton nuclear magnetic resonance (¹H MAS NMR), respectively [8, 25, 28, 31, 50, 59-63].

He⁺ serves as a catalyst since the second ionization energy of helium is 54.417 eV, which is equivalent to 2·27.2 eV. In this case, 54.417 eV is transferred nonradiatively from atomic hydrogen to He⁺ which is resonantly ionized. The electron decays to the n=⅓ state with the further release of 54.417 eV which may be emitted as a photon. Since the products of the catalysis reaction have binding energies of m·27.2 eV, they may further serve as catalysts. Thus, further catalytic transitions may occur:

$$n = \frac{1}{3} -> \frac{1}{4} , \frac{1}{4} -> \frac{1}{5} ,$$

and so on which may further react to form novel hydrides. Extremely stable hydride ions may stabilize a silicon surface to unprecedented time scales to increase the yield in integrated chip fabrication.

Aqueous HF acid etching of silicon surfaces results in the removal of the surface oxide and produces hydrogen terminated silicon surfaces, Si—H. HF etching is a key step in producing silicon surfaces which are contamination-free and chemically stable for subsequent processing in the semiconductor industry [73-75]. In fact, chemical oxidation and subsequent HF treatment of Si surfaces are used prior to gate oxidation, where surface contamination (<10 ppm level) and interface control are crucial to device performance. Fluorine termination was initially considered the basis of the chemical stability of HF-treated surfaces. Subsequently, it was found that fluorine is a minor species on the surface and that the remarkable surface passivation achieved by HF is explained by H termination of silicon dangling bonds protecting the surface from chemical attack [75-77]. However, the replacement of the oxide layer with the H termination of the silicon dangling bonds by HF can be attributed to the increased electronegativity of fluoride ion versus oxide causing an enhanced reactivity of H⁺ which attacks the oxide layer. The electron affinity of halogens increases from the bottom of the Group VII elements to the top. Hydride ion may be considered a halide since it possess the same electronic structure. And, according to the binding energy trend, it should have a high binding energy. However, the binding energy is only 0.75 eV which is much lower than the 3.4 eV binding energy of a fluoride ion. And, once the HF is rinsed from the surface, the Si—H layer undergoes rapid oxidation when exposed to oxygen or solvents containing oxygen. An Si—H layer with enhanced stability would be of great value to the semiconductor industry.

Amorphous Si—H films, the active component of important semiconductor devices such as photovoltaics, optoelectronics, liquid crystal displays, and field-effect transistors are formed by plasma enhanced chemical vapor deposition (PECVD) techniques [78]. Typically the film is grown on a silicon wafer substrate exposed to a plasma of silane, hydrogen, and often argon using a reactor with a diode configuration in which the plasma is confined between two parallel electrodes. These films are air sensitive. An alternative approach to achieve oxidation resistant Si—H is by the synthesize of a novel amorphous silicon hydride surface coating designated α-SiH(1/p) using a catalytic plasma reaction. For example, silane is reacted in a helium-hydrogen microwave discharge plasma at the surface of a substrate such as a nickel foil. The novel α-SiH(1/p) comprises high-binding-energy hydride ions which provide extreme stability to air. The novel α-SiH(1/p) film may advance semiconductor fabrication and devices.

1. Hydrinos

A hydrogen atom having a binding energy given by

$$Binding Energy = \frac{13.6 eV}{{( \frac{1}{p} )}^{2}} \qquad ( 6 )$$

where p is an integer greater than 1, preferably from 2 to 200, is disclosed in R. Mills, The Grand Unified Theory of Classical Quantum Mechanics, January 2000 Edition, BlackLight Power, Inc., Cranbury, N.J., Distributed by Amazon.com (“′00 Mills GUT”), provided by BlackLight Power, Inc., 493 Old Trenton Road, Cranbury, N.J., 08512; R. Mills, The Grand Unified Theory of Classical Quantum Mechanics, September 2001 Edition, BlackLight Power, Inc., Cranbury, N.J., Distributed by Amazon.com (“'01 Mills GUT”), provided by BlackLight Power, Inc., 493 Old Trenton Road, Cranbury, N.J., 08512 (posted at www.blacklightpower.com; R. Mills, The Grand Unified Theory of Classical Quantum Mechanics, September 2002 Edition, BlackLight Power, Inc., Cranbury N.J., (“′02 Mills GUT”), provided by BlackLight Power, Inc., 493 Old Trenton Road, Cranbury, N.J., 08512, posted at www.blacklightpower.com; A. J. Marchese, P. M. Jansson, J. L. Schmalzel, “The BlackLight Rocket Engine”, Phase I Final Report, NASA Institute for Advanced Concepts Phase I, May 1-Nov. 30, 2002, http://www.niac.usra.edu/files/studies/final_report/pdf/752Marchese.pdf; R. Mills, J. He, B. Dhandapani, P. Ray, “Comparison of Catalysts and Microwave Plasma Sources of Vibrational Spectral Emission of Fractional-Rydberg-State Hydrogen Molecular Ion”, Canadian Journal of Physics, submitted; R. L. Mills, P. Ray, J. Dong, M. Nansteel, B. Dhandapani, J. He, “Vibrational Spectral Emission of Fractional-Principal-Quantum-Energy-Level Molecular Hydrogen”, Bulletin of the Chemical Society of Japan, submitted; J. Phillips, R. L. Mills, X. Chen, “Water Bath Calorimetric Study of Excess Heat in ‘Resonance Transfer’ Plasmas”, Journal of Applied Physics, submitted; R. L. Mills, P. Ray, B. Dhandapani, X. Chen, “Comparison of Catalysts and Microwave Plasma Sources of Spectral Emission of Fractional-Principal-Quantum-Energy-Level Atomic and Molecular Hydrogen”, Journal of Applied Spectroscopy, submitted; R. Mills, J. He, A. Echezuria, B Dhandapani, P. Ray, “Comparison of Catalysts and Microwave Plasma Sources of Vibrational Spectral Emission of Fractional-Rydberg-State Hydrogen Molecular Ion”, Vibrational Spectroscopy, submitted; R. L. Mills, P. Ray, B. Dhandapani, J. He, “Novel Liquid-Nitrogen-Condensable Molecular Hydrogen Gas”, Chemical Engineering Science, submitted; R. L. Mills, P. C. Ray, R. M. Mayo, M. Nansteel, B. Dhandapani, J. Phillips, “Spectroscopic Study of Unique Line Broadening and Inversion in Low Pressure Microwave Generated Water Plasmas”, Physics of Plasmas, submitted; R. L. Mills, P. Ray, B. Dhandapani, J. He, “Energetic Helium-Hydrogen Plasma Reaction”, AIAA Journal, submitted; R. L. Mills, M. Nansteel, P. C. Ray, “Bright Hydrogen-Light and Power Source due to a Resonant Energy Transfer with Strontium and Argon Ions”, Vacuum, submitted; R. L. Mills, P. Ray, B. Dhandapani, J. Dong, X. Chen, “Power Source Based on Helium-Plasma Catalysis of Atomic Hydrogen to Fractional Rydberg States”, J. Mol. Struct., submitted; R. Mills, J. He, A. Echezuria, B Dhandapani, P. Ray, “Comparison of Catalysts and Plasma Sources of Vibrational Spectral Emission of Fractional-Rydberg-State Hydrogen Molecular Ion”, Vibrational Spectroscopy, submitted; R. L. Mills, J. Sankar, A. Voigt, J. He, B. Dhandapani, “Spectroscopic Characterization of the Atomic Hydrogen Energies and Densities and Carbon Species During Helium-Hydrogen-Methane Plasma CVD Synthesis of Diamond Films”, Chemistry of Materials, in press; R. Mills, P. Ray, R. M. Mayo, “Stationary Inverted Balmer and Lyman Populations for a CW HI Water-Plasma Laser”, IEEE Transactions on Plasma Science, submitted; R. L. Mills, P. Ray, B. Dhandapani, J. He, “Extreme Ultraviolet Spectroscopy of Helium-Hydrogen Plasma”, IEEE Transactions on Plasma Science, submitted; R. L. Mills, P. Ray, “Spectroscopic Evidence for a Water-Plasma Laser”, Europhysics Letters, submitted; R. Mills, P. Ray, R. M. Mayo, “Spectroscopic Evidence for CW H I Lasing in a Water-Plasma”, J. of Applied Physics, submitted; R. L. Mills, J. Sankar, A. Voigt, J. He, B. Dhandapani, “Low Power MPCVD of Diamond Films on Silicon Substrates”, J of Materials Chemistry, submitted; R. L. Mills, X. Chen, P. Ray, J. He, B. Dhandapani, “Plasma Power Source Based on a Catalytic Reaction of Atomic Hydrogen Measured by Water Bath Calorimetry”, Thermochimica Acta, submitted; R. L. Mills, A. Voigt, B. Dhandapani, J. He, “Synthesis and Spectroscopic Identification of Lithium Chloro Hydride”, Materials Characterization, submitted; R. L. Mills, B. Dhandapani, J. He, “Highly Stable Amorphous Silicon Hydride”, Solar Energy Materials & Solar Cells, submitted; R. L. Mills, J. Sankar, A. Voigt, J. He, B. Dhandapani, “Synthesis of HDLC Films from Solid Carbon”, Thin Solid Films, submitted; R. Mills, P. Ray, R. M. Mayo, “The Potential for a Hydrogen Water-Plasma Laser”, Applied Physics Letters, submitted; R. L. Mills, “Classical Quantum Mechanics”, Physics Essays, submitted; R. L. Mills, P. Ray, “Spectroscopic Characterization of Stationary Inverted Lyman Populations and Free-Free and Bound-Free Emission of Lower-Energy State Hydride Ion Formed by a Catalytic Reaction of Atomic Hydrogen and Certain Group I Catalysts, Spectrochimica Acta Part A: Molecular and Bimolecular Spectroscopy, submitted; R. M. Mayo, R. Mills, “Direct Plasmadynamic Conversion of Plasma Thermal Power to Electricity for Microdistributed Power Applications”, 40th Annual Power Sources Conference, Cherry Hill, N.J., Jun. 10-13, (2002), pp. 1-4; R. Mills, P. Ray, R. M. Mayo, “Chemically-Generated Stationary Inverted Lyman Population for a CW HI Laser”, J Vac. Sci. and Tech. A, submitted; R. L. Mills, P. Ray, “Stationary Inverted Lyman Population Formed from Incandescently Heated Hydrogen Gas with Certain Catalysts”, J. Phys. D, Applied Physics, submitted; R. Mills, “A Maxwellian Approach to Quantum Mechanics Explains the Nature of Free Electrons in Superfluid Helium”, Foundations of Science, submitted; R. Mills and M. Nansteel, P. Ray, “Bright Hydrogen-Light Source due to a Resonant Energy Transfer with Strontium and Argon Ions”, New Journal of Physics, Vol. 4, (2002), pp. 70.1-70.28; R. Mills, P. Ray, R. M. Mayo, “CW HI Laser Based on a Stationary Inverted Lyman Population Formed from Incandescently Heated Hydrogen Gas with Certain Group I Catalysts”, IEEE Transactions on Plasma Science, in press; R. L. Mills, P. Ray, J. Dong, M. Nansteel, B. Dhandapani, J. He, “Spectral Emission of Fractional-Principal-Quantum-Energy-Level Atomic and Molecular Hydrogen”, Vibrational Spectroscopy, in press; R. L. Mills, P. Ray, E. Dayalan, B. Dhandapani, J. He, “Comparison of Excessive Balmer α Line Broadening of Inductively and Capacitively Coupled RF, Microwave, and Glow Discharge Hydrogen Plasmas with Certain Catalysts”, IEEE Transactions on Plasma Science, submitted; R. M. Mayo, R. Mills, M. Nansteel, “Direct Plasmadynamic Conversion of Plasma Thermal Power to Electricity”, IEEE Transactions on Plasma Science, in press; H. Conrads, R. Mills, Th. Wrubel, “Emission in the Deep Vacuum Ultraviolet from a Plasma Formed by Incandescently Heating Hydrogen Gas with Trace Amounts of Potassium Carbonate”, Plasma Sources Science and Technology, submitted; R. L. Mills, P. Ray, “Stationary Inverted Lyman Population and a Very Stable Novel Hydride Formed by a Catalytic Reaction of Atomic Hydrogen and Certain Catalysts”, International Journal of Engineering Science, submitted; R. L. Mills, J. He, P. Ray, B. Dhandapani, X. Chen, “Synthesis and Characterization of a Highly Stable Amorphous Silicon Hydride as the Product of a Catalytic Helium-Hydrogen Plasma Reaction”, Int. J. Hydrogen Energy, in press; R. L. Mills, A. Voigt, B. Dhandapani, J. He, “Synthesis and Characterization of Lithium Chloro Hydride”, Int. J. Hydrogen Energy, submitted; R. L. Mills, P. Ray, “Substantial Changes in the Characteristics of a Microwave Plasma Due to Combining Argon and Hydrogen”, New Journal of Physics, www.njp.org, Vol. 4, (2002), pp. 22.1-22.17; R. L. Mills, P. Ray, “A Comprehensive Study of Spectra of the Bound-Free Hyperfine Levels of Novel Hydride Ion H⁻(½), Hydrogen, Nitrogen, and Air”, Int. J. Hydrogen Energy, in press; R. L. Mills, E. Dayalan, “Novel Alkali and Alkaline Earth Hydrides for High Voltage and High Energy Density Batteries”, Proceedings of the 17ₜₕ Annual Battery Conference on Applications and Advances, California State University, Long Beach, Calif., (Jan. 15-18, 2002), pp. 1-6; R. M. Mayo, R. Mills, M. Nansteel, “On the Potential of Direct and MHD Conversion of Power from a Novel Plasma Source to Electricity for Microdistributed Power Applications”, IEEE Transactions on Plasma Science, in press; R. Mills, P. C. Ray, R. M. Mayo, M. Nansteel, W. Good, P. Jansson, B. Dhandapani, J. He, “Stationary Inverted Lyman Populations and Free-Free and Bound-Free Emission of Lower-Energy State Hydride Ion Formed by an Exothermic Catalytic Reaction of Atomic Hydrogen and Certain Group I Catalysts”, Physical Chemistry Chemical Physics, submitted; R. Mills, E. Dayalan, P. Ray, B. Dhandapani, J. He, “Highly Stable Novel Inorganic Hydrides from Aqueous Electrolysis and Plasma Electrolysis”, Electrochimica Acta, Vol. 47, No. 24, (2002), pp. 3909-3926; R. L. Mills, P. Ray, B. Dhandapani, R. M. Mayo, J. He, “Comparison of Excessive Balmer α Line Broadening of Glow Discharge and Microwave Hydrogen Plasmas with Certain Catalysts”, J. of Applied Physics, (2002), Vol. 92, No. 12, pp. 7008-7022; R. L. Mills, P. Ray, B. Dhandapani, J. He, “Emission Spectroscopic Identification of Fractional Rydberg States of Atomic Hydrogen Formed by a Catalytic Helium-Hydrogen Plasma Reaction”, Vacuum, submitted; R. L. Mills, P. Ray, B. Dhandapani, M. Nansteel, X. Chen, J. He, “New Power Source from Fractional Rydberg States of Atomic Hydrogen”, Optics Communications, submitted; R. L. Mills, P. Ray, B. Dhandapani, M. Nansteel, X. Chen, J. He, “Spectroscopic Identification of Transitions of Fractional Rydberg States of Atomic Hydrogen”, Chemical Engineering Journal, submitted; R. L. Mills, P. Ray, B. Dhandapani, M. Nansteel, X. Chen, J. He, “New Power Source from Fractional Quantum Energy Levels of Atomic Hydrogen that Surpasses Internal Combustion”, J Mol. Struct., Vol. 643, No. 1-3, (2002), pp. 43-54; R. L. Mills, P. Ray, “Spectroscopic Identification of a Novel Catalytic Reaction of Rubidium Ion with Atomic Hydrogen and the Hydride Ion Product”, Int. J. Hydrogen Energy, Vol. 27, No. 9, (2002), pp. 927-935; R. Mills, J. Dong, W. Good, P. Ray, J. He, B. Dhandapani, “Measurement of Energy Balances of Noble Gas-Hydrogen Discharge Plasmas Using Calvet Calorimetry”, Int. J. Hydrogen Energy, Vol. 27, No. 9, (2002), pp. 967-978; R. L. Mills, A. Voigt, P. Ray, M. Nansteel, B. Dhandapani, “Measurement of Hydrogen Balmer Line Broadening and Thermal Power Balances of Noble Gas-Hydrogen Discharge Plasmas”, Int. J. Hydrogen Energy, Vol. 27, No. 6, (2002), pp. 671-685; R. Mills, P. Ray, “Vibrational Spectral Emission of Fractional-Principal-Quantum-Energy-Level Hydrogen Molecular Ion”, Int. J. Hydrogen Energy, Vol. 27, No. 5, (2002), pp. 533-564; R. Mills, P. Ray, “Spectral Emission of Fractional Quantum Energy Levels of Atomic Hydrogen from a Helium-Hydrogen Plasma and the Implications for Dark Matter”, Int. J. Hydrogen Energy, (2002), Vol. 27, No. 3, pp. 301-322; R. Mills, P. Ray, “Spectroscopic Identification of a Novel Catalytic Reaction of Potassium and Atomic Hydrogen and the Hydride Ion Product”, Int. J. Hydrogen Energy, Vol. 27, No. 2, (2002), pp. 183-192; R. Mills, “BlackLight Power Technology-A New Clean Hydrogen Energy Source with the Potential for Direct Conversion to Electricity”, Proceedings of the National Hydrogen Association, 12 th Annual U.S. Hydrogen Meeting and Exposition, Hydrogen: The Common Thread, The Washington Hilton and Towers, Washington DC, (Mar. 6-8, 2001), pp. 671-697; R. Mills, W. Good, A. Voigt, Jinquan Dong, “Minimum Heat of Formation of Potassium Todo Hydride”, Int. J. Hydrogen Energy, Vol. 26, No. 11, (2001), pp. 1199-1208; R. Mills, “Spectroscopic Identification of a Novel Catalytic Reaction of Atomic Hydrogen and the Hydride Ion Product”, Int. J. Hydrogen Energy, Vol. 26, No. 10, (2001), pp. 1041-1058; R. Mills, N. Greenig, S. Hicks, “Optically Measured Power Balances of Glow Discharges of Mixtures of Argon, Hydrogen, and Potassium, Rubidium, Cesium, or Strontium Vapor”, Int. J. Hydrogen Energy, Vol. 27, No. 6, (2002), pp. 651-670; R. Mills, “The Grand Unified Theory of Classical Quantum Mechanics”, Global Foundation, Inc. Orbis Scientiae entitled The Role of Attractive and Repulsive Gravitational Forces in Cosmic Acceleration of Particles The Origin of the Cosmic Gamma Ray Bursts, (29th Conference on High Energy Physics and Cosmology Since 1964) Dr. Behram N. Kursunoglu, Chairman, Dec. 14-17, 2000, Lago Mar Resort, Fort Lauderdale, Fla., Kluwer Academic/Plenum Publishers, New York, pp. 243-258; R. Mills, “The Grand Unified Theory of Classical Quantum Mechanics”, Int. J. Hydrogen Energy, Vol. 27, No. 5, (2002), pp. 565-590; R. Mills and M. Nansteel, P. Ray, “Argon-Hydrogen-Strontium Discharge Light Source”, IEEE Transactions on Plasma Science, Vol. 30, No. 2, (2002), pp. 639-653, R. Mills, B. Dhandapani, M. Nansteel, J. He, A. Voigt, “Identification of Compounds Containing Novel Hydride Ions by Nuclear Magnetic Resonance Spectroscopy”, Int. J. Hydrogen Energy, Vol. 26, No. 9, (2001), pp. 965-979; R. Mills, “BlackLight Power Technology-A New Clean Energy Source with the Potential for Direct Conversion to Electricity”, Global Foundation International Conference on “Global Warming and Energy Policy”, Dr. Behram N. Kursunoglu, Chairman, Fort Lauderdale, Fla., Nov. 26-28, 2000, Kluwer Academic/Plenum Publishers, New York, pp. 187-202; R. Mills, “The Nature of Free Electrons in Superfluid Helium—a Test of Quantum Mechanics and a Basis to Review its Foundations and Make a Comparison to Classical Theory”, Int. J. Hydrogen Energy, Vol. 26, No. 10, (2001), pp. 1059-1096; R. Mills, M. Nansteel, and Y. Lu, “Excessively Bright Hydrogen-Strontium Plasma Light Source Due to Energy Resonance of Strontium with Hydrogen”, J. of Plasma Physics, in press; R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943; R. Mills, “Observation of Extreme Ultraviolet Emission from Hydrogen-KI Plasmas Produced by a Hollow Cathode Discharge”, Int. J. Hydrogen Energy, Vol. 26, No. 6, (2001), pp. 579-592; R. Mills, “Temporal Behavior of Light-Emission in the Visible Spectral Range from a Ti—K2CO3-H-Cell”, Int. J. Hydrogen Energy, Vol. 26, No. 4, (2001), pp. 327-332; R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, Vol. 26, No. 7, July, (2001), pp. 749-762; R. Mills, M. Nansteel, and Y. Lu, “Observation of Extreme Ultraviolet Hydrogen Emission from Incandescently Heated Hydrogen Gas with Strontium that Produced an Anomalous Optically Measured Power Balance”, Int. J. Hydrogen Energy, Vol. 26, No. 4, (2001), pp. 309-326; R. Mills, B. Dhandapani, N. Greenig, J. He, “Synthesis and Characterization of Potassium Iodo Hydride”, Int. J. of Hydrogen Energy, Vol. 25, Issue 12, December, (2000), pp. 1185-1203; R. Mills, “Novel Inorganic Hydride”, Int. J. of Hydrogen Energy, Vol. 25, (2000), pp. 669-683; R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367; R. Mills, “Highly Stable Novel Inorganic Hydrides”, Journal of New Materials for Electrochemical Systems, in press; R. Mills, “Novel Hydrogen Compounds from a Potassium Carbonate Electrolytic Cell”, Fusion Technology, Vol. 37, No. 2, March, (2000), pp. 157-182; R. Mills, “The Hydrogen Atom Revisited”, Int. J. of Hydrogen Energy, Vol. 25, Issue 12, December, (2000), pp. 1171-1183; Mills, R., Good, W., “Fractional Quantum Energy Levels of Hydrogen”, Fusion Technology, Vol. 28, No. 4, November, (1995), pp. 1697-1719; Mills, R., Good, W., Shaubach, R., “Dihydrino Molecule Identification”, Fusion Technology, Vol. 25, 103 (1994); R. Mills and S. Kneizys, Fusion Technol. Vol. 20, 65 (1991); V. Noninski, Fusion Technol., Vol. 21, 163 (1992); Niedra, J., Meyers, I., Fralick, G. C., and Baldwin, R., “Replication of the Apparent Excess Heat Effect in a Light Water-Potassium Carbonate-Nickel Electrolytic Cell, NASA Technical Memorandum 107167, February, (1996). pp. 1-20.; Niedra, J., Baldwin, R., Meyers, I., NASA Presentation of Light Water Electrolytic Tests, May 15, 1994; in prior U.S. Provisional Patent Applications Ser. No. 60/343,585, filed Jan. 2, 2002; 60/352,880, filed Feb. 1, 2002; Ser. No. 60/361,337, filed Mar. 5, 2002; Ser. No. 60/365,176, filed Mar. 19, 2002; Ser. No. 60/367,476, filed Mar. 27, 2002; Ser. No. 60/376,546, filed May 1, 2002; Ser. No. 60/380,846, filed May 17, 2002; and Ser. No. 60/385,892, filed Jun. 6, 2002; Ser. No. 60/095,149, filed Aug. 3, 1998; Ser. No. 60/101,651, filed Sep. 24, 1998; Ser. No. 60/105,752, filed Oct. 26, 1998; Ser. No. 60/113,713, filed Dec. 24, 1998; Ser. No. 60/123,835, filed Mar. 11, 1999; Ser. No. 60/130,491, filed Apr. 22, 1999; Ser. No. 60/141,036, filed Jun. 29, 1999; Serial. No. 60/053378 filed Jul. 22, 1997; Serial No. 60/068913 filed Dec. 29, 1997; Serial No. 60/090239 filed Jun. 22, 1998; Serial No. 60/053,307 filed Jul. 22, 1997; Serial No. 60/068918 filed Dec. 29, 1997; Serial No. 60/080,725 filed Apr. 3, 1998; Serial No. 60/063,451 filed Oct. 29, 1997; Serial No. 60/074,006 filed Feb. 9, 1998; Serial No. 60/080,647 filed Apr. 3, 1998; in prior PCT applications PCT/US02/35872; PCT/US02/06945; PCT/US02/06955; PCT/US01/09055; PCT/US01/25954; PCT/US00/20820; PCT/US00/20819; PCT/US00/09055; PCT/US99/17171; PCT/US99/17129; PCT/US 98/22822; PCT/US98/14029; PCT/US96/07949; PCT/US94/02219; PCT/US91/08496; PCT/US90/01998; and PCT/US89/05037; prior U.S. patent applications Ser. No. 10/319,460, filed Nov. 27, 2002; Ser. No. 09/813,792, filed Mar. 22, 2001; Ser. No. 09/678,730, filed Oct. 4, 2000; Ser. No. 09/513,768, filed Feb. 25, 2000; Ser. No. 09/501,621, filed Feb. 9, 2000; Ser. No. 09/501,622, filed Feb. 9, 2000; Ser. No. 09/362,693, filed Jul. 29, 1999; Ser. No. 09/225,687, filed on Jan. 6, 1999; Ser. No. 09/009,294 filed Jan. 20, 1998; Ser. No. 09/111,160 filed Jul. 7, 1998; Ser. No. 09/111,170 filed Jul. 7, 1998; Ser. No. 09/111,016 filed Jul. 7, 1998; Ser. No. 09/111,003 filed Jul. 7, 1998; Ser. No. 09/110,694 filed Jul. 7, 1998; Ser. No. 09/110,717 filed Jul. 7, 1998; Ser. No. 09/009,455 filed Jan. 20, 1998; Ser. No. 09/110,678 filed Jul. 7, 1998; Ser. No. 09/181,180 filed Oct. 28, 1998; Ser. No. 09/008,947 filed Jan. 20, 1998; Ser. No. 09/009,837 filed Jan. 20, 1998; Ser. No. 08/822,170 filed Mar. 27, 1997; Ser. No. 08/592,712 filed Jan. 26, 1996; Ser. No. 08/467,051 filed on Jun. 6, 1995; Ser. No. 08/416,040 filed on Apr. 3, 1995; Ser. No. 08/467,911 filed on Jun. 6, 1995; Ser. No. 08/107,357 filed on Aug. 16, 1993; Ser. No. 08/075,102 filed on Jun. 11, 1993; Ser. No. 07/626,496 filed on Dec. 12,1990; Ser. No. 07/345,628 filed Apr. 28, 1989; Ser. No. 07/341,733 filed Apr. 21, 1989; and U.S. Pat. No. 6,024,935; the entire disclosures of which are all incorporated herein by reference (hereinafter “Mills Prior Publications”).

The binding energy of an atom, ion, or molecule, also known as the ionization energy, is the energy required to remove one electron from the atom, ion or molecule. A hydrogen atom having the binding energy given in Eq. (6) is hereafter referred to as a hydrino atom or hydrino. The designation for a hydrino of radius

$$\frac{{a}_{H}}{p} ,$$

where a_{H} is the radius of an ordinary hydrogen atom and p is an integer, is

$$H [ \frac{{a}_{H}}{p} ] .$$

A hydrogen atom with a radius a_{H} is hereinafter referred to as “ordinary hydrogen atom” or “normal hydrogen atom.” Ordinary atomic hydrogen is characterized by its binding energy of 13.6 eV.

Hydrinos are formed by reacting an ordinary hydrogen atom with a catalyst having a net enthalpy of reaction of about

m·27.2 eV (7a)

where m is an integer. This catalyst has also been referred to as an energy hole or source of energy hole in Mills earlier filed Patent Applications. It is believed that the rate of catalysis is increased as the net enthalpy of reaction is more closely matched to m·27.2 eV. It has been found that catalysts having a net enthalpy of reaction within ±10%, preferably ±5%, of m·27.2 eV are suitable for most applications.

In another embodiment, the catalyst to form hydrinos has a net enthalpy of reaction of about

m/2·27.2 eV (7b)

where m is an integer greater that one. It is believed that the rate of catalysis is increased as the net enthalpy of reaction is more closely matched to m/2·27.2 eV. It has been found that catalysts having a net enthalpy of reaction within ±10%, preferably ±5%, of m/2·27.2 eV are suitable for most applications. The catalyst are given in Mills Prior Publications such as those given in TABLES 1 and 3 of my prior PCT Appl. No. PCT/US02/06945 filed November 2002 and the Tables of the Prior Mills Publications (e.g. TABLE 4 of PCT/US90/01998 and pages 25-46, 80-108 of PCT/US94/02219). The catalyst may be at least one molecule selected from the group of C₂, N₂, O₂, CO₂, NO₂, and NO₃ or at least one atom, ion, or excimer selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He⁺, Na⁺, Rb⁺, Sr⁺, Fe³⁺, Mo²⁺, Mo⁴⁺, In³⁺, He⁺, Ne⁺, Ar⁺, Xe⁺, H, H(1/p), Ar²⁺ and Ne⁺ and H⁺, Ne₂*, and He₂*.

The hydrino hydride ion of the present invention can be formed by the reaction of an electron source with a hydrino, that is, a hydrogen atom having a binding energy of about

$$\frac{13.6 e V}{{n}^{2}} , where n = \frac{1}{p}$$

and p is an integer greater than 1. The hydrino hydride ion is represented by H⁻(n=1/p) or H⁻(1/p):

$$\begin{matrix}H [ \frac{{a}_{H}}{p} ] + {ⅇ}^{-} \to {H}^{-} ( n = 1 / p ) & ( \text{8a} ) \\ H [ \frac{{a}_{H}}{p} ] + {ⅇ}^{-} \to {H}^{-} ( 1 / p ) & ( 8 b )\end{matrix}$$

The hydrino hydride ion is distinguished from an ordinary hydride ion comprising an ordinary hydrogen nucleus and two electrons having a binding energy of about 0.8 eV. The latter is hereafter referred to as “ordinary hydride ion” or “normal hydride ion” The hydrino hydride ion comprises a hydrogen nucleus including proteum, deuterium, or tritium, and two indistinguishable electrons at a binding energy according to Eq. (9).

The binding energy of a novel hydrino hydride ion can be represented by the following formula:

$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} ) \qquad ( 9 )$$

where p is an integer greater than one, s=½, π is pi, [symbol] is Planck's constant bar, μₒ is the permeability of vacuum, mₑ is the mass of the electron, μₑ is the reduced electron mass given by

$${μ}_{e} = \frac{{m}_{e} {m}_{p}}{\frac{{m}_{e}}{\sqrt{\frac{3}{4}}} + {m}_{p}}$$

where mₚ is the mass of the proton, a_{H} is the radius of the hydrogen atom, aₒ is the Bohr radius, and e is the elementary charge. The radii are given by

$${r}_{2} = {r}_{1} = {a}_{0} ( 1 + \sqrt{s ( s + 1 )} ) s = \frac{1}{2} \qquad ( 10 )$$

The binding energies of the hydrino hydride ion, H⁻(n=1/p) as a function of p, where p is an integer, are shown in TABLE 1.

TABLE 1
The representative binding energy of the hydrino hydride ion
H⁻(n = 1/p) as a function of p, Eq. (9).

| | r₁ | Binding | Wavelength |
|---|---|---|---|
| Hydride Ion | (a₀)^{a} | Energy (eV)^{b} | (nm) |
| H⁻(n = 1) | 1.8660 | 0.7542 | 1644 |
| H⁻(n = 1/2) | 0.9330 | 3.047 | 406.9 |
| H⁻(n = 1/3) | 0.6220 | 6.610 | 187.6 |
| H⁻(n = 1/4) | 0.4665 | 11.23 | 110.4 |
| H⁻(n = 1/5) | 0.3732 | 16.70 | 74.23 |
| H⁻(n = 1/6) | 0.3110 | 22.81 | 54.35 |
| H⁻(n = 1/7) | 0.2666 | 29.34 | 42.25 |
| H⁻(n = 1/8) | 0.2333 | 36.09 | 34.46 |
| H⁻(n = 1/9) | 0.2073 | 42.84 | 28.94 |
| H⁻(n = 1/10) | 0.1866 | 49.38 | 25.11 |
| H⁻(n = 1/11) | 0.1696 | 55.50 | 22.34 |
| H⁻(n = 1/12) | 0.1555 | 60.98 | 20.33 |
| H⁻(n = 1/13) | 0.1435 | 65.63 | 18.89 |
| H⁻(n = 1/14) | 0.1333 | 69.22 | 17.91 |
| H⁻(n = 1/15) | 0.1244 | 71.55 | 17.33 |
| H⁻(n = 1/16) | 0.1166 | 72.40 | 17.12 |
| H⁻(n = 1/17) | 0.1098 | 71.56 | 17.33 |
| H⁻(n = 1/18) | 0.1037 | 68.83 | 18.01 |
| H⁻(n = 1/19) | 0.0982 | 63.98 | 19.38 |
| H⁻(n = 1/20) | 0.0933 | 56.81 | 21.82 |
| H⁻(n = 1/21) | 0.0889 | 47.11 | 26.32 |
| H⁻(n = 1/22) | 0.0848 | 34.66 | 35.76 |
| H⁻(n = 1/23) | 0.0811 | 19.26 | 64.36 |
| H⁻(n = 1/24) | 0.0778 | 0.6945 | 1785 |

^{a}Equation (10)
^{b}Equation (9)

The existence of novel alkaline and alkaline earth hydride and halido-hydrides were previously identified by large distinct upfield ¹H NMR resonances compared to the NMR peaks of the corresponding ordinary hydrides [R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367; R. Mills, B. Dhandapani, N. Greenig, J. He, “Synthesis and Characterization of Potassium Iodo Hydride”, Int. J. of Hydrogen Energy, Vol. 25, Issue 12, December, (2000), pp. 1185-1203; R. Mills, B. Dhandapani, M. Nansteel, J. He, A. Voigt, “Identification of Compounds Containing Novel Hydride Ions by Nuclear Magnetic Resonance Spectroscopy”, Int. J. Hydrogen Energy, Vol. 26, No. 9, (2001), pp. 965-979]. Using a number of analytical techniques such as XPS and time-of-flight-secondary-mass-spectroscopy (ToF-SIMS) as well as NMR, the hydrogen content was assigned to H⁻(1/p), novel high-binding-energy hydride ions in stable fractional principal quantum states [R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367; R. Mills, B. Dhandapani, N. Greenig, J. He, “Synthesis and Characterization of Potassium Iodo Hydride”, Int. J. of Hydrogen Energy, Vol. 25, Issue 12, December, (2000), pp. 1185-1203; R. L. Mills, B. Dhandapani, J. He, “Highly Stable Amorphous Silicon Hydride”, Solar Energy Materials & Solar Cells, submitted]. The synthesis reactions typically involve metal ion catalysts. For example, Rb⁺ to Rb ²⁺ and 2K⁺ to K+K²⁺ each provide a reaction with a net enthalpy equal to the potential energy of atomic hydrogen. It was reported previously [R. L. Mills, P. Ray, “A Comprehensive Study of Spectra of the Bound-Free Hyperfine Levels of Novel Hydride Ion H⁻(½), Hydrogen, Nitrogen, and Air”, Int. J. Hydrogen Energy, in press] that the presence of these gaseous ions with thermally dissociated hydrogen formed a hydrogen plasma with hydrogen atom energies of 17 and 12 eV respectively, compared to 3 eV for a hydrogen microwave plasma. The energetic catalytic reaction involves a resonance energy transfer between hydrogen atoms and Rb⁺ or 2K⁺ to form a very stable novel hydride ion H⁻(½). Its predicted binding energy of 3.0468 eV was observed by high resolution visible spectroscopy as a continuum threshold at 406.82 nm, and a structured, strong emission peak was observed at 407.1 nm corresponding to the fine structure and hyperfine structure of H(½). From the electron g factor, bound-free hyperfine structure lines of H⁻(½) were predicted with energies E_{HF} given by E_{HF}=j²3.00213×10⁻⁵+3.0563 eV (j is an integer) as an inverse Rydberg-type series from 3.0563 eV to 3.1012 eV—the hydride binding energy peak with the fine structure plus one and five times the spin-pairing energy, respectively. The high resolution visible plasma emission spectra in the region of 399.5 to 406.0 nm matched the predicted emission lines for j=1 to j=39 with the series edge at 399.63 nm up to 1 part in 10⁵.

### SUMMARY OF THE INVENTIONS

An object of the present invention is to generate power and novel hydrogen species and compositions of matter comprising new forms of hydrogen via the catalysis of atomic hydrogen.

Another object of the present invention is to synthesize silicon hydride (SiH(1/p)) thin films on substrates that have enhanced stability to oxidation due to the incorporation of increased binding energy species. The films may be amorphous or crystalline.

The above objectives and other objectives are achieved by the present invention comprising a power source and hydrogen reactor to form silicon hydride SiH(1/p) in crystalline or amorphous form. SiH(1/p) may be formed as a film on a substrate. SiH(1/p) comprises silicon and at least one increased binding energy hydrogen species. SiH(1/p) may comprise silicon that is terminated with an increased binding energy hydrogen species. In an embodiment SiH(1/p) comprises hydrino terminated silicon.

The power source and reactor comprises a cell for the catalysis of atomic hydrogen to form novel hydrogen species and compositions of matter comprising new forms of hydrogen. The novel hydrogen compositions of matter comprise:

(a) at least one neutral, positive, or negative hydrogen species (hereinafter “increased binding energy hydrogen species”) having a binding energy

(i) greater than the binding energy of the corresponding ordinary hydrogen species, or

(ii) greater than the binding energy of any hydrogen species for which the corresponding ordinary hydrogen species is unstable or is not observed because the ordinary hydrogen species' binding energy is less than thermal energies at ambient conditions (standard temperature and pressure, STP), or is negative; and

(b) at least one other element. The compounds of the invention are hereinafter referred to as “increased binding energy hydrogen compounds”.

By “other element” in this context is meant an element other than an increased binding energy hydrogen species. Thus, the other element can be an ordinary hydrogen species, or any element other than hydrogen. In one group of compounds, the other element and the increased binding energy hydrogen species are neutral. In another group of compounds, the other element and increased binding energy hydrogen species are charged such that the other element provides the balancing charge to form a neutral compound. The former group of compounds is characterized by molecular and coordinate bonding; the latter group is characterized by ionic bonding. The other element may be silicon in any oxidation state.

Also provided are novel compounds and molecular ions comprising

(a) at least one neutral, positive, or negative hydrogen species (hereinafter “increased binding energy hydrogen species”) having a total energy

(i) greater than the total energy of the corresponding ordinary hydrogen species, or

(ii) greater than the total energy of any hydrogen species for which the corresponding ordinary hydrogen species is unstable or is not observed because the ordinary hydrogen species' total energy is less than thermal energies at ambient conditions, or is negative; and

(b) at least one other element. The other element may be silicon in any oxidation state.

The total energy of the hydrogen species is the sum of the energies to remove all of the electrons from the hydrogen species. The hydrogen species according to the present invention has a total energy greater than the total energy of the corresponding ordinary hydrogen species. The hydrogen species having an increased total energy according to the present invention is also referred to as an “increased binding energy hydrogen species” even though some embodiments of the hydrogen species having an increased total energy may have a first electron binding energy less that the first electron binding energy of the corresponding ordinary hydrogen species. For example, the hydride ion of Eq. (9) for p=24 has a first binding energy that is less than the first binding energy of ordinary hydride ion, while the total energy of the hydride ion of Eq. (9) for p=24 is much greater than the total energy of the corresponding ordinary hydride ion.

Also provided are novel compounds and molecular ions comprising

(a) a plurality of neutral, positive, or negative hydrogen species (hereinafter “increased binding energy hydrogen species”) having a binding energy

(i) greater than the binding energy of the corresponding ordinary hydrogen species, or

(ii) greater than the binding energy of any hydrogen species for which the corresponding ordinary hydrogen species is unstable or is not observed because the ordinary hydrogen species' binding energy is less than thermal energies at ambient conditions or is negative; and

(b) optionally one other element. The compounds of the invention are hereinafter referred to as “increased binding energy hydrogen compounds”.

The increased binding energy hydrogen species can be formed by reacting one or more hydrino atoms with one or more of an electron, hydrino atom, a compound containing at least one of said increased binding energy hydrogen species, and at least one other atom, molecule, or ion other than an increased binding energy hydrogen species.

Also provided are novel compounds and molecular ions comprising

(a) a plurality of neutral, positive, or negative hydrogen species (hereinafter “increased binding energy hydrogen species”) having a total energy

(i) greater than the total energy of ordinary molecular hydrogen, or

(ii) greater than the total energy of any hydrogen species for which the corresponding ordinary hydrogen species is unstable or is not observed because the ordinary hydrogen species' total energy is less than thermal energies at ambient conditions or is negative; and

(b) optionally one other element. The other element may be silicon. The compounds of the invention are hereinafter referred to as “increased binding energy hydrogen compounds”.

The total energy of the increased total energy hydrogen species is the sum of the energies to remove all of the electrons from the increased total energy hydrogen species. The total energy of the ordinary hydrogen species is the sum of the energies to remove all of the electrons from the ordinary hydrogen species. The increased total energy hydrogen species is referred to as an increased binding energy hydrogen species, even though some of the increased binding energy hydrogen species may have a first electron binding energy less than the first electron binding energy of ordinary molecular hydrogen. However, the total energy of the increased binding energy hydrogen species is much greater than the total energy of ordinary molecular hydrogen.

In one embodiment of the invention, the increased binding energy hydrogen species can be Hₙ, and Hₙ⁻ where n is a positive integer, or Hₙ⁺ where n is a positive integer greater than one. Preferably, the increased binding energy hydrogen species is Hₙ and Hₙ⁻ where n is an integer from one to about 1×10⁶, more preferably one to about 1×10⁴, even more preferably one to about 1×10², and most preferably one to about 10, and Hₙ⁺ where n is an integer from two to about 1×10⁶, more preferably two to about 1×10⁴, even more preferably two to about 1×10², and most preferably two to about 10. A specific example of Hₙ⁻ is H₁₆⁻.

In an embodiment of the invention, the increased binding energy hydrogen species can be Hₙ^{m-} where n and m are positive integers and Hₙ^{m+} where n and m are positive integers with m<n. Preferably, the increased binding energy hydrogen species is Hₙ^{m-} where n is an integer from one to about 1×10⁶, more preferably one to about 1×10⁴, even more preferably one to about 1×10² , and most preferably one to about 10 and m is an integer from one to 100, one to ten, and Hₙ^{m+} where n is an integer from two to about 1×10⁶, more preferably two to about 1×10⁴, even more preferably two to about 1×10², and most preferably two to about 10 and m is one to about 100, preferably one to ten.

According to a preferred embodiment of the invention, a compound is provided, comprising at least one increased binding energy hydrogen species selected from the group consisting of (a) hydride ion having a binding energy according to Eq. (9) that is greater than the binding of ordinary hydride ion (about 0.8 eV) for p=2 up to 23, and less for p=24 (“increased binding energy hydride ion” or “hydrino hydride ion”); (b) hydrogen atom having a binding energy greater than the binding energy of ordinary hydrogen atom (about 13.6 eV) (“increased binding energy hydrogen atom” or “hydrino”); (c) hydrogen molecule having a first binding energy greater than about 15.3 eV (“increased binding energy hydrogen molecule” or “dihydrino”); and (d) molecular hydrogen ion having a binding energy greater than about 16.3 eV (“increased binding energy molecular hydrogen ion” or “dihydrino molecular ion”).

The compounds of the present invention are capable of exhibiting one or more unique properties which distinguishes them from the corresponding compound comprising ordinary hydrogen, if such ordinary hydrogen compound exists. The unique properties include, for example, (a) a unique stoichiometry; (b) unique chemical structure; (c) one or more extraordinary chemical properties such as conductivity, melting point, boiling point, density, and refractive index; (d) unique reactivity to other elements and compounds; (e) enhanced stability at room temperature and above; and/or (f) enhanced stability in air and/or water. Methods for distinguishing the increased binding energy hydrogen-containing compounds from compounds of ordinary hydrogen include: 1.) elemental analysis, 2.) solubility, 3.) reactivity, 4.) melting point, 5.) boiling point, 6.) vapor pressure as a function of temperature, 7.) refractive index, 8.) X-ray photoelectron spectroscopy (XPS), 9.) gas chromatography, 10.) X-ray diffraction (XRD), 11.) calorimetry, 12.) infrared spectroscopy (IR), 13.) Raman spectroscopy, 14.) Mossbauer spectroscopy, 15.) extreme ultraviolet (EUV) emission and absorption spectroscopy, 16.) ultraviolet (UV) emission and absorption spectroscopy, 17.) visible emission and absorption spectroscopy, 18.) nuclear magnetic resonance spectroscopy, 19.) gas phase mass spectroscopy of a heated sample (solids probe and direct exposure probe quadrapole and magnetic sector mass spectroscopy), 20.) time-of-flight-secondary-ion-mass-spectroscopy (TOFSIMS); 21.) electrospray-ionization-time-of-flight-mass-spectroscopy (ESITOFMS), 22.) thermogravimetric analysis (TGA), 23.) differential thermal analysis (DTA), 24.) differential scanning calorimetry (DSC), 25.) liquid chromatography/mass spectroscopy (LCMS), and/or 26.) gas chromatography/mass spectroscopy (GCMS).

According to the present invention, a hydrino hydride ion (H⁻) having a binding energy according to Eq. (9) that is greater than the binding of ordinary hydride ion (about 0.8 eV) for p=2 up to 23, and less for p=24 (H⁻) is provided. For p=2 to p=24 of Eq. (9), the hydride ion binding energies are respectively 3, 6.6, 11.2, 16.7, 22.8, 29.3, 36.1, 42.8, 49.4, 55.5, 61.0, 65.6, 69.2, 71.6, 72.4, 71.6, 68.8, 64.0, 56.8, 47.1, 34.7, 19.3, and 0.69 eV. Compositions comprising the novel hydride ion are also provided.

Novel compounds are provided comprising one or more hydrino hydride ions and one or more other elements. The other element may be silicon. Such a compound is referred to as a hydrino hydride compound.

Ordinary hydrogen species are characterized by the following binding energies (a) hydride ion, 0.754 eV (“ordinary hydride ion”); (b) hydrogen atom (“ordinary hydrogen atom”), 13.6 eV; (c) diatomic hydrogen molecule, 15.46 eV (“ordinary hydrogen molecule”); (d) hydrogen molecular ion, 16.3 eV (“ordinary hydrogen molecular ion”); and (e) H₃⁺, 22.6 eV (“ordinary trihydrogen molecular ion”). Herein, with reference to forms of hydrogen, “normal” and “ordinary” are synonymous.

According to a further preferred embodiment of the invention, a compound is provided comprising at least one increased binding energy hydrogen species such as (a) a hydrogen atom having a binding energy of about

$$\frac{13.6 eV}{{( \frac{1}{p} )}^{2}} ,$$

preferably within ±10%, more preferably ±5%, where p is an integer, preferably an integer from 2 to 200; (b) a hydride ion (H⁻) having a binding energy of about

$$\frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} ) ,$$

preferably within ±10%, more preferably ±5%, where p is an integer, preferably an integer from 2 to 200; (c) H₄⁺(1/p); (d) a trihydrino molecular ion, H₃⁺(1/p), having a binding energy of about

$$\frac{22.6}{{( \frac{1}{p} )}^{2}} eV$$

preferably within ±10%, more preferably ±5%, where p is an integer, preferably an integer from 2 to 200; (e) a dihydrino having a binding energy of about

$$\frac{15.3}{{( \frac{1}{p} )}^{2}} eV$$

preferably within ±10%, more preferably ±5%, where p is an integer, preferably and integer from 2 to 200; (f) a dihydrino molecular ion with a binding energy of about

$$\frac{16.3}{{( \frac{1}{p} )}^{2}} eV$$

preferably within ±10%, more preferably ±5%, where p is an integer, preferably an integer from 2 to 200.

According to one embodiment of the invention wherein the compound comprises a negatively charged increased binding energy hydrogen species, the compound further comprises one or more cations, such as a proton, ordinary H₂⁺, or ordinary H₃⁺.

A method is provided for preparing compounds comprising at least one increased binding energy hydride ion. Such compounds are hereinafter referred to as “hydrino hydride compounds”. The method comprises reacting atomic hydrogen with a catalyst having a net enthalpy of reaction of about

$$\frac{m}{2} \cdot 27 e V ,$$

where m is an integer greater than 1, preferably an integer less than 400, to produce an increased binding energy hydrogen atom having a binding energy of about

$$\frac{13.6 e V}{{( \frac{1}{p} )}^{2}}$$

where p is an integer, preferably an integer from 2 to 200. A further product of the catalysis is energy. The increased binding energy hydrogen atom can be reacted with an electron source, to produce an increased binding energy hydride ion. The increased binding energy hydride ion can be reacted with one or more cations to produce a compound comprising at least one increased binding energy hydride ion. The increased binding energy hydrogen may be reacted with a source of silicon to form an increased binding energy hydrogen compound comprising silicon.

2. Hydrogen Power and Plasma Cell and Reactor

The invention is also directed to a reactor for producing a increased binding energy hydrogen compounds of the invention, such as dihydrino molecules and hydrino hydride compounds. A further product of the catalysis is plasma, light, and power. Such a reactor is hereinafter referred to as a “hydrogen reactor” or “hydrogen cell”. The hydrogen reactor comprises a cell for making hydrinos. The cell for making hydrinos may take the form of at least one of a gas cell, gas discharge cell, microwave cell, inductively or capacitive coupled RF cell, multicusp cell, RF barrier electrode discharge cell, and filament or rt-plasma cell, for example. These exemplary cells which are not meant to be exhaustive are disclosed in Mills Prior Publications. Each of these cells comprises: a source of atomic hydrogen; at least one of a solid, molten, liquid, or gaseous catalyst for making hydrinos; and a vessel for reacting hydrogen and the catalyst for making hydrinos. As used herein and as contemplated by the subject invention, the term “hydrogen”, unless specified otherwise, includes not only proteum (¹H), but also deuterium (²H) and tritium (³H).

The reactors described herein as “hydrogen reactors” are capable of producing not only hydrinos, but also the other increased binding energy hydrogen species and compounds of the present invention. Hence, the designation “hydrogen reactors” should not be understood as being limiting with respect to the nature of the increased binding energy hydrogen species or compound produced. The reactor may be at least one of the group of a gas cell, gas discharge cell, microwave cell, inductively or capacitive coupled RF cell, multicusp cell, RF barrier electrode discharge cell, and filament or rt-plasma cell disclosed in Mills Prior Publications such as my prior PCT Appl. No. PCT/US02/06945 filed November 2002.

In an embodiment, a hydrogen microwave plasma and power cell and reactor of the present invention for the catalysis of atomic hydrogen to form increased-binding-energy-hydrogen species and increased-binding-energy-hydrogen compounds comprises a vessel having a chamber capable of containing a vacuum or pressures greater than atmospheric, a source of atomic hydrogen, a source of microwave power to form a plasma, a catalyst capable of providing a net enthalpy of reaction of m/2·27.2±0.5 eV where m is an integer, preferably m is an integer less than 400, and a source of silicon. The source of microwave power may comprise a microwave generator, a tunable microwave cavity, waveguide, and an antenna.

In another embodiment of a hydrogen capacitively and/or inductively coupled radio frequency (RF) plasma and power cell and reactor of the present invention for the catalysis of atomic hydrogen to form increased-binding-energy-hydrogen species and increased-binding-energy-hydrogen compounds comprises a vessel having a chamber capable of containing a vacuum or pressures greater than atmospheric, a source of atomic hydrogen, a source of RF power to form a plasma, a catalyst capable of providing a net enthalpy of reaction of m/2·27.2±0.5 eV where m is an integer, preferably m is an integer less than 400, and a source of silicon. The cell may further comprise at least two electrodes and an RF generator wherein the source of RF power may comprise the electrodes driven by the RF generator. Alternatively, the cell may further comprise a source coil which may be external to a cell wall which permits RF power to couple to the plasma formed in the cell, a conducting cell wall which may be grounded and a RF generator which drives the coil which may inductively and/or capacitively couple RF power to the cell plasma.

3. SiH(1/p) Synthesis

A reactor of the present invention for the synthesis of silicon hydride SiH(1/p) comprising increased binding energy hydrogen species in crystalline or as amorphous material such thin films comprises a hydrino hydride reactor and a source of silicon. The source of silicon may be at least one of the group of solid silicon, silane, SiₙH₂ₙ₊₂ (1<n<100), siloxanes, or other silicon containing compounds such as those given in the CRC or in Cotton [David R. Lide, CRC Handbook of Chemistry and Physics, 79 th Edition, CRC Press, Boca Raton, Fla., (1998-9), p. 4-82 to p. 4-83 and F. A. Cotton, G. Wilkinson, Advanced Inorganic Chemistry, Fourth Edition, John Wiley & Sons, New York which are herein incorporated by reference]. In an embodiment, the silicon or silicon precursor is supplied to the reactor as a solid. The solid may be placed in the reactor, and the hydrogen catalysis reaction is carried with the silicon present. In another embodiment, the source of silicon is supplied as a gas from a gas supply line. In another embodiment, silicon is vapor deposited on a desired target such as a substrate in the presence of the hydrogen catalysis reaction. Silicon and silicon precursors such as silanes may supplied to the hydrogen catalysis reaction to form SiH(1/p) by methods known to those skilled in the art such as by ion implantation, epitaxy, or vacuum deposition. In an embodiment, the formation of SiH(1/p) films occurs by vapor deposition of silicon in the presence of a helium-hydrogen plasma or an argon-hydrogen plasma wherein He⁺ or Ar⁺ serves as a catalyst, respectively. The catalysis reaction forms increased binding energy hydrogen species which react with the silicon in the gas phase or on the substrate. In a preferred embodiment, SiH(1/p) films are formed on a substrate by the reaction of silicon from silane, SiₙH₂ₙ₊₂ or a silicon compound with increased binding energy species formed in a helium-hydrogen plasma or an argon-hydrogen plasma wherein He⁺ or Ar⁺ serves as a catalyst, respectively. The reaction may occur in the gas phase followed by substrate deposition of SiH(1/p), or the silicon or silicon precursors may deposit on the substrate followed by reaction with increased binding energy hydrogen species.

### BRIEF DESCRIPTION OF THE DRAWINGS

FIG. 1 is a schematic drawing of a microwave gas cell reactor in accordance with the present invention;

FIG. 2 is the experimental set up of a microwave discharge gas cell light source comprising 1—microwave generator, 2—coaxial cable, 3-spectrometer, 4—fiber optic probe, 5—pressure gauge, 6, 7—mass flow controllers, 8, 9, 10, 17—valves, 11—helium supply, 12—xenon supply, 13—hydrogen supply, 14—microwave cavity such as an Evenson cavity, 15—plasma, 16—pump such as a molecular drag pump, 18—plasma cell reactor such as a quartz cell, 19—gas and vacuum line;

FIG. 3 is a schematic of the water bath calorimeter. The Evenson cavity and a plasma-containing section of the quartz tube were fitted with an water-tight stainless steel housing, and the housing and cell assembly were suspended by 4 support rods from an acrylic plate which held the cell vertically from the top of a water bath calorimeter. The components were 20, 21—gas supplies, 22, 23, 41—valves, 24, 25—mass flow controllers, 26—inlet gas line, 27—pressure gauge, 28—thermistor probe, 29—water, 30—insulation, 31—stirrer, 32—stirring motor, 33—sealed cavity containing a microwave cavity and a plasma cell, 34—coaxial cable, 35—water bath, 36—computer, 37—microwave generator, 38—vacuum pump, 39—gas outlet line;

FIG. 4 is the experimental synthesis set up comprising a microwave discharge cell operated under flow conditions. The components were 45—silane supply, 46—helium-hydrogen supply, 47, 48, 53, 54, 59—valves, 49—gas reservoir, 50, 51—pressure gauges, 52—needle valve, 55—substrate, 56—microwave cavity such as an Evenson cavity, 57—microwave generator, 58—vacuum pump, 60—plasma cell, 61, 62, 63, 64, 65—gas/vacuum lines, 66—coaxial cable;

FIG. 5 is the 656.3 nm Balmer α line width recorded with a high resolution (±0.006 nm ) visible spectrometer on a xenon-hydrogen (90/10%) and a hydrogen microwave discharge plasma. No line excessive broadening was observed corresponding to an average hydrogen atom temperature of 3-4 eV;

FIG. 6 is the 656.3 nr Balmer α line width recorded with a high resolution (±0.006 nm) visible spectrometer on a helium-hydrogen (90/10%) and a hydrogen microwave discharge plasma. Significant broadening was observed corresponding to an average hydrogen atom temperature of 180-210 eV compared to ≈3 eV for hydrogen alone;

FIG. 7 is the 667.816 nm He I line width recorded with a high resolution (±0.006 nm) visible spectrometer on helium-hydrogen (90/10%) and helium microwave discharge plasmas. No broadening was observed in either case;

FIG. 8 is the thermogram, T(t) response of the cell, with stirring only and with a constant input power to the high precision heater of 50 W. The baseline corrected least squares fit of the slope, T^{Y}(t), was 2.622×10⁻⁴° C./s, and the heat capacity was determined to be 1.907×10⁵ J/° C.;

FIG. 9 is the T(t) water bath response to stirring and then with selected panel meter readings of the constant forward and reflected microwave input power to krypton was recorded. The microwave input power was determined to be 8.1±1 W. A helium-hydrogen (90/10%) mixture was run at identical microwave input power readings as the control, and the excess power was determined to be 21.9±1 W from the T(t) response;

FIG. 10 is the positive ion ToF-SIMS spectra (m/e=0-100) of a noncoated cleaned commercial silicon wafer (Alfa Aesar 99.9%);

FIG. 11 is the positive ion ToF-SIMS spectra (m/e=0-100) of a nickel foil coated with an α—SiH(1/p) film and exposed to air for 10 min. that showed a large SiH⁺ peak;

FIG. 12 is the positive ion ToF-SIMS spectrum (m/e=0-100) of a nickel foil coated with an α—SiH(1/p) film and exposed to atmosphere for 10 days before the ToF-SIMS analysis that retained a large SiH⁺ peak;

FIG. 13 is the positive ion ToF-SIMS spectrum (m/e=0-100) of the HF cleaned silicon wafer exposed to air for 10 min. before ToF-SIMS analysis;

FIG. 14 is the negative ion ToF-SIMS spectrum (m/e=0-100) of the noncoated cleaned commercial silicon wafer (Alfa Aesar 99.99%);

FIG. 15 is the negative ion ToF-SIMS spectrum (m/e=0-100) of a nickel foil coated with an α—SiH(1/p) film and exposed to air for 10 min. before ToF-SINMS analysis that was dominated by hydride ion;

FIG. 16 is the negative ion ToF-SIMS spectrum (m/e=0-100) of a nickel foil coated with an α—SiH(1/p) film and exposed to air for 10 days before the ToF-SIMS analysis that retained the dominant hydride ion peak;

FIG. 17 is the negative ion ToF-SIMS spectrum (m/e=0-100) of the HF cleaned silicon wafer exposed to air for 10 min. before ToF-SIMS analysis;

FIG. 18 is the negative ion ToF-SIMS spectrum (m/e=0-100) of the HF cleaned silicon wafer exposed to air for 3 hours before ToF-SIMS analysis showing a dominant oxide peak;

FIG. 19 is the XPS survey scan of the noncoated cleaned commercial silicon wafer showing a large amount of oxide and carbon contamination of the surface;

FIG. 20 is the XPS survey scan of a nickel foil coated with an α—SiH(1/p) film and exposed to air for 20 min. before XPS analysis showing minimal oxide and carbon;

FIG. 21 is the XPS spectrum (96-108 eV) in the region of the Si 2 p peak of the noncoated cleaned commercial silicon wafer showing a large SiO₂ in the region of 104 eV;

FIG. 22 is the XPS spectrum (96-108 eV) in the region of the Si 2 p peak of a nickel foil with an α—SiH(1/p) film and exposed to air for 20 min. before XPS analysis showing no oxide in the region of 104 eV;

FIG. 23 is the XPS spectrum (96-108 eV) in the region of the Si 2 p peak of a nickel foil coated with an α—SiH(1/p) film and exposed to air for 48 hours before the XPS analysis showing no oxide at 104 eV and possibly trace SiOH in the region of 102 eV;

FIG. 24 is the XPS spectrum (96-108 eV) in the region of the Si 2 p peak of the HF cleaned silicon wafer exposed to air for 10 min. before XPS analysis showing a very large SiOₓ peak in the region of 101.5-104 eV;

FIG. 25 is the XPS spectrum (525-540 eV) in the region of the O 1s peak of a nickel foil coated with an α—SiH(1/p) film and exposed to air for 48 hours before XPS analysis showing a minimal amount of oxide;

FIG. 26 is the XPS spectrum (525-540 eV) in the region of the O 1s peak of the HF cleaned silicon wafer exposed to air for 10 min. before XPS analysis showing a very large oxide peak;

FIG. 27 is the 0-70 eV binding energy region of a high resolution XPS spectrum of the commercial silicon wafer showing only a large O 2s peak in the low binding energy region;

FIG. 28 is the 0-85 eV binding energy region of a high resolution XPS spectrum of the HF cleaned silicon wafer exposed to air for 10 min. before XPS analysis showing only a large O 2s peak in the low binding energy region, and

FIG. 29 is the 0-70 eV binding energy region of a high resolution XPS spectrum of a nickel foil coated with an α—SiH(1/p) film and exposed to air for 20 min. before XPS analysis. The novel peaks observed at 11, 43 and 55 eV which could not be assigned to the elements identified by their primary XPS peaks matched and were assigned to highly stable silicon hydrides formed by the catalytic reaction of He⁺ and atomic hydrogen.

### DETAILED DESCRIPTION OF THE INVENTION

The following preferred embodiments of the invention disclose numerous property ranges, including but not limited to, plasma power densities, gas pressure, mole fractions of reactants and catalysts, flow rates, temperature, and the like, which are merely intended as illustrative examples. Based on the detailed written description, one skilled in the art would easily be able to practice this invention within other property ranges to produce the desired result without undue experimentation.

1. Hydrogen RF and Microwave Power and Plasma Cell and Reactor

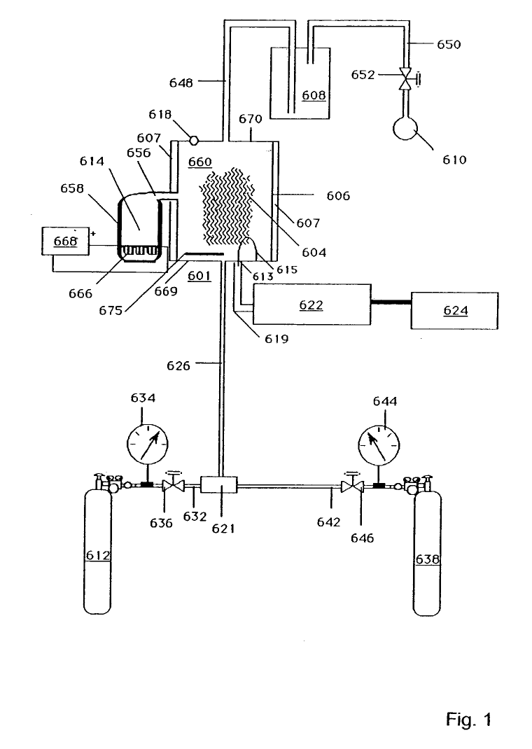

According to an embodiment of the invention, a reactor for producing power, plasma, and at least one of hydrinos, hydrino hydride ions, dihydrino molecular ions, and dihydrino molecules that react with a source of silicon to form α—SiH(1/p) may take the form of a hydrogen microwave reactor. A hydrogen microwave gas cell reactor of the present invention is shown in FIG. 1. Hydrinos are provided by a reaction with a catalyst capable of providing a net enthalpy of reaction of m/2·27.2±0.5 eV where m is an integer, preferably an integer less than 400 such as those given in TABLES 1 and 3 of my Prior PCT Appl. No. PCT/US02/06945 filed November 2002 and/or by a disproportionation reaction wherein lower-energy hydrogen, hydrinos, serve to cause transitions of hydrogen atoms and hydrinos to lower-energy levels with the release of power. Catalysis may occur in the gas phase. The catalyst may be generated by a microwave discharge. Preferred catalysts are He⁺ or Ar⁺ from a source such as helium gas or argon gas. The catalysis reaction may provide power to form and maintain a plasma that comprises energetic ions.

The reactor system of FIG. 1 comprises a reaction vessel 601 having a chamber 660 capable of containing a vacuum or pressures greater than atmospheric. A source of hydrogen 638 delivers hydrogen to supply tube 642, and hydrogen flows to the chamber through hydrogen supply passage 626. The flow of hydrogen can be controlled by hydrogen flow controller 644 and valve 646. In an embodiment, a source of hydrogen communicating with chamber 660 that delivers hydrogen to the chamber through hydrogen supply passage 626 is a hydrogen permeable hollow cathode of an electrolysis cell of the reactor system. Electrolysis of water produces hydrogen that permeates through the hollow cathode. The cathode may be a transition metal such as nickel, iron, or titanium, or a noble metal such as palladium, or platinum, or tantalum or palladium coated tantalum, or palladium coated niobium. The electrolyte may be basic and the anode may be nickel, platinum, or a dimensionally stable anode. The electrolyte may be aqueous K₂CO₃. The flow of hydrogen into the cell may be controlled by controlling the electrolysis current with an electrolysis power controller.

Plasma gas flows from the plasma gas supply 612 via passage 632. The flow of plasma gas can be controlled by plasma gas flow controller 634 and valve 636. A mixture of plasma gas and hydrogen can be supplied to the cell via passage 626. The mixture is controlled by hydrogen-plasma-gas mixer and mixture flow regulator 621. The plasma gas such as helium may be a source of catalyst such as He⁺ or He₂ *, argon may be a source of catalyst such as Ar⁺, neon may serve as a source of catalyst such as Ne₂ * or Ne⁺, and neon-hydrogen mixture may serve as a source of catalyst such as Ne⁺/H⁺. The source of catalyst and hydrogen of the mixture flow into the plasma and become catalyst and atomic hydrogen in the chamber 660.

The plasma may be powered by a microwave generator 624 wherein the microwaves are tuned by a tunable microwave cavity 622, carried by waveguide 619, and can be delivered to the chamber 660 though an RF transparent window 613 or antenna 615. Sources of microwaves known in the art are traveling wave tubes, klystrons, magnetrons, cyclotron resonance masers, gyrotrons, and free electron lasers. The waveguide or antenna may be inside or outside of the cell. In the latter case, the microwaves may penetrate the cell from the source through a window of the cell 613. The microwave window may comprise Alumina or quartz.

In another embodiment, the cell 601 is a microwave resonator cavity. In an embodiment, the source of microwave supplies sufficient microwave power density to the cell to ionize a source of catalyst such as at least one of helium, neon-hydrogen mixture, and argon gases to form a catalyst such as He⁺, Ne⁺, and Ar⁺, respectively. In such an embodiment, the microwave power source or applicator such as an antenna, waveguide, or cavity forms a nonthermal plasma wherein the species corresponding to the source of catalyst such as helium or argon atoms and ions have a higher temperature than that at thermal equilibrium. Thus, higher energy states such as ionized states of the source of catalyst are predominant over that of hydrogen compared to a corresponding thermal plasma wherein excited states of hydrogen are predominant. In an embodiment, the source of catalyst is in excess compared to the source of hydrogen atoms such that the formation of a nonthermal plasma is favored. The power supplied by the source of microwave power may be delivered to the cell such that it is dissipated in the formation of energetic electrons within about the electron mean free path. In an embodiment, the total pressure is about 0.5 to about 5 Torr and the mean electron free path is about 0.1 cm to 1 cm. In an embodiment, the dimensions of the cell are greater than the electron mean free path.

In an embodiment, the cavity is at least one of the group of a reentrant cavity such as an Evenson cavity, Beenakker, McCarrol, and cylindrical cavity. In an embodiment, the cavity provides a strong electromagnetic field which may form a nonthermal plasma. The strong electromagnetic field may be due to a TM₀₁₀ mode of a cavity such as a Beenakker cavity. In a preferred embodiment, the cavity provides an E mode rather than an M mode. In a preferred embodiment, the cavity is a reentrant cavity such as an Evenson cavity that forms a plasma with an E mode. Multiple sources of microwave power may be used simultaneously. For example, the microwave plasma such as a nonthermal plasma may be maintained by multiple Evenson cavities operated in parallel to form the plasma in the microwave cell 601. The cell may be cylindrical and may comprise a quartz cell with Evenson cavities spaced along the longitudinal axis. In another embodiment, a multi slotted antenna such as a planar antenna serves as the equivalent of multiple sources of microwaves such as dipole-antenna-equivalent sources. One such embodiment is given in Y. Yasaka, D. Nozaki, M. Ando, T. Yamamoto, N. Goto, N. Ishii, T. Morimoto, “Production of large-diameter plasma using multi-slotted planar antenna,” Plasma Sources Sci. Technol., Vol. 8, (1999), pp. 530-533 which is incorporated herein by reference in its entirety.

In an embodiment, of the hydrogen microwave power and plasma cell and reactor, the output power is optimized by using a cavity such as a reentrant cavity such as an Evenson cavity and tuning the cell to an optimal voltage staging wave. In an embodiment, the reflected versus input power is tuned such that a desired voltage standing wave is obtained which optimizes or controls the output power. Typically, the ratio of the maximum voltage to the minimum voltage on the transmission line determines the voltage standing wave. In another embodiment, the cell comprises a tunable microwave cavity having a desired voltage standing wave to optimize and control the output power.

The cell may further comprise a magnet such a solenoidal magnet 607 to provide an axial magnetic field. The ions such as electrons formed by the hydrogen catalysis reaction produce microwaves to at least partially maintain the microwave discharge plasma. The microwave frequency may be selected to efficiently form atomic hydrogen from molecular hydrogen. It may also effectively form ions that serve as catalysts from a source of catalyst such as He⁺, Ne⁺, Ne⁺/H⁺, or Ar⁺ catalysts from helium, neon, neon-hydrogen mixtures, and argon gases, respectively.

The microwave frequency is preferably in the range of about 1 MHz to about 100 GHz, more preferably in the range about 50 MHz to about 10 GHz, most preferably in the range of about 75 MHz±50 MHz or about 2.4 GHz±1 GHz.

A vacuum pump 610 may be used to evacuate the chamber 660 through vacuum lines 648 and 650. The cell may be operated under flow conditions with the hydrogen and the catalyst supplied continuously from catalyst source 612 and hydrogen source 638. The amount of gaseous catalyst may be controlled by controlling the plasma gas flow rate where the plasma gas includes a hydrogen and a source of catalyst (e.g., hydrogen and argon or helium). The amount of gaseous hydrogen atoms to the plasma may be controlled by controlling the hydrogen flow rate and the ratio of hydrogen to plasma gas in the mixture. The hydrogen flow rate and the plasma gas flow rate to the hydrogen-plasma-gas mixer and mixture flow regulator 621 are controlled by flow rate controllers 634 and 644, and by valves 636 and 646. Mixer regulator 621 controls the hydrogen-plasma mixture to the chamber 660. The catalysis rate is also controlled by controlling the temperature of the plasma with microwave generator 624.

Catalysis may occur in the gas phase. Hydrino atoms, dihydrino molecular ions, dihydrino molecules, and hydrino hydride ions are produced in the plasma 604. Dihydrino molecules and hydrino hydride compounds such as α—SiH(1/p) may be cryopumped onto the wall 606, or they may flow into a 608 such as a cryotrap through passage 648. Trap 608 communicates with vacuum pump 610 through vacuum line 650 and valve 652. A flow to the trap 608 can be effected by a pressure gradient controlled by the vacuum pump 610, vacuum line 650, and vacuum valve 652.

In another embodiment of the hydrogen microwave reactor shown in FIG. 1, the wall 606 has a catalyst supply passage 656 for passage of the gaseous catalyst from a catalyst reservoir 658 to the plasma 604. The catalyst in the catalyst reservoir 658 can be heated by a catalyst reservoir heater 666 having a power supply 668 to provide the gaseous catalyst to the plasma 604. The catalyst vapor pressure can be controlled by controlling the temperature of the catalyst reservoir 658 by adjusting the heater 666 with its power supply 668. The catalyst in the gas phase may comprise those given in TABLES 1 and 3 of my prior PCT Appl. No. PCT/US02/06945 filed November 2002, hydrinos, and those described in the Mills Prior Publication.

A source of silicon may also be delivered to the reaction by the same means and methods as the catalyst, hydrogen, and plasma gas such that increased binding energy hydrogen species react with silicon to form α—SiH(1/p).

In another embodiment of the hydrogen microwave reactor, a chemically resistant open container such as a ceramic boat located inside the chamber 660 contains the catalyst. The reactor further comprises a heater that may maintain an elevated temperature. The cell can be operated at an elevated temperature such that the catalyst in the boat is sublimed, boiled, or volatilized into the gas phase. Alternatively, the catalyst in the catalyst boat can be heated with a boat heater having a power supply to provide the gaseous catalyst to the plasma. The catalyst vapor pressure can be controlled by controlling the temperature of the cell with a cell heater, or by controlling the temperature of the boat by adjusting the boat heater with an associated power supply. A source of silicon may also be delivered to the reaction by the same means and methods as the catalyst such that increased binding energy hydrogen species react with silicon to form α—SiH(1/p).

In an embodiment, the hydrogen microwave reactor further comprises a structure interact with the microwaves to cause localized regions of high electric and/or magnetic field strength. A high magnetic field may cause electrical breakdown of the gases in the plasma chamber 660. The electric field may form a nonthermal plasma that increases the rate of catalysis by methods such as the formation of the catalyst from a source of catalyst. The source of catalyst may be argon, neon-hydrogen mixture, helium to form He⁺, Ne⁺, and Ar⁺, respectively. The structures and methods are equivalent to those given in the Plasma Torch Cell Hydride Reactor section of my previous PCT Appl. No. PCT/US02/35872 filed March 2002.

The nonthermal plasma temperature corresponding to the energetic ion and/or electron temperature as opposed to the relatively low energy thermal neutral gas temperature in the microwave cell reactor is advantageously maintained in the range of about 5,000-5,000,000° C. The cell may be operated without heating or insulation. Alternatively, in the case that the catalyst has a low volatility, the cell temperature is maintained above that of the catalyst source, catalyst reservoir 658 or catalyst boat to prevent the catalyst from condensing in the cell. The operating temperature depends, in part, on the nature of the material comprising the cell. The temperature for a stainless steel alloy cell is preferably about 0-1200° C. The temperature for a molybdenum cell is preferably about 0-1800° C. The temperature for a tungsten cell is preferably about 0-3000° C. The temperature for a glass, quartz, or ceramic cell is preferably about 0-1800° C.

The molecular and atomic hydrogen partial pressures in the chamber 660, as well as the catalyst partial pressure, is preferably maintained in the range of about 1 mtorr to about 100 atm. Preferably the pressure is in the range of about 100 mtorr to about 1 atm, more preferably the pressure is about 100 mtorr to about 20 torr.

An exemplary plasma gas for the hydrogen microwave reactor is argon. Exemplary flow rates are about 0.1 standard liters per minute (slm) hydrogen and about 1 slm argon. An exemplary forward microwave input power is about 1000 W. The flow rate of the plasma gas or hydrogen-plasma gas mixture such as at least one gas selected for the group of hydrogen, argon, helium, argon-hydrogen mixture, helium-hydrogen mixture, water vapor, ammonia is preferably about 0-1 standard liters per minute per cm³ of vessel volume and more preferably about 0.001-10 sccm per cm³ of vessel volume. In the case of an helium-hydrogen, neon-hydrogen, or argon-hydrogen mixture, preferably helium, neon, or argon is in the mole percentage range of about 99 to about 1%, more preferably about 99 to about 95%. The power density of the source of plasma power is preferably in the range of about 0.01 W to about 100 W/cm³ vessel volume.

In other embodiments of the microwave reactor, the catalyst may be agitated and supplied through a flowing gas stream such as the hydrogen gas or plasma gas which may be an additional source of catalyst such as helium or argon gas. The source of catalyst may also be provided by an aspirator, atomizer, or nebulizer to form an aerosol of the source of catalyst. The catalyst which may become an aerosol may be dissolved or suspended in a liquid medium such as water. The medium may be contained in the catalyst reservoir 614. Alternatively, the aspirator, atomizer, or nebulizer may inject the source of catalyst or catalyst directly into the plasma 604. In another embodiment, the nebulized or atomized catalyst may be carried into the plasma 604 by a carrier gas, such as hydrogen, helium, neon, or argon where the helium, neon-hydrogen, or argon may be ionized to He⁺, Ne⁺, or Ar⁺, respectively, and serve as hydrogen catalysts.

Atomic hydrogen may serve as the catalyst according to Eqs. (30-32) of my previous PCT Appl. No. PCT/US02/06945 filed November 2002. In an embodiment the catalysis of atomic hydrogen to form increased-binding-energy-hydrogen species is achieved with a hydrogen plasma. The cavity may be reentrant cavity such as an Evenson cavity. The hydrogen pressure may be in the range of about 1 mtorr to about 100 atm. Preferably the pressure is in the range of about 100 mtorr to about 1 atm, more preferably the pressure is about 100 mtorr to about 10 torr. The microwave power density may be in the range of about 0.01 W to about 100 W/cm³ vessel volume. The hydrogen flow rate may be in the range of about 0-1 standard liters per minute per cm³ of vessel volume and more preferably about 0.001-10 sccm per cm³ of vessel volume.

The hydrogen microwave reactor further includes an electron source in contact with the hydrinos, for generating hydrino hydride ions. In the cell, the hydrinos may be reduced to hydrino hydride ions by contacting a reductant extraneous to the operation of the cell (e.g. a consumable reductant added to the cell from an outside source). In an embodiment, the microwave cell reactor further comprise a selective valve 618 for removal of lower-energy hydrogen products such as dihydrino molecules. Compounds comprising a hydrino hydride anion and a cation may be formed in the gas cell. The cation which forms the hydrino hydride compound may comprise a cation of other element, a cation of an oxidized added reductant, or a cation present in the plasma (such as a cation of the catalyst).

2. Capacitively and Inductively Coupled RF Plasma Gas Cell Hydride and Power Reactor

According to an embodiment of the invention, a reactor for producing power and at least one of hydrinos, hydrino hydride ions, dihydrino molecular ions and dihydrino molecules that react with a source of silicon to form α—SiH(1/p) may take the form of a capacitively or inductively coupled RF plasma cell hydride reactor. A RF plasma cell hydride reactor of the present invention is also shown in FIG. 1. The cell structures, systems, catalysts, and methods may be the same as those given for the microwave plasma cell reactor except that the microwave source may be replaced by a RF source 624 with an impedance matching network 622 that may drive at least one electrode and/or a coil. The RF plasma cell may further comprise two electrodes 669 and 670. The coaxial cable 619 may connect to the electrode 669 by coaxial center conductor 615. Alternatively, the coaxial center conductor 615 may connect to an external source coil which is wrapped around the cell 601 which may terminate without a connection to ground or it may connect to ground. The electrode 670 may be connected to ground in the case of the parallel plate or external coil embodiments. The parallel electrode cell may be according to the industry standard, the Gaseous Electronics Conference (GEC) Reference Cell or modification thereof by those skilled in the art as described in G A. Hebner, K. E. Greenberg, “Optical diagnostics in the Gaseous electronics Conference Reference Cell, J. Res. Natl. Inst. Stand. Technol., Vol. 100, (1995), pp. 373-383; V. S. Gathen, J. Ropcke, T. Gans, M. Kaning, C. Lukas, H. F. Dobele, “Diagnostic studies of species concentrations in a capacitively coupled RF plasma containing CH₄—H₂—Ar,” Plasma Sources Sci. Technol., Vol. 10, (2001), pp. 530-539; P. J. Hargis, et al., Rev. Sci. Instrum., Vol. 65, (1994), p. 140; Ph. Belenguer, L. C. Pitchford, J. C. Hubinois, “Electrical characteristics of a RF-GD-OES cell,” J. Anal. At. Spectrom., Vol. 16, (2001), pp. 1-3 which are herein incorporated by reference in their entirety. The cell which comprises an external source coil such as a 13.56 MHz external source coil microwave plasma source is as given in D. Barton, J. W. Bradley, D. A. Steele, and R. D. Short, “investigating radio frequency plasmas used for the modification of polymer surfaces,” J. Phys. Chem. B, Vol. 103, (1999), pp. 4423-4430; D. T. Clark, A. J. Dilks, J. Polym. Sci. Polym. Chem. Ed., Vol. 15, (1977), p. 2321; B. D. Beake, J. S. G. Ling, G. J. Leggett, J. Mater. Chem., Vol. 8, (1998), p. 1735; R. M. France, R. D. Short, Faraday Trans. Vol. 93, No. 3, (1997), p. 3173, and R. M. France, R. D. Short, Langmuir, Vol. 14, No. 17, (1998), p. 4827 which are herein incorporated by reference in their entirety. At least one wall of the cell 601 wrapped with the external coil is at least partially transparent to the RF excitation. The RF frequency is preferably in the range of about 100 Hz to about 100 GHz, more preferably in the range about 1 kHz to about 100 MHz, most preferably in the range of about 13.56 MHz±50 MHz or about 2.4 GHz±1 GHz.

In another embodiment, an inductively coupled plasma source is a toroidal plasma system such as the Astron system of Astex Corporation described in U.S. Pat. No. 6,150,628 which is herein incorporated by reference in its entirety. In an embodiment, the field strength is high to cause a nonthermal plasma. The toroidal plasma system may comprise a primary of a transformer circuit. The primary may be driven by a radio frequency power supply. The plasma may be a closed loop which acts at as a secondary of the transformer circuit. The RF frequency is preferably in the range of about 100 Hz to about 100 GHz, more preferably in the range about 1 kHz to about 100 MHz, most preferably in the range of about 13.56 MHz±50 MHz or about 2.4 GHz±1 GHz.

3. SiH(1/p) Synthesis

A reactor of the present invention for the synthesis of silicon hydride SiH(1/p) comprising increased binding energy hydrogen species in crystalline or as amorphous material such thin films comprises a hydrino hydride reactor and a source of silicon. The silicon may be at least one of the group of solid silicon, silane, SiₙH₂ₙ₊₂ (1<n<100), siloxanes, or other silicon containing compounds such as those given in the CRC or in Cotton [David R. Lide, CRC Handbook of Chemistry and Physics, 79 th Edition, CRC Press, Boca Raton, Fla., (1998-9), p. 4-82 to p. 4-83 and F. A. Cotton, G. Wilkinson, Advanced Inorganic Chemistry, Fourth Edition, John Wiley & Sons, New York which are herein incorporated by reference]. In an embodiment, the silicon or silicon precursor is supplied as a solid to the reactor such as the reactor 601 shown in FIG. 1. The solid may be placed in the reactor cell 660, and the hydrogen catalysis reaction is carried with the silicon present. In another embodiment, the source of silicon is supplied as a gas from a gas supply line 626. In another embodiment, silicon is vapor deposited on a desired target such as a substrate in the presence of the hydrogen catalysis reaction. Silicon and silicon precursors such as silanes may supplied to the hydrogen catalysis reaction to form SiH(1/p) by methods known to those skilled in the art such as by ion implantation, epitaxy, or vacuum deposition. Apparatus and methods of ion implantation, epitaxy, and vacuum deposition such as those used by persons skilled in the art are described in the following references which are incorporated herein by reference: Fadei Komarov, Ion Beam Modification of Metals, Gordon and Breach Science Publishers, Philadelphia, 1992, especially pp.-1-37.; Emanuele Rimini, Ion Implantation: Basics to Device Fabrication, Kluwer Academic Publishers, Boston, 1995, especially pp. 33-252; 315-348; 173-212; J. F. Ziegler, (Editor), Ion Implantation Science and Technology, Second Edition, Academic Press, Inc., Boston, 1988, especially pp. 219-377.

The catalyst may be one or more molecules wherein the energy to break the molecular bond and the ionization of t electrons from an atom from the dissociated molecule to a continuum energy level is such that the sum of the ionization energies of the t electrons is approximately m·27.2±0.5 eV where m is an integer or m/2·27.2±0.5 eV where m is an integer greater than one and t is an integer. The catalyst may comprise at least one of C₂, N₂, O₂, CO₂, NO₂, and NO₃. In another embodiment, the catalytic system is provided by the ionization of t electrons from a participating species such as an atom, an ion, a molecule, an ionic or molecular compound, and an excimer to a continuum energy level such that the sum of the ionization energies of the t electrons is approximately m·27.2±0.5 eV where m is an integer or m/2·27.2±0.5 eV where m is an integer greater than one and t is an integer. The catalyst may be selected from the group of atom, ion, or excimer selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He³⁰ , Na⁺, Rb⁺, Sr⁺, Fe³⁺, Mo²⁺, Mo⁴⁺, In³⁺, He³⁰ , Ne⁺, Ar⁺, Xe⁺, H, H(1/p), Ar²⁺ and H⁺, and Ne⁺ and H⁺, Ne₂ *, and He₂ *. In another embodiment, the catalyst is provided by the transfer of t electrons between participating ions; the transfer of t electrons from one ion to another ion provides a net enthalpy of reaction whereby the sum of the ionization energy of the electron donating ion minus the ionization energy of the electron accepting ion equals approximately m·27.2±0.5 eV where m is an integer or m/2·27.2±0.5 eV where m is an integer greater than one and t is an integer.

A preferred embodiment comprises a microwave plasma cell wherein a catalyst of atomic hydrogen capable of providing a net enthalpy of reaction of m·27.2±0.5 eV where m is an integer or m/2·27.2±0.5 eV where m is an integer greater than one and capable of forming a hydrogen atom having a binding energy of about

$$\frac{13.6 e V}{{( \frac{1}{p} )}^{2}}$$

where p is an integer wherein the net enthalpy is provided by the breaking of a molecular bond of the catalyst and the ionization of t electrons from an atom of the broken molecule each to a continuum energy level such that the sum of the bond energy and the ionization energies of the t electrons is approximately m/2·27.2±0.5 eV where m is an integer greater than one and t is an integer. The catalyst may comprise at least one of C₂, N₂, O₂, CO₂, NO₂, and NO₃. The catalyst may further comprise one atom or ion selected from the group of atom, ion, or excimer selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He⁺, Na⁺, Rb⁺, Sr⁺, Fe³⁺, Mo²⁺, Mo⁴⁺, In³⁺, He⁺, Ne⁺, Ar⁺, Xe⁺, H, H(1/p), Ar²⁺ and H⁺, and Ne⁺ and H⁺, Ne₂ *, and He₂ *. A catalyst may comprise a molecule in combination with an atom, ion, or excimer catalyst. The catalyst combination may comprise at least one molecule selected from the group of C₂, N₂, O₂, CO₂, NO₂, and NO₃ in combination with at least one atom or ion selected from the group of atom, ion, or excimer selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He⁺, Na⁺, Rb⁺, Sr⁺, Fe³⁺, Mo²⁺, Mo⁴⁺, In³⁺, He⁺, Ne⁺, Ar⁺, Xe⁺, H, H(1/p), Ar²⁺ and H⁺, and Ne⁺ and H⁺, Ne₂ *, He₂ *.

In an embodiment, the formation of SiH(1/p) films occurs by vapor deposition of silicon in the presence of a catalyst-hydrogen plasmas such as a helium-hydrogen plasma or an argon-hydrogen plasma wherein He⁺ or Ar⁺ serves as a catalyst, respectively. The catalysis reaction forms increased binding energy hydrogen species which react with the silicon in the gas phase or on the substrate. In a preferred embodiment, SiH(1/p) films are formed on a substrate by the reaction of silicon from silane, SiₙH₂ₙ₊₂, or a silicon compound with increased binding energy species formed in a helium-hydrogen plasma or an argon-hydrogen plasma wherein He⁺ or Ar⁺ serves as a catalyst, respectively. The reaction may occur in the gas phase followed by substrate deposition of SiH(1/p), or the silicon or silicon precursors may deposit on the substrate followed by reaction with increased binding energy hydrogen species.

In an embodiment, the silicon or silicon precursor deposition rate is in the range of 1 Å/hr to 100 cm/hr. More preferably, the silicon or silicon precursor deposition rate is in the range of 10 Å/hr to 10 cm/hr. Most preferably, the silicon or silicon precursor deposition rate is in the range of 100 Å/hr to 1 mm/hr. The catalyst, hydrogen, and cell parameters are as disclosed previously for production of increased binding energy compounds.

In an embodiment, the substrate temperature is maintained in the range of about 0-3000 ° C., more preferably about 100-1000° C., and most preferably about 100-500° C.

In another embodiment, the source of silicon is supplied as a gas from a gas supply line. The source of silicon may be silane, SiₙH₂ₙ₊₂ (1<n<100), siloxanes, or other silicon containing compounds. In a preferred embodiment, the silicon compound is silane. In an embodiment of the reactor shown in FIG. 1 to form SiH(1/p), the plasma gas and catalyst gas may be supplied by a mixture from a source 638, and a source of silicon may be supplied from a source 612. The gasses and be mixed at controlled ratios by mixer and flow controller 621 and supplied to the plasma 604 by a line 626. The substrate 675 is coated with SiH(1/p). In an alternative embodiment, the substrate is oriented parallel to the axis of the reactor cell 669 rather than perpendicularly as shown in FIG. 1.

The silicon or silicon compound, molecular and atomic hydrogen partial pressures, as well as the catalyst partial pressure, is preferably maintained in the range of about 1 mtorr to about 100 atm. Preferably, the pressure is in the range of about 100 mtorr to about 1 atm, more preferably the pressure is about 100 mtorr to about 20 torr. The catalyst gas may be selected from neon, argon, helium, or mixtures thereof.

The flow rate of the catalyst gas, hydrogen-catalyst gas mixture, silicon compound gas, hydrogen-silicon compound gas mixture, hydrogen-silicon compound-catalyst gas mixture, or silicon compound-catalyst gas mixture is preferably about 0.0001-1 standard liters per minute per cm³ of vessel volume and more preferably about 0.001-10 sccm per cm³ of vessel volume, most preferably 0.1-10 sccm per cm³ of vessel volume.

In an embodiment, the silicon or silicon compound gas is the molar percentage composition range of about 0.01-99% and the balance is due to catalyst-hydrogen gas mixture which is present in the relative amounts that achieves hydrogen catalysis as disclosed previously. More preferably, the silicon or silicon compound gas is in the molar percentage composition range of about 0.1-10% and the balance is due to hydrogen-catalyst gas. Most preferably, the silicon or silicon compound gas is in the range of about 0.5-5% and the balance is due to hydrogen-catalyst gas mixture. In an embodiment, the catalyst-hydrogen gas mixture added to the silicon or silicon compound gas comprises a catalyst gas molar percentage composition range of about 0.01 to 99.90%, and the balance is hydrogen. More preferably, the catalyst-hydrogen gas mixture added,to the silicon or silicon compound gas comprises a catalyst gas molar percentage composition range of about 10 to 99.9%, and the balance is hydrogen. Most preferably, the catalyst-hydrogen gas mixture added to the silicon or silicon compound gas comprises a catalyst gas molar percentage composition range of about 50 to 99.9%, and the balance is hydrogen.

An exemplary catalyst gas for the microwave cell reactor is helium, neon, or argon. Exemplary flow rates for 10 cm of plasma reaction volume are about 0.1-100 standard cubic centimeters per minute (sccm) hydrogen, about 0.1-100 sccm silane, and about 10-1000 sccm helium, neon, or argon, and an exemplary microwave input power is about 10-500 W, and an exemplary pressure range is about 10 mTorr-10 Torr.

In an embodiment of a silane-helium-hydrogen mixture, silane-neon-hydrogen mixture, or silane-argon-hydrogen, helium, neon, or argon is in the mole percentage range of about 50 to about 99%, more preferably about 80 to about 99%, and hydrogen and silane make up the balance. In an embodiment the plasma mixture comprises SiH₄ (0.1-5%)/He (90-99.8%)/H₂ (0.1-5%). In an embodiment the plasma mixture comprises SiH₄ (0.1-5%)/Ne (90-99.8%)/H₂ (0.1-5%). In an embodiment the plasma mixture comprises SiH₄ (0.1-5%)/Ar (90-99.8%)/H₂ (0.1-5%). The power density of the source of plasma power is preferably in the range of about 0.01 W to about 100 W/cm³ vessel volume. The flow rate of the plasma gas mixture may be in the range of about 0.1-50 sccm per cm³ of vessel volume. An exemplary pressure range is about 10 mTorr-10 Torr.

Substrates such as silicon wafers, metals, plastics, aluminum, some glasses, nickel, steel and electronics materials such as GaAs may be coated by placing the substrate in the reactor during SiH(1/p) formation such that the SiH(1/p) material is deposited onto the substrate.

The plasma may be a catalyst-hydrogen plasma. The plasma cell may be at least one of a gas cell, gas discharge cell, microwave cell, inductively or capacitive coupled RF cell, multicusp cell, RF barrier electrode discharge cell, and filament or rt-plasma cell for example. The source of silicon may be by sputter vapor deposition from a solid source by the plasma of the reactor cell or a separate silicon source cell. In an embodiment, the formation of SiH(1/p) and related materials may be by vapor deposition of silicon in the presence of a neon-hydrogen plasma, helium-hydrogen plasma, or an argon-hydrogen plasma wherein Ne⁺, He⁺, or Ar⁺ serves as a catalyst, respectively.

In an embodiment, the formation of SiH( 1/p) and related materials may be by the deposition of silicon from a silicon compound in the presence of a neon-hydrogen plasma, helium-hydrogen plasma, or an argon-hydrogen plasma wherein Ne⁺, He⁺, or Ar⁺ serves as a catalyst, respectively. Preferably the silicon compound is Si₃ H₈. More preferably, the silicon compound is disilane. Most preferably, the silicon compound is silane. The cell may be maintained in normal the pressure range to achieve hydrogen catalysis given previously such as in the range 1 millitorr to about one atmosphere.

In an embodiment, SiH₄ gas is introduced into a reservoir by a gas/vacuum line where it is mixed with premixed He (95-99.9%)/H₂ (0.1-5%), Ne (95-99.9%)/H₂ (0.1-5%), or Ar (95-99.9%)/H₂ (0.1-5%) to obtain the reaction mixture SiH₄ (0.1-5%)/He (90-99.8%)/H₂ (0.1-5%), SiH₄ (0.1-5%)/Ne (90-99.8%)/H₂ (0.1-5%), or SiH₄ (0.1-5%)/Ar (90-99.8%)/H₂ (0.1-5%), respectively, by controlling the individual gas pressures. In a preferred embodiment, the SiH₄ gas is introduced into a reservoir by a gas/vacuum line where it was mixed with premixed He(99%)/H₂ (1%), Ne(99%)/H₂ (1%), or Ar(99%)/H₂ (1%) to obtain the reaction mixture SiH₄ (2.5%)/He (96.6%)/H₂ (0.9%), SiH₄ (2.5%)/Ne (96.6%)/H₂ (0.9%, or SiH₄ (2.5%)/Ar (96.6%)/H₂ (0.9%), respectively, by controlling the individual gas pressures.

### EXPERIMENTAL

A novel highly stable silicon hydride (SiH(1/p)) surface coating which comprised high binding energy hydride ions was synthesized by a microwave plasma reaction of a mixture of silane, hydrogen, and helium wherein He⁺ served as a catalyst with atomic hydrogen to form the highly stable hydride ions. Novel silicon hydride was identified by time of flight secondary ion mass spectroscopy and X-ray photoelectron spectroscopy. The time of flight secondary ion mass spectroscopy (ToF-SIMS) identified the coatings as hydride by the large SiH⁺ peak in the positive spectrum and the dominant H⁻ in the negative spectrum. X-ray photoelectron spectroscopy (XPS) identified the H content of the SiH coatings as hydride ions, H⁻(¼), H⁻(1/9), and H⁻(1/11) corresponding to peaks at 11, 43, and 55 eV, respectively. The silicon hydride surface was remarkably stable to air as shown by XPS. The highly stable amorphous silicon hydride coating may advance the production of integrated circuits and microdevices by resisting the oxygen passivation of the surface and possibly altering the dielectric constant and band gap to increase device performance.

The plasma which formed SiH(1/p) showed a number of extraordinary features. Novel emission lines with energies of q·13.6 eV where q=1,2,3,4,6,7,8,9, or 11 were previously observed by extreme ultraviolet (EUV) spectroscopy recorded on microwave discharges of helium with 2% hydrogen [R. Mills, P. Ray, “Spectral Emission of Fractional Quantum Energy Levels of Atomic Hydrogen from a Helium-Hydrogen Plasma and the Implications for Dark Matter”, Int. J. Hydrogen Energy, Vol. 27, No. 3, pp. 301-322]. These lines matched H(1/p), fractional Rydberg states of atomic hydrogen where p is an integer, formed by a resonant nonradiative energy transfer to He⁺ acting as a catalyst. The average hydrogen atom temperature of the helium-hydrogen plasma was measured to be 180-210 eV versus ≈3 eV for pure hydrogen. Using water bath calorimetry, excess power was observed from the helium-hydrogen plasma compared to control krypton plasma. For example, for an input of 8.1 W, the total plasma power of the helium-hydrogen plasma measured by water bath calorimetry was 30.0 W corresponding to 21.9 W of excess power in 3 cm³. The excess power density and energy balance were high, 7.3 W/cm³ and −2.9×10⁴ kJ/mole H₂, respectively. This catalytic plasma reaction may represent a new hydrogen energy source and a new field of hydrogen chemistry.

The energetic catalytic reaction of hydrogen in a helium plasma was characterized by measuring the line broadening and intensity of the 656.3 nm Balmer α line to determine the excited hydrogen atom energy and H concentration and the power balance using water bath calorimetry on helium-hydrogen plasmas compared to krypton control plasmas. The catalytic plasma reaction was used to synthesize a novel amorphous silicon hydride surface coating designated α—SiH(1/p). Silane was reacted in a helium-hydrogen microwave discharge plasma at the surface of a nickel foil. After the plasma reaction processing, the surface was characterized by ToF-SIMS and XPS. Aqueous HF acid etched silicon surfaces were found to rapidly oxidized when exposed to air and provided little protection from such exposure; whereas, the novel α—SiH(1/p) identified as having high-binding-energy hydride ions was extremely stable to air. The novel α—SiH(1/p) film may advance semiconductor fabrication and devices.

Line Broadening Measurements

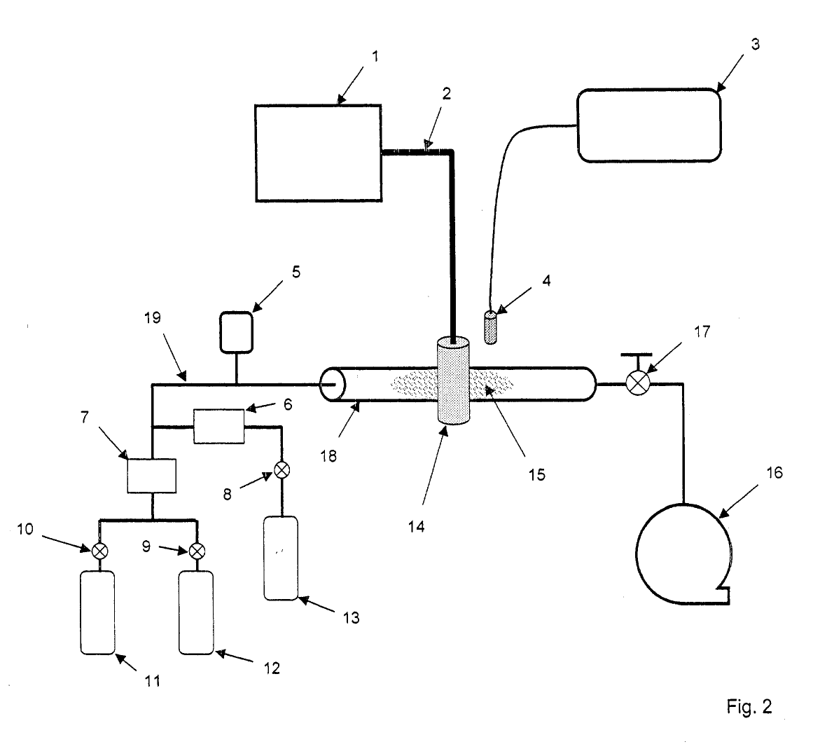

The widths of the 656.3 nm Balmer α and 486.1 nm Balmer β lines emitted from hydrogen, xenon-hydrogen (90/10%), or helium-hydrogen mixture (90/10%) microwave discharge plasmas were measured according to the methods given previously [21, 32]. The experimental set up comprising a microwave discharge gas cell light source is shown in FIG. 2. Each ultrapure gas alone or mixture was flowed through a half inch diameter quartz tube at 1 Torr. The gas pressure to the cell was maintained by flowing the mixture while monitoring the pressure with a 10 torr and 1000 torr MKS Baratron absolute pressure gauge. The tube was fitted with an Opthos coaxial microwave cavity (Evenson cavity). The microwave generator was an Opthos model MPG-4M generator (Frequency: 2450 MHz). The input power to the plasma was set at 40 W. The plasma emission was fiber-optically coupled through a 220F matching fiber adapter positioned 2 cm from the cell wall to a high resolution visible spectrometer with a resolution of ±0.006 nm over the spectral range 190-860 nm. The spectrometer was a Jobin Yvon Horiba 1250 M with 2400 groves/mm ion-etched holographic diffraction grating. The entrance and exit slits were set to 20 μm. The spectrometer was scanned between 485.9-486.4 nm and 655.5-657 nm using a 0.005 nm step size. The signal was recorded by a PMT with a stand alone high voltage power supply (950 V) and an acquisition controller. The data was obtained in a single accumulation with a 1 second integration time. The electron density was determined using a Langmuir probe according to the method given previously [79].

The method of Videnovic et al. [80] and Griem [81] was used to calculate the energetic hydrogen atom energies from the width of the 656.28 nm Balmer α line emitted from hydrogen and noble gas-hydrogen microwave plasmas as described previously [21, 32]. The full half-width Δλ_{G} of each Gaussian results from the Doppler (Δλ_{D}) and instrumental (Δλ_{I}) half-widths:

Δλ_{G}=\sqrt{Δλ_{D}²+Δλ_{I}²} (11)

where Δλ_{I} in our experiments was ±0.006 nm. The temperature was calculated from the Doppler half-width using the formula:

$${Δλ}_{D} = 7.16 \times {10}^{- 6} {{λ}_{0} ( \frac{T}{μ} )}^{1 / 2} ( Å ) \qquad ( 12 )$$

where λ₀ is the line wavelength in Å, T is the temperature in K (1 eV=11,605 K), and μ is the molecular weight (=1 for hydrogen). In each case, the average Doppler half-width that was not appreciably changed with pressure varied by ±5% corresponding to an error in the energy of±10%. The corresponding number densities varied by±10%.

The method of Sultan et al. [82] was used to calculate the hydrogen atom densities from the intensities of the 656.28 nm Balmer α line emitted from hydrogen and noble gas-hydrogen microwave plasmas as described previously [21, 32]. The absolute density of n=3 was measured as given below, then the H number density for n=1 was estimated by the following equation which is in good agreement with the evolution equations of Sultan et al. [82]:

$$\frac{[ H ( n = 3 ) ]}{[ H ( n = 1 ) ]} = \frac{{g}_{3}}{{g}_{1}} exp ( - Δ E / kT ) \qquad ( 13 )$$

where the degeneracy g is given by g=2n² (n is the principal quantum number) and kT≈1 eV. The number densities for noble gas-hydrogen mixtures varied by ±20% depending on the pressure.

To measure the absolute intensity, the high resolution visible spectrometer and detection system were calibrated [83] with 546.08 nm, 579.96 nm, and 696.54 nm light from a Hg—Ar lamp (Ocean Optics, model HG-1) that was calibrated with a NIST certified silicon photodiode. The population density of the n=3 hydrogen excited state N₃ was determined from the absolute intensity of the Balmer α (656.28 nm) line measured using the calibrated spectrometer. The spectrometer response was determined to be approximately flat in the 400-700 nm region by ion etching and with a tungsten intensity calibrated lamp.

Calorimetry

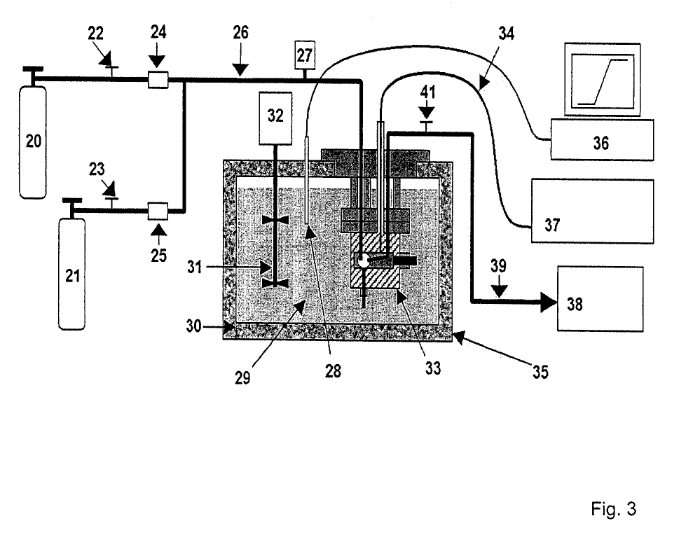

The excess power was measured by water bath calorimetry on helium-hydrogen (90/10%) plasmas compared to krypton plasma with the same input power. The plasmas were maintained in a microwave discharge cell shown in FIG. 3. Each gas was ultrahigh pure. Each pure test gas was flowed through a half inch diameter quartz tube at 500 mTorr maintained with a noble gas or hydrogen flow rate of 10 sccm. After the calorimeter had reached a steady state, the pressure of the helium-hydrogen mixture was changed to 0.29 torr. Each gas flow was controlled by a 0-20 sccm range mass flow controller (MKS 1179A21CS1BB) with a readout (MKS type 246). The cell pressure was monitored by a 0-10 Torr MKS Baratron absolute pressure gauge. The tube was fitted with an Evenson coaxial microwave cavity (Opthos) having an E-mode [84-85]. The microwave generator shown in FIG. 3 was an Opthos model MPG-4M generator (Frequency: 2450 MHz).

The Evenson cavity and a plasma-containing section of the quartz tube were fitted with a water-tight stainless steel housing shown in FIG. 3. The housing comprised a 4×4×2 cm rectangular enclosure welded to a set of high vacuum 15.24 cm diameter conflat flanges. A silver plated copper gasket was placed between a mating flange and the cell flange. The two flanges were clamped together with 10 circumferential bolts. The top mating flange contained two penetrations comprising 1.) a stainless steel thermocouple well (1 cm OD) housing a thermocouple probe in the cell interior that was in contact with the quartz tube wall adjacent to the Evenson cavity and 2.) a centered 2.54 cm OD coaxial cable housing. The 1.27 cm OD quartz tube was sealed at its penetrations with the rectangular housing by Ultratorr fittings. The housing and cell assembly was suspended by 4 support rods from an 5.1 cm thick acrylic plate which held the cell vertically from the top of a water bath calorimeter shown in FIG. 3. The plate contained four sealed penetrations comprising 1.) the stainless steel thermocouple well 2.) a 1 cm OD noble or hydrogen gas line, 3.) a 1 cm OD vacuum line, and 4.) the 2.54 cm OD coaxial cable housing. The gas inlet connected to a 0.64 cm OD flexible stainless steel tube that was connected by an Ultratorr seal to a welded-in 0.63 cm OD penetration of the rectangular enclosure. Inside of the enclosure, the penetration connected to the quartz tube by a 0.63-to-1.27 cm OD mating Ultratorr seal. The quartz tube had an elbow at the end opposite to the gas inlet penetration which attached to a 1 cm OD flexible stainless steel tube section of the vacuum line. The microwave cavity contained in the rectangular enclosure was tuned by a threaded tuning stub sealed in an end wall of the enclosure and a sliding tuning stub sealed with an Ultratorr fitting in the bottom wall. The sliding stub was tightened after the cell was tuned outside of the water bath, and the cell was immersed.

The water bath comprised an insulated reservoir filled with 45 liters of distilled water. The water was agitated with a paddle driven by a stirring motor. A high precision linear response thermistor probe (Omega OL-703) recorded the temperature of the water bath as a function of time for the stirrer alone to establish the baseline. The water bath was calibrated by a high precision heater (Watlow 125CA65A2X, with a Xantrex DC power supply 0-1200±0.01 W). The heat capacity was determined for several input powers, 30, 40, and 50 W±0.01 W, and was found to be independent of input power over this power range within ±0.05%. The temperature rise of the reservoir as a function of time gave a slope in ° C./s. This slope was baseline corrected for the negligible stirrer power and loss to ambient. The constant known input power (J/s), was divided by this slope to give the heat capacity in J/° C. Then, in general, the total power output from the cell to the reservoir was determined by multiplying the heat capacity by the rate of temperature rise (° C./s) to give J/s.

Since the cell and water bath system were adiabatic, the general form of the power balance equation is:

Pᵢₙ+Pₑₓ−Pₒᵤₜ=0 (14)

where Pᵢₙ is the microwave input power, Pₑₓ is the excess power generated from the hydrogen catalysis reaction, and Pₒᵤₜ is the thermal power loss from the cell to the water bath. The cell typically reached steady state in about 10 minutes after each experiment was started. At this point, the power lost from the cell Pₒᵤₜ was equal to the power supplied to the cell, Pᵢₙ, plus any excess power Pₑₓ.

Pᵢₙ+Pₑₓ=Pₒᵤₜ (15)

Since the cell was surrounded by water that was contained in an insulated reservoir with negligible thermal losses, the temperature response of the thermistor T as a function of time t was modeled by a linear curve

T^{Y}(t)=a⁻¹Pₒᵤₜ (16)

where a is the heat capacity (J/° C.) for the least square curve fit of the response to power input for the control experiments (Pₑₓ=0). The slope was recorded for about 2 hours after the cell had reached a thermal steady state, to achieve an accuracy of ±1%.

The slope of the temperature rise as a function of time was recorded for each run and baseline corrected for the negligible stirrer power and loss to ambient, then the output power was calculated from the corrected slope. After the calorimeter was calibrated, T(t) was recorded with a selected setting of the forward and reflected power to the krypton plasma. The slope was determined with this constant forward and reflected microwave power, and the microwave input power was absolutely determined for these panel meter readings using Eq. (16) with the T^{Y}(t) response and the heat capacity a. Then, identical forward and reflected microwave power settings were replicated for the helium-hydrogen mixture and T(t) was again recorded. The higher slope produced with helium-hydrogen mixture, having He⁺ as a catalyst and atomic hydrogen as a reactant, compared with controls with no hydrogen and no catalyst present was representative of the excess power. In the case of the catalysis run, the total output power Pₒᵤₜ was determined by solving Eq. (16) using the measured T^{Y}(t) and the heat capacity α. The excess power Pₑₓ was determined from Eq. (15).

Exemplary Synthesis

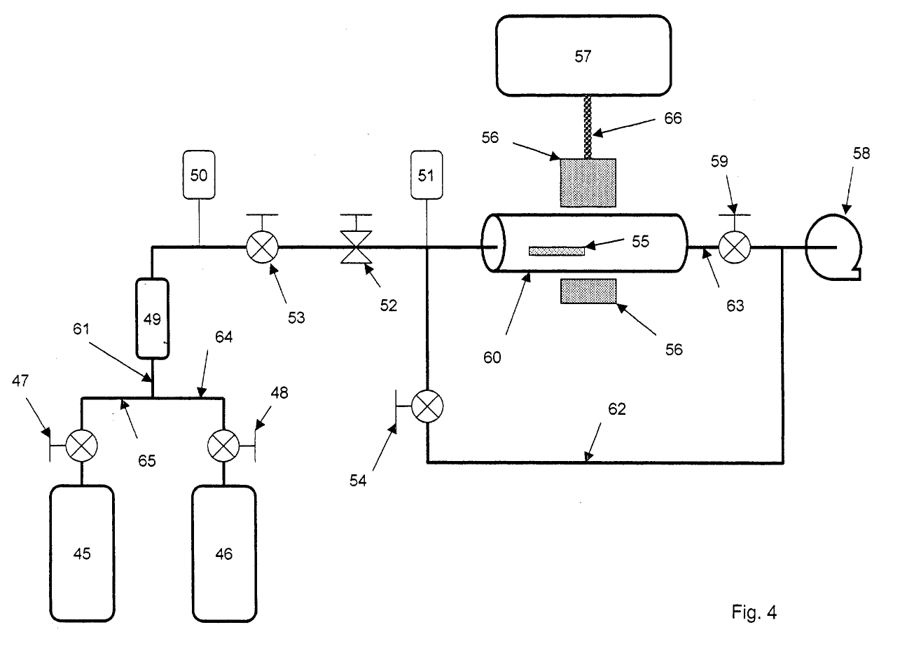

Amorphous silicon hydride (α—SiH(1/p)) films were grown on nickel substrates by their exposure to a low pressure microwave discharge of SiH₄ (2.5%)/He (96.6%)/H₂ (0.9%). The experimental set up comprising a microwave discharge cell operated under flow conditions is shown in FIG. 4. The SiH₄ gas was introduced into a 1000 ml reservoir 49 by a gas/vacuum line 61 where it was mixed with premixed He (99%)/H₂ (1%) to obtain the reaction mixture SiH₄ (2.5%)/He (96.6%)/H₂ (0.9%) by controlling the individual gas pressures. Nickel foil (5×5 mm and 0.05 mm thick, Alfa Aesar 99+%) substrates 55 were used to avoid charging during ToF-SIMS and XPS characterization. (In an alternative embodiment, the substrate 55 is oriented perpendicularly to the axis of the plasma tube 60 rather than parallel to the tube as shown in FIG. 4.) The synthesis of α—SiH was also performed on semiconductor substrates, Si and SiO₂ surfaces, by the same methods as for Ni substrates. The substrates were placed inside of a quartz tube 60 (1.3 cm in diameter by 15.5 cm long) with vacuum valves 53, 54, and 59 at both ends. The tube was fitted with an Opthos coaxial microwave cavity 56 (Evenson cavity) and connected to the gas/vacuum line 63. The quartz tube 60 and vacuum line 61, 62, 63, 64, and 65 were evacuated sufficiently to remove any trace moisture or oxygen. The gas mixture SiH₄ (2.5%)/He (96.6%)/H₂ (0.9%) was flowed from sources 45 and 46 through the quartz tube 60 at a total pressure of 0.7 Torr maintained with a gas flow rate of 40 sccm controlled by a mass flow controller with a readout. The cell pressure was monitored by an absolute pressure gauge 51. The microwave generator 57 shown in FIG. 4 was an Opthos model MPG-4M generator (Frequency: 2450 MHz). The microwave plasma was maintained with a 40 W (forward)/15 W (reflected) power for about 20 min. Yellow-orange coatings formed on the substrates and the wall of the quartz tube. The quartz tube was removed and transferred to a drybox with the samples inside by closing the vacuum valves at both ends and detaching the tube from the vacuum/gas line. The coated substrates were mounted on XPS and ToF-SIMS sample holders under an argon atmosphere in order to prepare samples for the corresponding analyses. One set of samples was analyzed with air exposure limited to 10 minutes and another for 20 minutes while transferring and mounting during the analyses. Separate samples were removed from the drybox and stored in air at room temperature for 48 hours or 10 days before the analyses. Controls comprised a commercial silicon wafer (Alfa Aesar 99.99%) untreated, and HF cleaned silicon wafers exposed to air for 10 minutes or 3 hours.

Characterization

a. ToF-SIMS Characterization

The commercial silicon wafer, HF cleaned silicon wafer, and α—SiH(1/p) coated nickel foil samples were characterized using Physical Electronics TRIFT ToF-SIMS instrument. The primary ion source was a pulsed ⁶⁹Ga⁺ liquid metal source operated at 15 keV [86-87]. The secondary ions were exacted by a ±3 keV (according to the mode) voltage. Three electrostatic analyzers (Triple-Focusing-Time-of-Flight) deflect them in order to compensate for the initial energy dispersion of ions of the same mass. The 400 pA dc current was pulsed at a 5 kHz repetition rate with a 7 ns pulse width. The analyzed area was 60 μm×60 μm and the mass range was 0-1000 AMU. The total ion dose was 7×11¹⁰ ions/cm², ensuring static conditions. Charge compensation was performed with a pulsed electron gun operated at 20 eV electron energy. In order to remove surface contaminants and expose a fresh surface for analysis, the samples were sputter-cleaned for 30 s using a 80 μm×80 μm raster, with 600 pA current, resulting in a total ion dose of 10¹⁵ ions/cm². Three different regions on each sample of 60 μm×60 μm were analyzed. The positive and negative SIMS spectra were acquired. Representative post sputtering data is reported. The ToF-SIMS data were treated using ‘Cadence’ software (Physical Electronics), which calculates the mass calibration from well-defined reference peaks.

b. XPS Characterization

A series of XPS analyses were made on the samples using a Scienta 300 XPS Spectrometer. The fixed analyzer transmission mode and the sweep acquisition mode were used. The angle was 15°. The step energy in the survey scan was 0.5 eV, and the step energy in the high resolution scan was 0.15 eV. In the survey scan, the time per step was 0.4 seconds, and the number of sweeps was 4. In the high resolution scan, the time per step was 0.3 seconds, and the number of sweeps was 30. C 1s at 284.5 eV was used as the internal standard.

### RESULTS AND DISCUSSION

A. Line Broadening Measurements

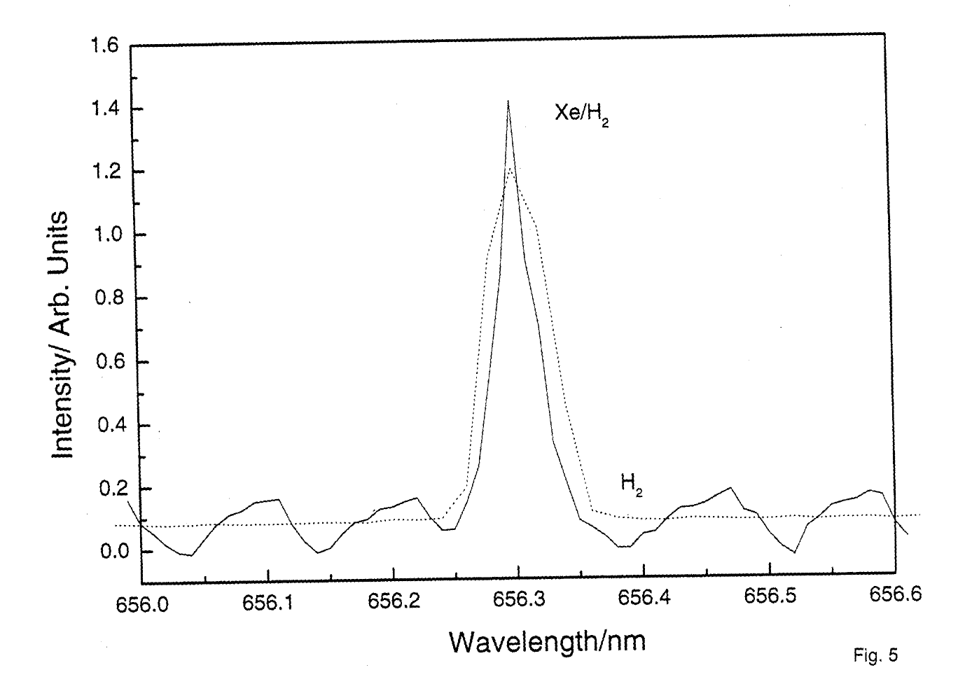

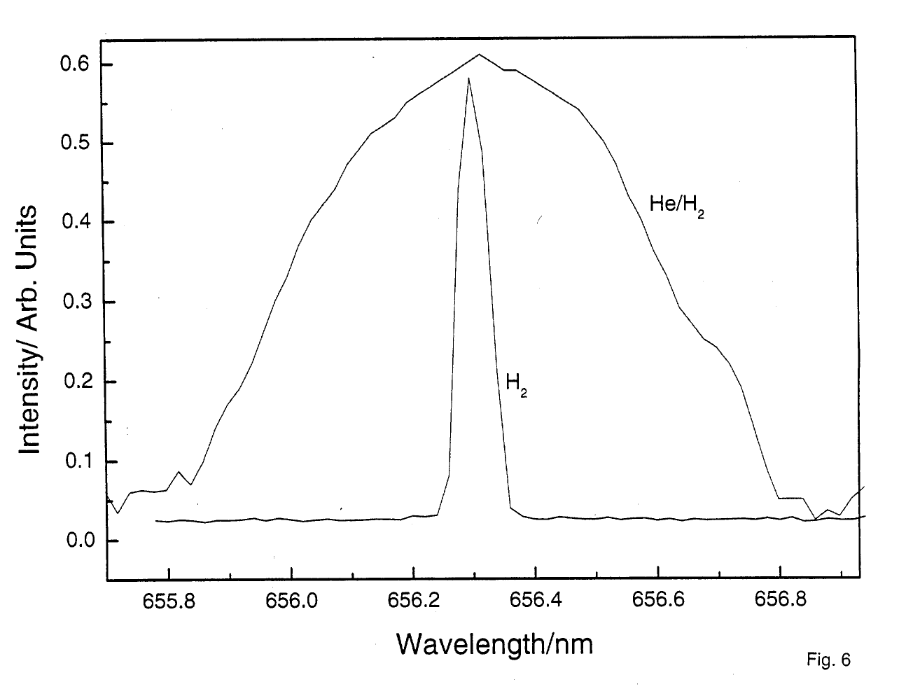

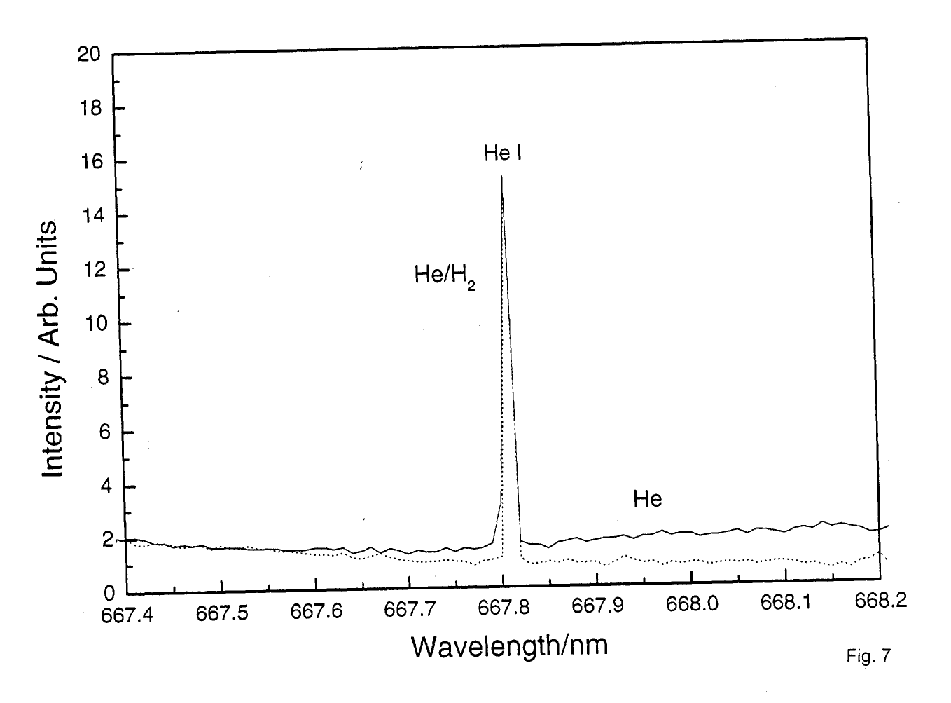

The 656.3 nm Balmer α line width recorded with a high resolution (±0.006 nm ) visible spectrometer on microwave discharge plasmas of hydrogen compared with each of xenon-hydrogen (90/10%) and helium-hydrogen (90/10%) are shown in FIGS. 5 and 6, respectively. The average helium-hydrogen Doppler half-width of 0.52±5% nm was not appreciably changed with pressure. The corresponding energy of 180-210 eV and the number density of 5×10¹⁴±20% atoms/cm³, depending on the pressure, were significant compared to only ≈3 eV and 7×10¹³ atoms/cm³ for pure hydrogen, even though 10 times more hydrogen was present. Only ≈3 eV broadening was observed with control xenon-hydrogen (90/10%) ruling out collisional broadening. The xenon-hydrogen plasma number density of 3×10¹³ atoms/cm³ was much lower than that of the helium-hydrogen plasma. Furthermore, only the hydrogen lines were broadened. The addition of hydrogen to helium had no effect on the helium lines as shown for the 667.816 nm He I line in FIG. 7.

Doppler broadening due to thermal motion was assumed to be the dominant source to the extent that other sources may be neglected. This assumption was confirmed when each source was considered. In general, the experimental profile is a convolution of a Doppler profile, an instrumental profile, the natural (lifetime) profile, Stark profiles, van der Waals profiles, a resonance profile, and fine structure. The contribution from each source was determined to be below the limit of detection [21, 26, 32].

Furthermore, no hydrogen species, H⁺, H₂⁺, H₃⁺, H⁻, H, or H₂ , responds to the microwave field; rather, only the electrons respond. But, the measured electron temperature was about 1 eV; whereas, the measured H temperature was 180-210 eV. This requires that T_{H}>>>Tₑ. This result can not be explained by electron or external Stark broadening or electric field acceleration of charged species. The electron density was nₑ˜10⁸ cm⁻³, at least five orders of magnitude too low [21, 26, 32] for detectable Stark broadening. And, in microwave driven plasmas, there is no high electric field in a cathode fall region (>1 kV/cm) to accelerate positive ions as proposed previously [80, 88-90] to explain significant broadening in hydrogen containing plasmas driven at high voltage electrodes. It is impossible for H or any H-containing ion which may give rise to H to have a higher temperature than the electrons in a microwave plasma. The observation of excessive Balmer line broadening in a microwave driven plasma requires a source of energy other than that provided by the electric field. The source is the catalytic reaction of atomic hydrogen with He⁺ and subsequent autocatalytic reactions of the lower-energy hydrogen product given previously [36, 41].

The formation of fast H can be explained by a resonant energy transfer from hydrogen atoms to He⁺ ions of two times the potential energy of atomic hydrogen, 2·27.2 eV, followed by a collisional energy transfer to yield fast H(n=1) as well as the emission of q·13.6 eV photons discussed previously [35-36, 41]. For example, the exothermic chemical reaction of H+H to form H₂ does not occur with the emission of a photon. Rather, the reaction requires a 30 collision with a third body, M, to remove the bond energy—H+H+M→H₂+M* [71]. The third body distributes the energy from the exothermic reaction, and the end result is the H₂ molecule and an increase in the temperature of the system. In the case of the He⁺ catalytic reaction with the formation of states given by Eqs. (1,3), the temperature of H becomes very high.

The hydrogen atom temperature in plasmas of hydrogen mixed with helium were about 50-100 times that observed for the control plasmas such as hydrogen mixed with xenon or hydrogen alone. Even so, the observed ≈3 eV temperature of the latter plasmas was still well above the resolution capability of the instrument, and surprisingly it was appreciably above that expected based on the electron temperature of about 1 eV. The observation of an elevated hydrogen atom temperature for pure hydrogen plasmas and mixtures containing hydrogen with the unusual absence of an elevated temperature of any other gas present can be explained by a catalytic reaction involving hydrogen atoms alone. Since the ionization energy of hydrogen is 13.6 eV, two hydrogen atoms can provide a net enthalpy equal to the potential energy of the hydrogen atom, 27.2 eV—the necessary resonance energy, for a third hydrogen atom. On this basis, the unusual observation of the H energy slightly above the electron temperature is expected. The effect is expected to more pronounced with greater hydrogen concentration such as that achieved near or on the cathode in RF and glow discharge cells as described previously [21, 32].

Power Balance of the Helium-Hydrogen Microwave Plasma

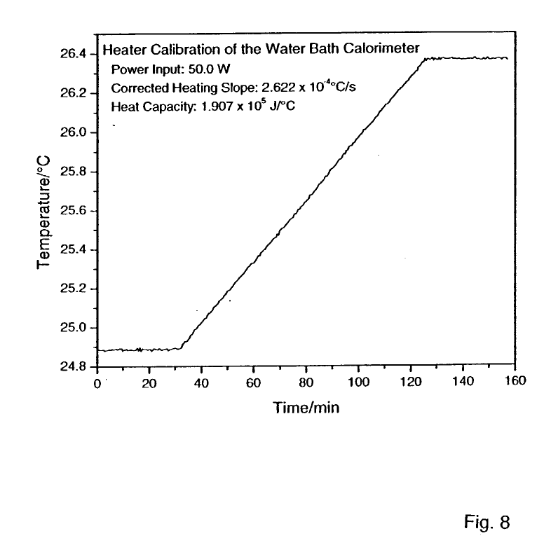

The thermogram, T(t) response of the cell, with stirring only and with a constant input power to the high precision heater of 50 W is shown in FIG. 8. The baseline corrected least squares fit of the slope, T^{Y}(t), was 2.622×10⁻⁴° C./s, and the heat capacity determined from Eqs. (15-16) with Pₑₓ=0, and Pᵢₙ=Pₒᵤₜ=50 W was 1.907×10⁵J/° C. Then the temperature response of the calorimeter for any case (Eq. (16)) was determined to be

T^{Y}(t)=(1.907×10⁵ J/° C.)⁻¹×Pₒᵤₜ (17)

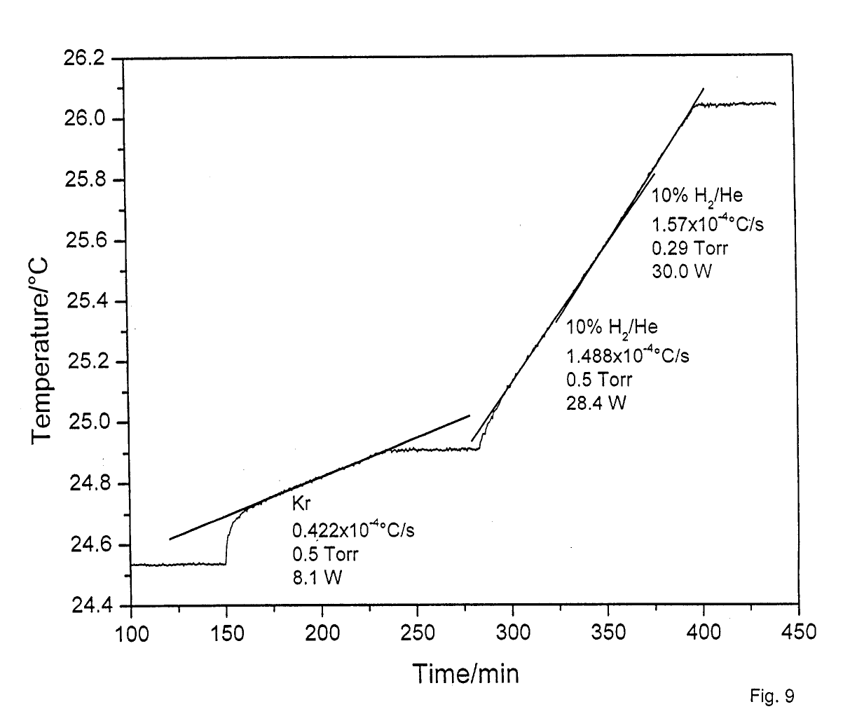

The T(t) water bath response to stirring and then with selected panel meter readings of the constant forward and reflected microwave input power to krypton was recorded as shown in FIG. 9. Using the corresponding T^{Y}(t) in Eq. (17), the microwave input power was determined to be 8.1±1 W. A helium-hydrogen (90/10%) mixture was run at the same microwave input power readings as the control which corresponded to Pᵢₙ=8.1±1 W in Eq. (15). The T(t) response was significantly increased for helium-hydrogen (90/10%) as shown in FIG. 9. At 350 minutes, the pressure was changed from 0.5 torr to 0.29 torr. A slight increase in T^{Y}(t) was observed at the lower pressure, possibly due to an increase in atomic hydrogen and He⁺. The excess power was determined to be 21.9±1 W from the corresponding T^{Y}(t) using Eq. (17) and Eq. (15).

The sources of error were the error in the calibration curve (±0.05 W) and the measured microwave input power (±1 W). The propagated error of the calibration and power measurements was ±1 W.

Given a helium-hydrogen (90/10%) flow rate of 10.0 sccm and an excess power of 21.9 W, energy balances of over −2.9×10⁴ kJ/mole H₂ (150 eV/H atom )were measured. The reaction of hydrogen to form water which releases −241.8 kJ/mole H₂ (1.48 eV/H atom) is about 100 times less than that observed. Given that no conventional chemical reaction is plausible, the results indicate that the catalytic reaction of atomic hydrogen with He⁺ and subsequent autocatalytic reactions given previously [36, 41] occur to a significant extent. This is consistent with the previously reported series of lower-energy hydrogen lines with energies of q·13.6 eV where q=1,2,3,4,6,7,8,9, or 11 [35-36, 41], the previously given theory [36, 41, 68], and previous studies which show very large energy balances [2, 7, 26, 30, 34-36, 38-39, 44, 46, 58, 65-67].

Characterization

a. ToF-SIMS Characterization

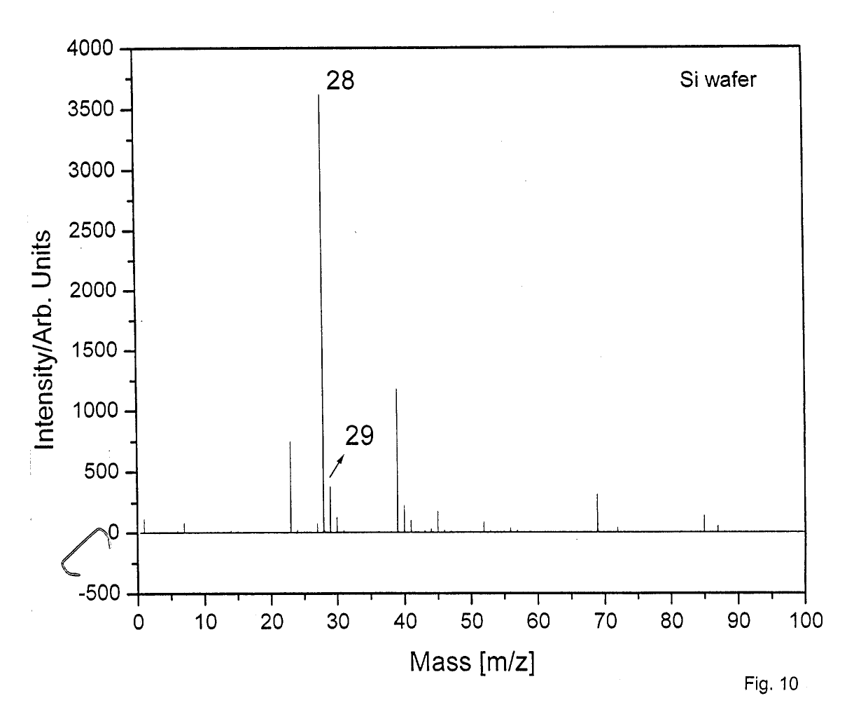

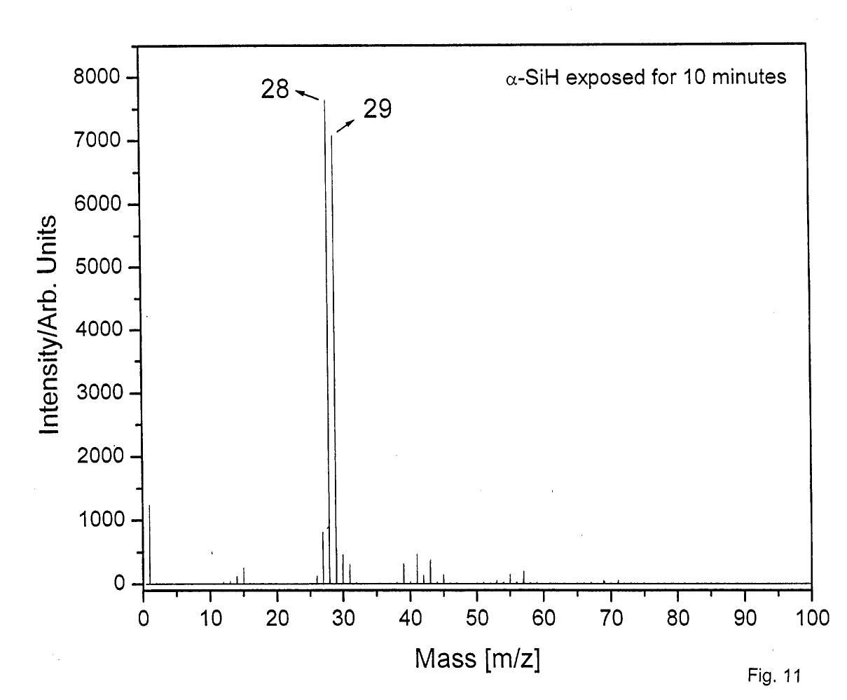

The positive ToF-SIMS spectra (m/e=0-100) of the noncoated cleaned commercial silicon wafer control and a nickel foil coated with an α—SiH(1/p) film and exposed to air for 10 min. are shown in FIGS. 10 and 11, respectively. The positive ion spectrum of the silicon wafer control was dominated by Si⁺, oxides SiₓO_{y}⁺, and hydroxides Siₓ(OH)_{y}⁺; whereas, that of the α—SiH(1/p) sample contained essentially no oxide or hydroxide peaks. Rather, it was dominated by Si⁺ and a peak at m/z=29 which comprised a contribution from SiH⁺ and ²⁹Si⁺ which were difficult to separate definitively. However, the contribution due to SiH⁺ could be determined by calculating the ratio

$$R = \frac{{}^{28} Si}{{}^{28} SiH + {}^{29} Si} .$$

For comparison, the theoretical ratio of

$$\frac{{}^{28} Si}{{}^{29} Si}$$

based on isotopic abundance is 19.6. R for the clean noncoated silicon wafer was 8.1. Whereas, R for the α—SiH(1/p) sample was 1.15 indicating that the m/z=29 peak was overwhelmingly due to SiH⁺.

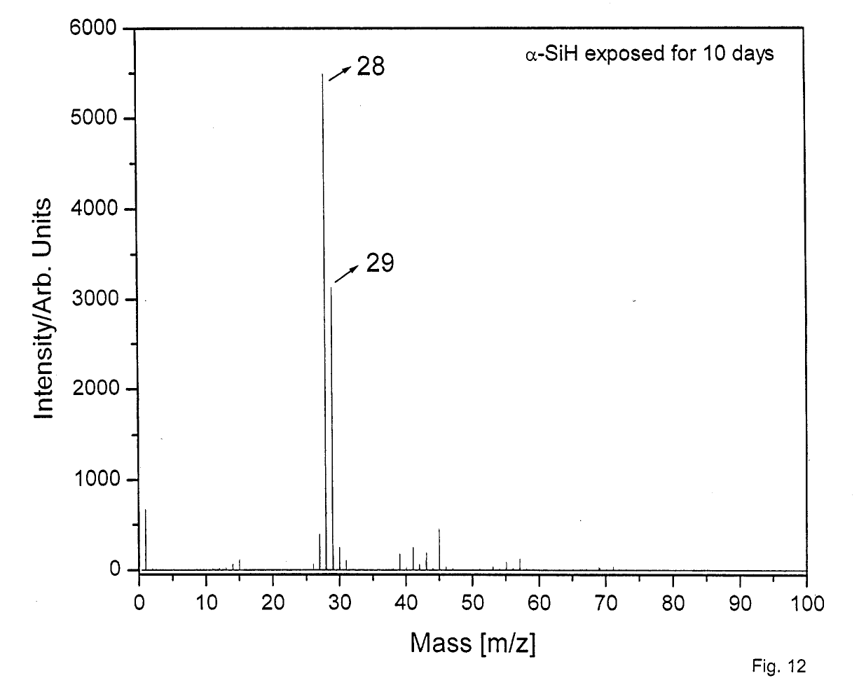

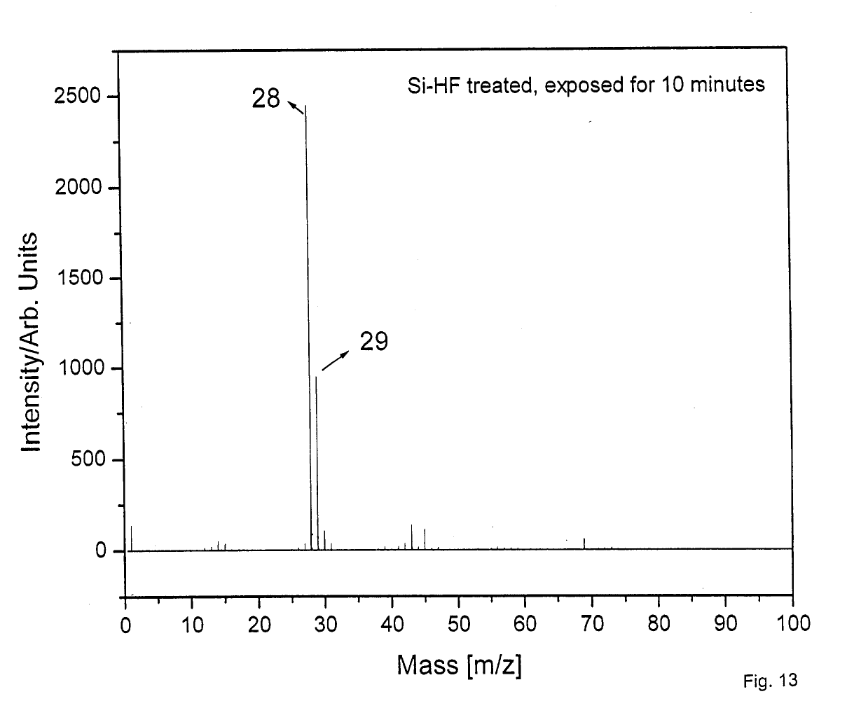

The positive spectrum (m/e=0-100) of a nickel foil coated with an α—SiH(1/p) film and exposed to air for 10 days before the ToF-SIMS analysis is shown in FIG. 12. In this case R was 1.75 demonstrating that the sample was extraordinarily stable to air exposure. In contrast, R was 2.45 in the positive spectrum (m/e=0-100) of the HF cleaned silicon wafer exposed to air for only 10 min. before ToF-SIMS analysis as shown in FIG. 13.

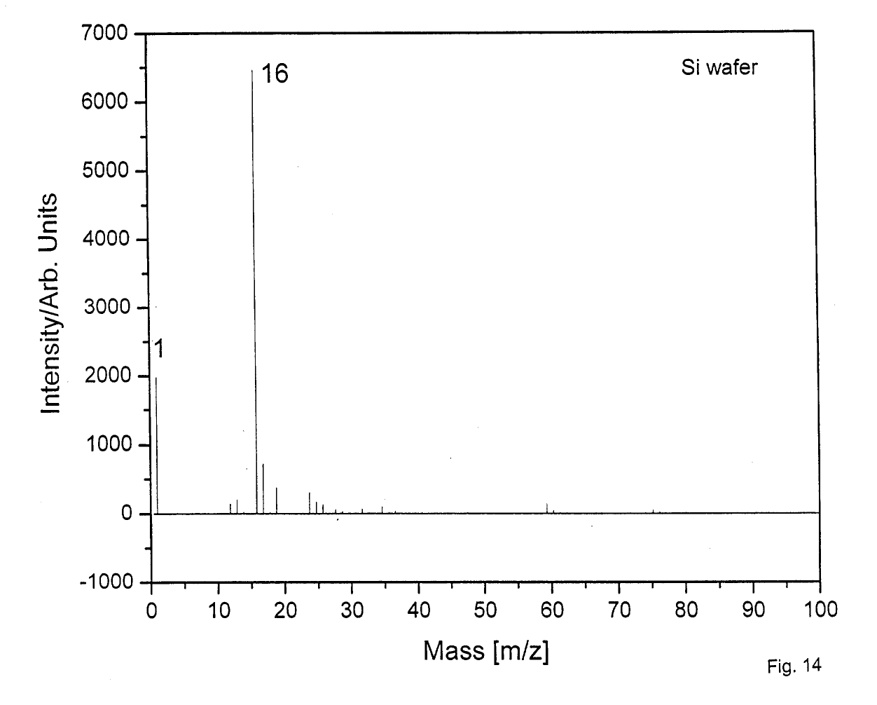

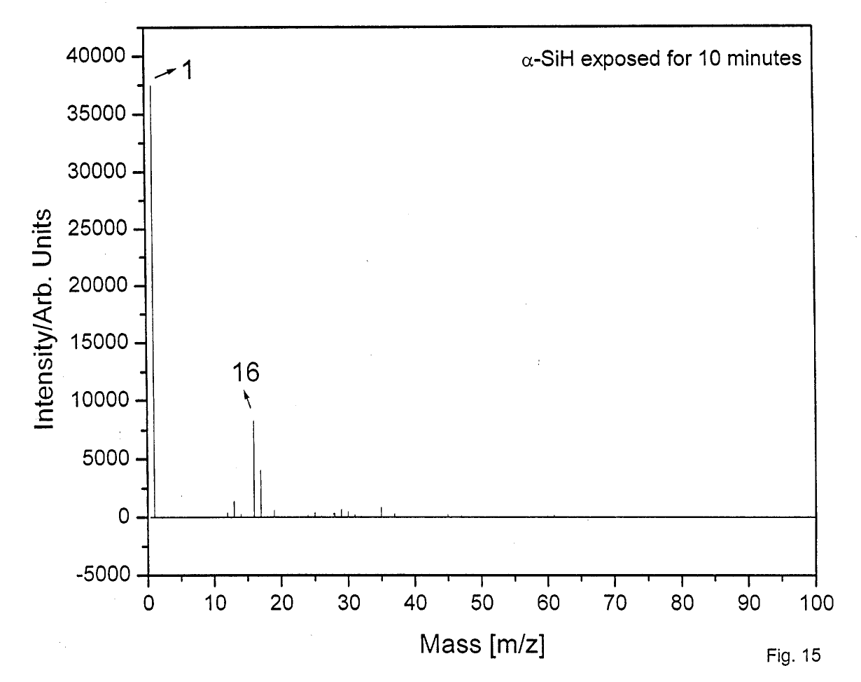

The negative ion spectra (m/e=0-100) of the noncoated cleaned commercial silicon wafer and a nickel foil coated with an α—SiH(1/p) film and exposed to air for 10 min. before ToF-SIMS analysis are shown in FIGS. 14 and 15, respectively. The control spectrum was dominated by oxide (O⁻ m/z=16) and hydroxide (OH⁻ m/z=17); whereas, spectrum of the α—SiH(1/p) film was dominated by hydride ion (H⁻ m/z=1). Very little oxide or hydroxide was observed.

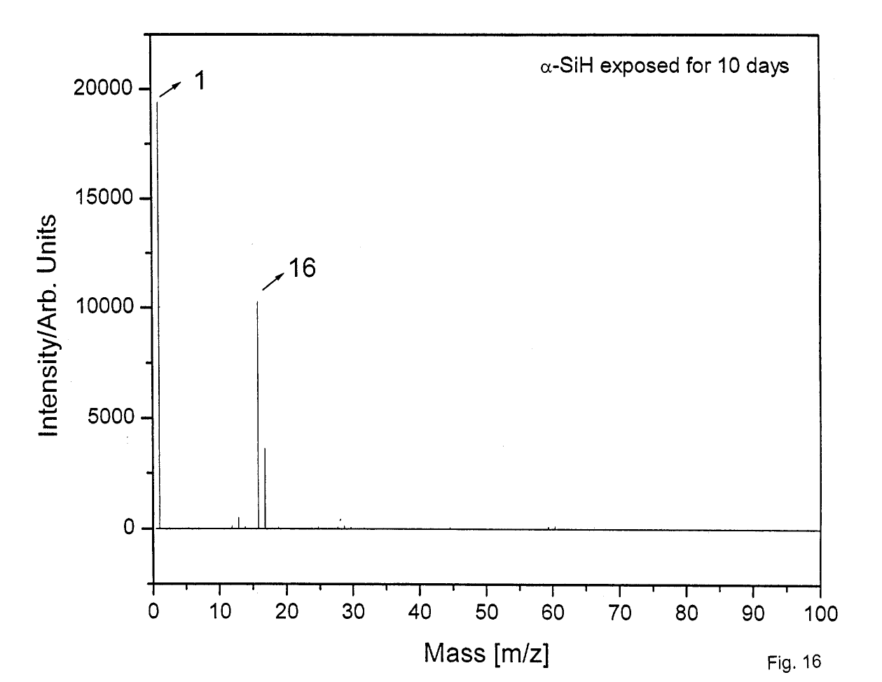

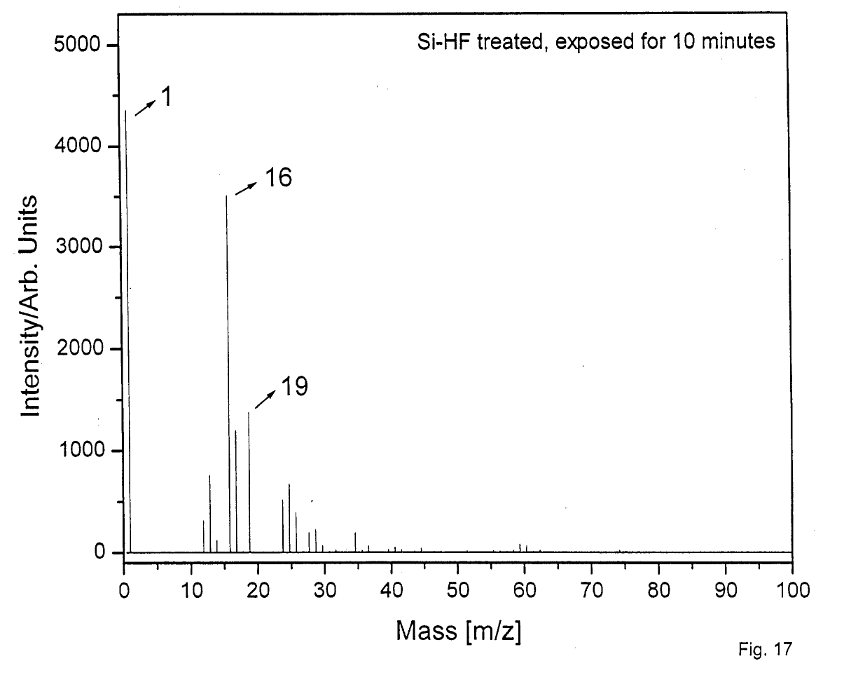

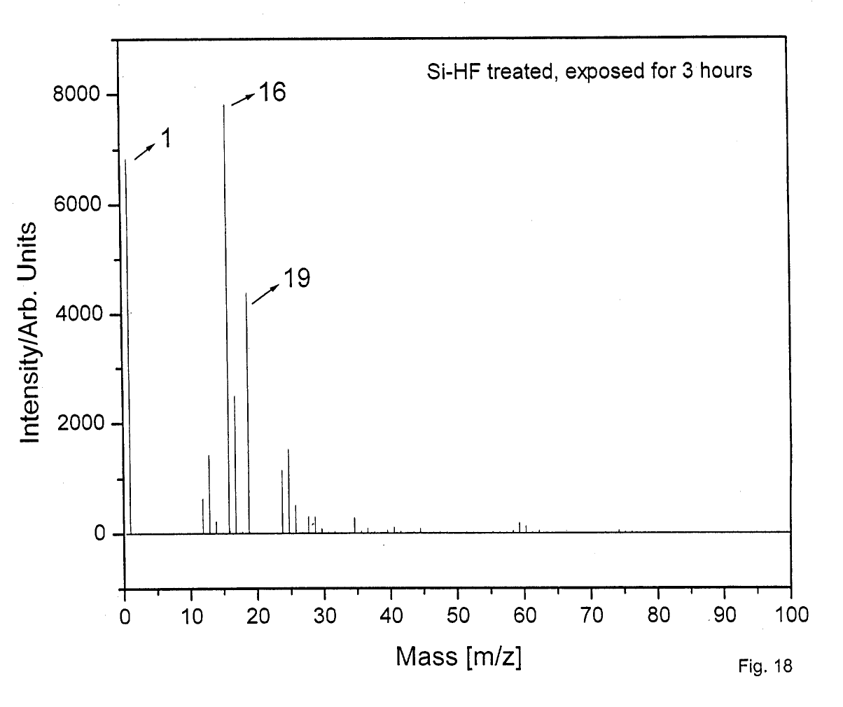

The negative spectrum (m/e=0-100) of a nickel foil coated with an α—SiH(1/p) film and exposed to air for 10 days before the ToF-SIMS analysis is shown in FIG. 16. In this case, hydride ion also dominated the negative spectrum demonstrating extraordinary air stability of the α—SiH(1/p) film. The negative spectrum (m/e=0-100) of the HF cleaned silicon wafer exposed to air for only 10 min. before ToF-SIMS analysis shown in FIG. 17 also shows a dominant hydride as well as oxide, hydroxide, and some fluoride (F⁻ m/z=19). However, the HF treated surface was not stable with prolonged air exposure. A dominant oxide peak was observed in the negative spectrum (m/e=0-100) of the HF cleaned silicon wafer exposed to air for only 3 hours before ToF-SIMS analysis as shown in FIG. 18. Hydride was also observed in lesser amounts and may have resulted as a fragment of the observed hydroxide. Fluoride (F⁻ m/z=19) was also observed. The ToF-SIMS results from the HF treated surface is consistent with predominantly H termination of silicon dangling bonds as reported previously [75-77] that has undergone rapid oxidation to form mixed oxides such as SiOH.

These results indicate that the plasma reaction formed a highly stable hydrogenated silicon coating in the absence of fluorine observed on the HF treated surface. Remarkably, the α—SiH film was stable even after 10 days; whereas, the HF treated surface showed signs of oxidation over a 1500 times shorter time scale—10 mins. At 3 hours the HF treated surface had similarities to the control untreated silicon wafer which comprised a full oxide coating.

The plasma-reaction-formed α—SiH(1/p) is shown to comprise a more stable hydride ion than the H terminated silicon from HF treatment. Thus, the ion production efficiencies in ToF-SIMS analysis could be different making a comparison only qualitative and indicative of relative changes that occurred with timed air exposure. Since the Si 2 p electron of all samples was equivalent except for energy shifts due to the presence of ordinary H, novel H, or oxide, qualitative analysis was possible as given in the XPS section. As shown in this section, the ToF-SIMS results were confirmed by XPS.

XPS Characterization

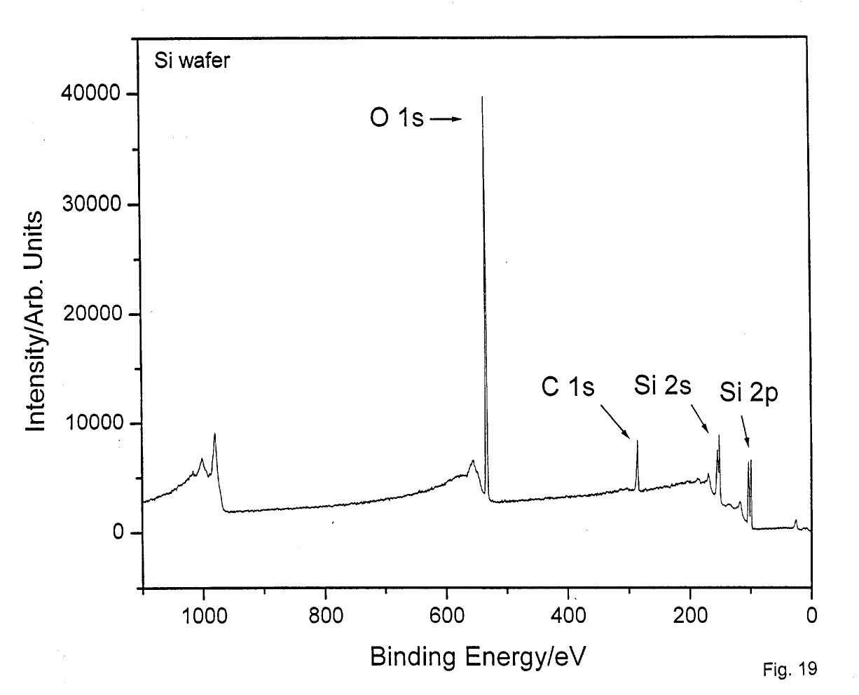

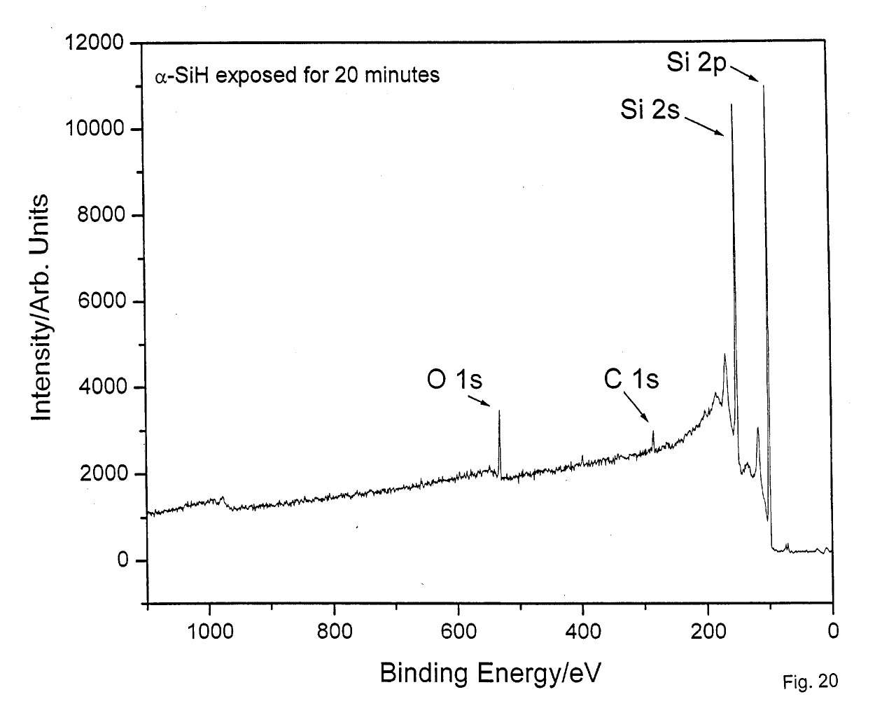

The XPS survey spectra of the noncoated cleaned commercial silicon wafer (control) and a nickel foil coated with an α—SiH film and exposed to air for 20 min were obtained over the region E_{b}=0 eV to 1200 eV and are shown in FIGS. 19 and 20, respectively. The survey spectra permitted the determination of all of the elements present and detected shifts in the binding energies of the Si 2 p peak, which also identifies the presence or absence of SiO₂. The major species identified in the XPS spectrum of the control sample were silicon, oxygen, and carbon. The α—SiH(1/p) sample contained essentially silicon with negligible oxygen and carbon.

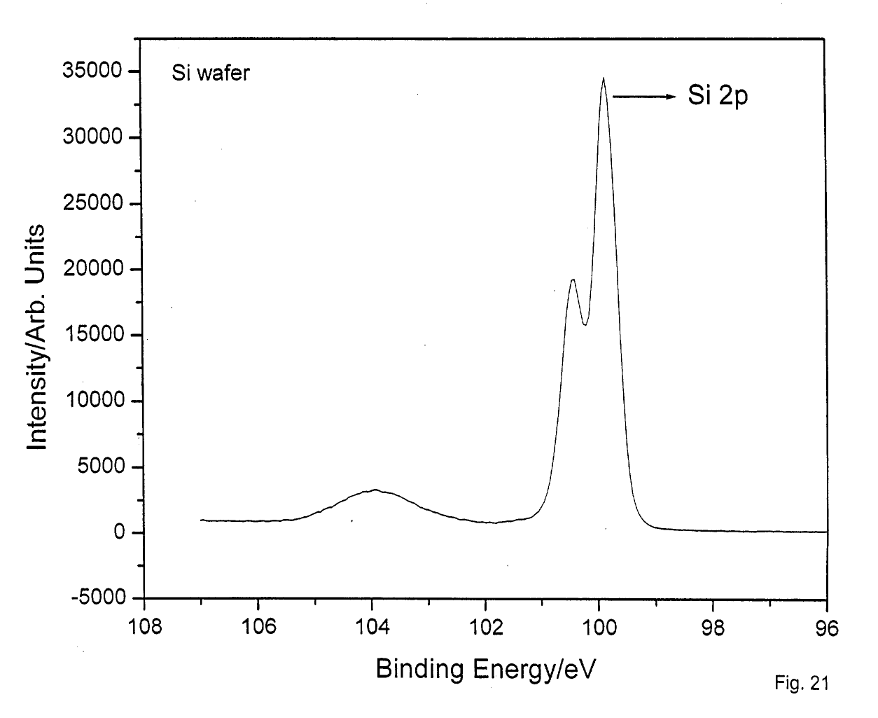

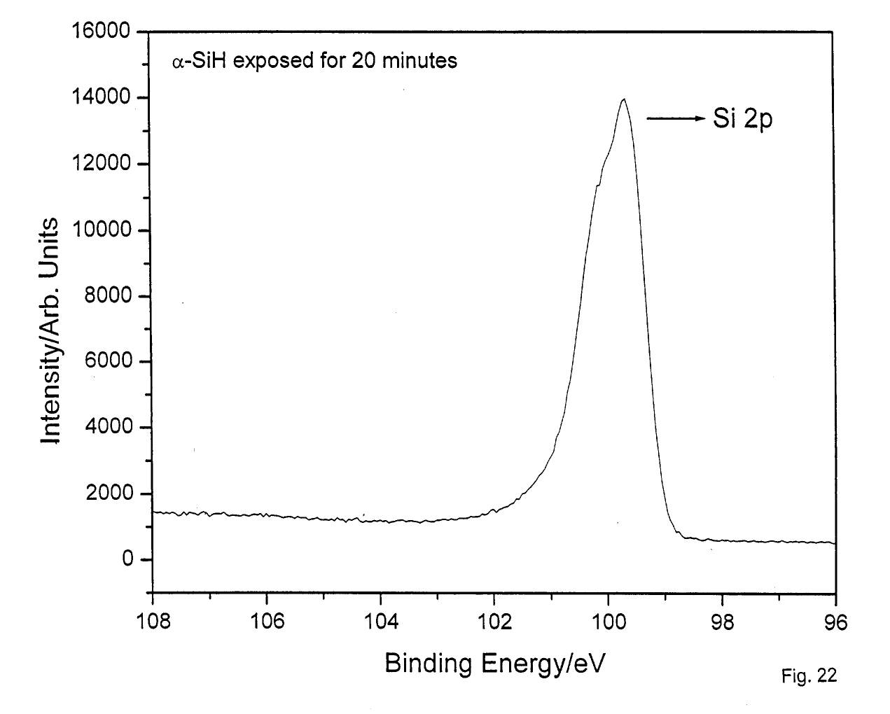

The XPS spectra (96-108 eV) in the region of the Si 2 p peak of the noncoated cleaned commercial silicon wafer and a nickel foil coated with an α—SiH(1/p) film and exposed to air for 20 min. are shown in FIGS. 21 and 22, respectively. The XPS spectrum of the control silicon wafer shows a large SiO₂ content at 104 eV as given by Wagner et al. [91]. In contrast, the α—SiH(1/p) sample had essentially no SiO₂. In addition, spin-orbital coupling gives rise to a split Si 2 p peak in pure silicon, but this peak changed to a single broad peak upon reaction to form the α—SiH(1/p) film indicative of amorphous silicon.

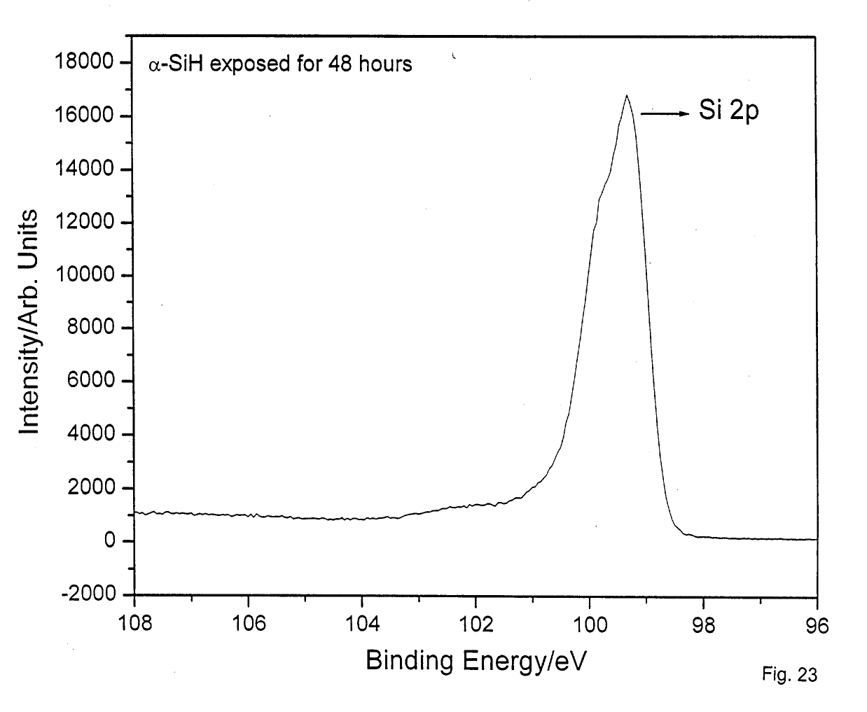

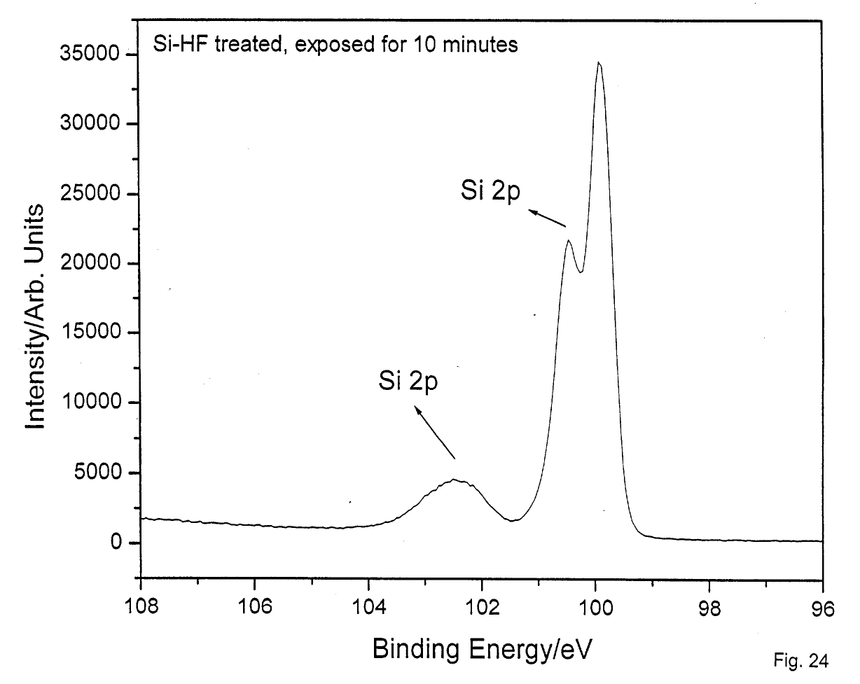

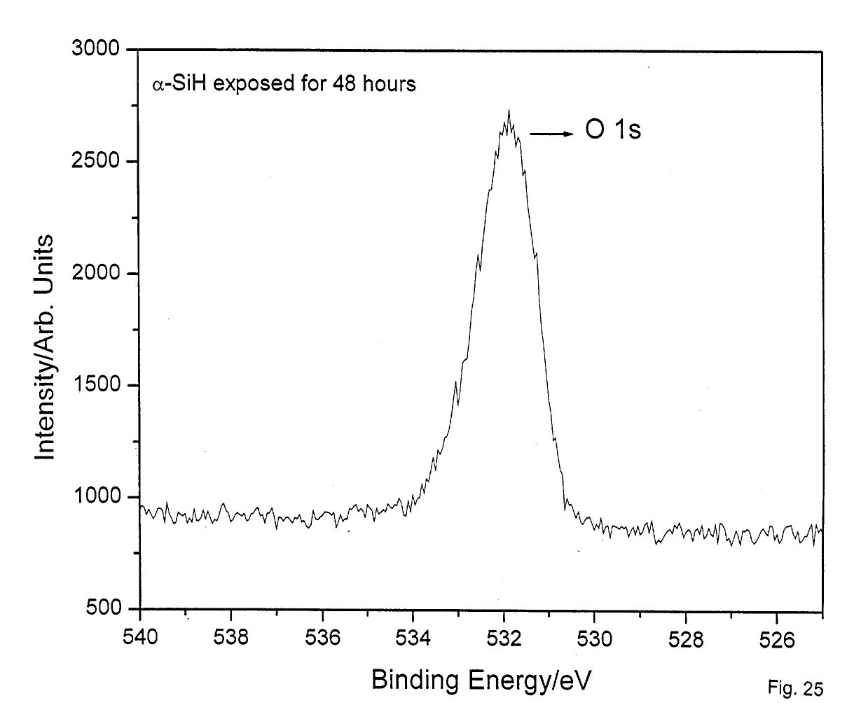

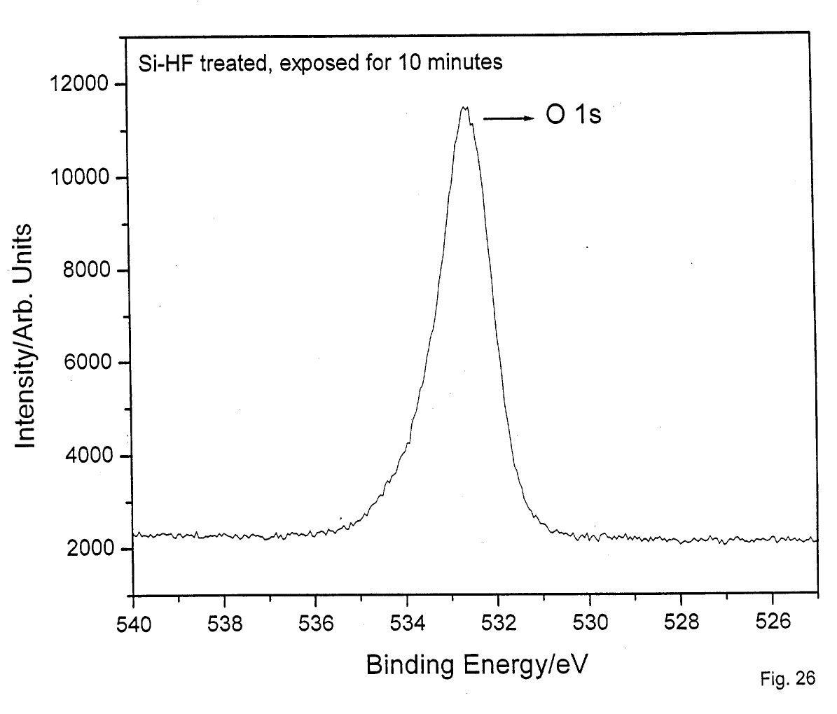

The XPS spectrum (96-108 eV) in the region of the Si 2 p peak of a nickel foil coated with an α—SiH(1/p) film and exposed to air for 48 hours before the XPS analysis is shown in FIG. 23. Essentially no SiO₂ was observed at 104 eV demonstrating that the sample was extraordinarily stable to air exposure. Perhaps trace SiOH is present in the region of 102 eV potentially due to less than 100% coverage of the surface with the α—SiH(1/p) film; rather, some silicon deposition may have occurred. In contrast, the XPS spectrum (96-108 eV) in the region of the Si 2 p peak of the HF cleaned silicon wafer exposed to air for 10 min. before XPS analysis was essentially fully covered by partial oxides SiOₓ such as SiOH. The mixed silicon oxide peak in the region of 101.5-104 eV shown in FIG. 24 was essentially the same percentage of the Si 2 p as that of the SiO₂ peak of the uncleaned wafer shown at 104 eV in FIG. 21. In addition, the O 1s peak of the α—SiH(1/p) film exposed to air for 48 hours shown in FIG. 25 was negligible; whereas, that of the HF cleaned wafer exposed to air for 10 min. was intense as shown in FIG. 26.

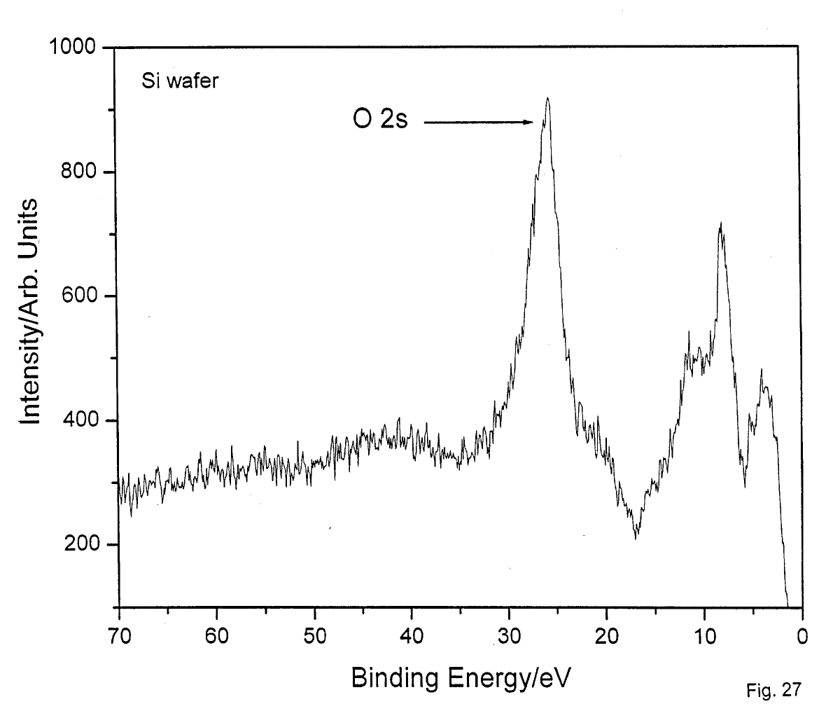

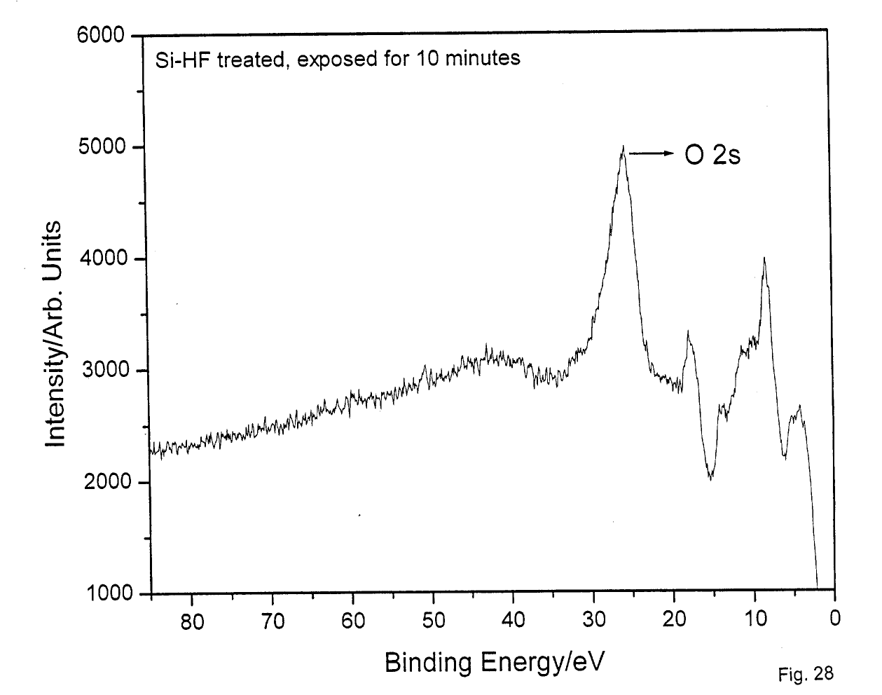

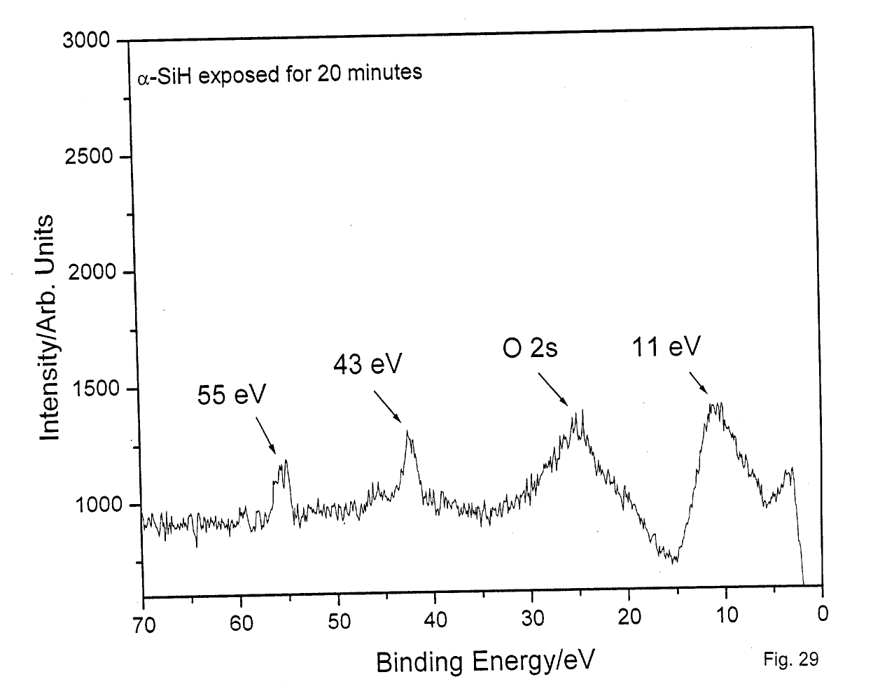

The 0-70 eV and the 0-85 eV binding energy region of high resolution XPS spectra of the commercial silicon wafer and a HF cleaned silicon wafer exposed to air for 10 min. before XPS analysis are shown in FIGS. 27 and 28, respectively. Only a large O 2s peak in the low binding energy region was observed in each case. The 0-70 eV binding energy region of a nickel foil coated with an α-SiH(1/p) film and exposed to air for 20 min. before XPS analysis is shown in FIG. 29. By comparison of the α-SiH(1/p) sample to the controls, novel XPS peaks were identified at 11, 43, and 55 eV. These peaks do not correspond to any of the primary elements, silicon, carbon, or oxygen, shown in the survey scan in FIG. 20, wherein the peaks of these elements are given by Wagner et al. [91]. Hydrogen is the only element which does not have primary element peaks; thus, it is the only candidate to produce the novel peaks and correspond to the H content of the SiH coatings. These peaks closely matched and were assigned to hydride ions, H⁻(¼), H⁻(1/9), and H⁻(1/11), respectively, given by Eqs (4-5). The novel hydride ions are formed by the catalytic reaction of He⁺ with atomic hydrogen and subsequent autocatalytic reactions of H(1/p) to form highly stable silicon hydride products comprising SiH(1/p) (p is an integer greater than one in Eqs. (4-5)).

The XPS spectra of the Si 2 p region were analyzed, and it was found that the Si 2 p peak was shifted 0.3-0.7 eV for the α-SiH(1/p) films relative to that of the HF cleaned silicon wafer as shown in FIGS. 22 and 23 compared to FIG. 21. The shift was due to the influence of the hydride ions since no other counter ion peaks were observed as shown by the survey scan, FIG. 20. The stability and the intensity of the hydride ion peaks in the low binding energy region were correlated with the shift of the Si 2 p peaks as shown by the shift of 0.3 eV in FIG. 22 compared to a 0.7 eV shift in FIG. 23. This provides further evidence of a novel α-SiH(1/p) film with increased stability due to the novel hydride ions.

These results indicate that the plasma reaction formed a highly stable novel hydrogenated coating; whereas, the control comprised an oxide coating or an ordinary hydrogen terminated silicon surface which rapidly formed an oxide passivation layer. The hydrogen content of the α-SiH(1/p) coating appears to be novel hydride ions with high binding energies which account for the exceptional air stability.

### CONCLUSIONS

Microwave helium-hydrogen plasmas showed extraordinary broadening, and the corresponding extremely high hydrogen-atom temperature of 180-210 eV was observed with the presence of helium ion catalyst only with hydrogen present. Using water bath calorimetry, excess power was observed from the helium-hydrogen plasma compared to control krypton plasma. For a 8.1 W input, the thermal output power of the helium-hydrogen plasma was measured to be 30.0 W corresponding to 21.9 W of excess power in 3 cm³. The excess power density and energy balance were high, 7.3 W/cm³ and −2.9×10⁴ kJ/mole H₂, respectively.

The energetic plasma reaction was used to synthesize a potentially commercially important product. Nickel substrates were coated by the reaction product of a low pressure microwave discharge plasma of SiH₄ (2.5%)/He (96.6%)/H₂ (0.9%). The ToF-SIMS identified the coatings as hydride by the large SiH⁺ peak in the positive spectrum and the dominant H⁻ in the negative spectrum. XPS identified the H content of the SiH coatings as hydride ions, H⁻(¼), H⁻(1/9), and H⁻(1/11) corresponding to peaks at 11, 43, and 55 eV, respectively. The novel hydride ions are formed by the catalytic reaction of He⁺ with atomic hydrogen and subsequent autocatalytic reactions of H(1/p) to form highly stable silicon hydride products SiH(1/p) (p is an integer greater than one in Eqs. (4-5)). The SiH coating was amorphous as indicated by the shape of the Si 2 p peak and was remarkably stable to air exposure. After a 48 hour exposure to air, essentially no oxygen was observed as evidence by the negligible O 1s peak at 531 eV and absence of any SiOₓ Si 2 p peak in the region of 102-104 eV. The highly stable amorphous silicon hydride coating may advance the production of integrated circuits and microdevices by resisting the oxygen passivation of the surface and possibly altering the dielectric constant and band gap to increase device performance.

### REFERENCE LIST

The following references are incorporated herein by reference in their entirety.

1. R. Mills, J. Sankar, P. Ray, B. Dhandapani, J. He, “Spectroscopic Characterization of the Atomic Hydrogen Energies and Densities and Carbon Species During Helium-Hydrogen-Methane Plasma CVD Synthesis of Single Crystal Diamond Films”, Chemistry of Materials, submitted.

2. R. Mills, P. Ray, R. M. Mayo, “Stationary Inverted Balmer and Lyman Populations for a CW HI Water-Plasma Laser”, IEEE Transactions on Plasma Science, submitted.

3. R. L. Mills, P. Ray, B. Dhandapani, J. He, “New Energy States of Atomic Hydrogen Formed in a Catalytic Helium-Hydrogen Plasma”, IEEE Transactions on Plasma Science, submitted.

4. R. L. Mills, P. Ray, “Spectroscopic Evidence for a Water-Plasma Laser”, Europhysics Letters, submitted.

5. R. Mills, P. Ray, R. M. Mayo, “Spectroscopic Evidence for CW H I Lasing in a Water-Plasma”, J. of Applied Physics, submitted.

6. R. L. Mills, B. Dhandapani, J. He, J. Sankar, “Low Power MPCVD of Diamond Films on Silicon Substrates”, J of Materials Chemistry, submitted.

7. R. L. Mills, X. Chen, P. Ray, J. He, B. Dhandapani, “Plasma Power Source Based on a Catalytic Reaction of Atomic Hydrogen Measured by Water Bath Calorimetry”, Thermochimica Acta, submitted.

8. R. L. Mills, A. Voigt, B. Dhandapani, J. He, “Synthesis and Spectroscopic Identification of Lithium Chloro Hydride”, Materials Characterization, submitted.

9. R. L. Mills, B. Dhandapani, J. He, “Highly Stable Amorphous Silicon Hydride”, Solar Energy Materials & Solar Cells, submitted.

10. R. L. Mills, B. Dhandapani, J. He, J. Sankar, “Synthesis of HDLC Films from Solid Carbon”, Thin Solid Films, submitted.

11. R. Mills, P. Ray, R. M. Mayo, “The Potential for a Hydrogen Water-Plasma Laser”, Applied Physics Letters, submitted.

12. R. L. Mills, “Classical Quantum Mechanics”, Proceedings A, submitted.

13. R. L. Mills, P. Ray, “Spectroscopic Characterization of Stationary Inverted Lyman Populations and Free-Free and Bound-Free Emission of Lower-Energy State Hydride Ion Formed by a Catalytic Reaction of Atomic Hydrogen and Certain Group I Catalysts, ChemPhysChem, submitted.

14. R. M. Mayo, R. Mills, “Direct Plasmadynamic Conversion of Plasma Thermal Power to Electricity for Microdistributed Power Applications”, 40th Annual Power Sources Conference, Cherry Hill, N.J., Jun. 10-13, (2002), pp. 1-4.

15. R. Mills, P. Ray, R. M. Mayo, “Chemically-Generated Stationary Inverted Lyman Population for a CW HI Laser”, J Vac. Sci. and Tech. A, submitted.

16. R. L. Mills, P. C. Ray, R. M. Mayo, M. Nansteel, B. Dhandapani, J. Phillips, “Spectroscopic Study of Unique Line Broadening and Inversion in Low Pressure Microwave Generated Water Plasmas”, Physics of Plasmas, submitted.

17. R. Mills, “A Maxwellian Approach to Quantum Mechanics Explains the Nature of Free Electrons in Superfluid Helium”, Foundations of Science, submitted.

18. R. Mills and M. Nansteel, P. Ray, “Bright Hydrogen-Light Source due to a Resonant Energy Transfer with Strontium and Argon Ions”, New Journal of Physics, Vol. 4, (2002), pp. 70.1-70.28.

19. R. Mills, P. Ray, R. M. Mayo, “CW HI Laser Based on a Stationary Inverted Lyman Population Formed from Incandescently Heated Hydrogen Gas with Certain Group I Catalysts”, IEEE Transactions on Plasma Science, in press.

20. R. L. Mills, P. Ray, J. Dong, M. Nansteel, B. Dhandapani, J. He, “Spectral Emission of Fractional-Principal-Quantum-Energy-Level Atomic and Molecular Hydrogen”, Vibrational Spectroscopy, submitted.

21. R. L. Mills, P. Ray, E. Dayalan, B. Dhandapani, J. He, “Comparison of Excessive Balmer α Line Broadening of Inductively and Capacitively Coupled RF, Microwave, and Glow Discharge Hydrogen Plasmas with Certain Catalysts”, IEEE Transactions on Plasma Science, in press.

22. R. M. Mayo, R. Mills, M. Nansteel, “Direct Plasmadynamic Conversion of Plasma Thermal Power to Electricity”, IEEE Transactions on Plasma Science, in press.

23. H. Conrads, R. Mills, Th. Wrubel, “Emission in the Deep Vacuum Ultraviolet from a Plasma Formed by Incandescently Heating Hydrogen Gas with Trace Amounts of Potassium Carbonate”, Plasma Sources Science and Technology, submitted.

24. R. L. Mills, P. Ray, “Stationary Inverted Lyman Population and a Very Stable Novel Hydride Formed by a Catalytic Reaction of Atomic Hydrogen and Certain Catalysts”, International Journal of Engineering Science, submitted.

25. R. L. Mills, A. Voigt, B. Dhandapani, J. He, “Synthesis and Characterization of Lithium Chloro Hydride”, Int. J. Hydrogen Energy, submitted.

26. R. L. Mills, P. Ray, “Substantial Changes in the Characteristics of a Microwave Plasma Due to Combining Argon and Hydrogen”, New Journal of Physics, www.njp.org, Vol. 4, (2002), pp. 22.1-22.17.

27. R. L. Mills, P. Ray, “A Comprehensive Study of Spectra of the Bound-Free Hyperfine Levels of Novel Hydride Ion H⁻(½), Hydrogen, Nitrogen, and Air”, Int. J. Hydrogen Energy, in press.

28. R. L. Mills, E. Dayalan, “Novel Alkali and Alkaline Earth Hydrides for High Voltage and High Energy Density Batteries”, Proceedings of the 17^{th} Annual Battery Conference on Applications and Advances, California State University, Long Beach, Calif., (Jan. 15-18, 2002), pp. 1-6.

29. R. M. Mayo, R. Mills, M. Nansteel, “On the Potential of Direct and MHD Conversion of Power from a Novel Plasma Source to Electricity for Microdistributed Power Applications”, IEEE Transactions on Plasma Science, in press.

30. R. Mills, P. C. Ray, R. M. Mayo, M. Nansteel, W. Good, P. Jansson, B. Dhandapani, J. He, “Stationary Inverted Lyman Populations and Free-Free and Bound-Free Emission of Lower-Energy State Hydride Ion Formed by an Exothermic Catalytic Reaction of Atomic Hydrogen and Certain Group I Catalysts”, Physical Chemistry Chemical Physics, submitted.

31. R. Mills, E. Dayalan, P. Ray, B. Dhandapani, J. He, “Highly Stable Novel Inorganic Hydrides from Aqueous Electrolysis and Plasma Electrolysis”, Electrochimica Acta, Vol. 47, No. 24, (2002), pp. 3909-3926.

32. R. L. Mills, P. Ray, B. Dhandapani, J. He, “Comparison of Excessive Balmer α Line Broadening of Glow Discharge and Microwave Hydrogen Plasmas with Certain Catalysts”, J. of Applied Physics, Jan., 1, (2003).

33. R. L. Mills, P. Ray, B. Dhandapani, J. He, “Emission Spectroscopic Identification of Fractional Rydberg States of Atomic Hydrogen Formed by a Catalytic Helium-Hydrogen Plasma Reaction”, Vacuum, submitted.

34. R. L. Mills, P. Ray, B. Dhandapani, M. Nansteel, X. Chen, J. He, “New Power Source from Fractional Rydberg States of Atomic Hydrogen”, Canadian Journal of Chemistry, submitted.

35. R. L. Mills, P. Ray, B. Dhandapani, M. Nansteel, X. Chen, J. He, “Spectroscopic Identification of Transitions of Fractional Rydberg States of Atomic Hydrogen”, J. of Quantitative Spectroscopy and Radiative Transfer, Vol. 76, No. 1, (2003), pp. 117-130.

36. R. L. Mills, P. Ray, B. Dhandapani, M. Nansteel, X. Chen, J. He, “New Power Source from Fractional Quantum Energy Levels of Atomic Hydrogen that Surpasses Internal Combustion”, J Mol. Struct., Vol. 643, No. 1-3, (2002), pp. 43-54.

37. R. L. Mills, P. Ray, “Spectroscopic Identification of a Novel Catalytic Reaction of Rubidium Ion with Atomic Hydrogen and the Hydride Ion Product”, Int. J. Hydrogen Energy, Vol. 27, No. 9, (2002), pp. 927-935.

38. R. Mills, J. Dong, W. Good, P. Ray, J. He, B. Dhandapani, “Measurement of Energy Balances of Noble Gas-Hydrogen Discharge Plasmas Using Calvet Calorimetry”, Int. J. Hydrogen Energy, Vol. 27, No. 9, (2002), pp. 967-978.

39. R. L. Mills, A. Voigt, P. Ray, M. Nansteel, B. Dhandapani, “Measurement of Hydrogen Balmer Line Broadening and Thermal Power Balances of Noble Gas-Hydrogen Discharge Plasmas”, Int. J. Hydrogen Energy, Vol. 27, No. 6, (2002), pp. 671-685.

40. R. Mills, P. Ray, “Vibrational Spectral Emission of Fractional-Principal-Quantum-Energy-Level Hydrogen Molecular Ion”, Int. J. Hydrogen Energy, Vol. 27, No. 5, (2002), pp. 533-564.

41. R. Mills, P. Ray, “Spectral Emission of Fractional Quantum Energy Levels of Atomic Hydrogen from a Helium-Hydrogen Plasma and the Implications for Dark Matter”, Int. J. Hydrogen Energy, Vol. 27, No. 3, pp. 301-322.

42. R. Mills, P. Ray, “Spectroscopic Identification of a Novel Catalytic Reaction of Potassium and Atomic Hydrogen and the Hydride Ion Product”, Int. J. Hydrogen Energy, Vol. 27, No. 2, (2002), pp. 183-192.

43. R. Mills, “BlackLight Power Technology-A New Clean Hydrogen Energy Source with the Potential for Direct Conversion to Electricity”, Proceedings of the National Hydrogen Association, 12 th Annual U.S. Hydrogen Meeting and Exposition, Hydrogen: The Common Thread, The Washington Hilton and Towers, Washington D.C., (Mar. 6-8, 2001), pp. 671-697.

44. R. Mills, W. Good, A. Voigt, Jinquan Dong, “Minimum Heat of Formation of Potassium Iodo Hydride”, Int. J. Hydrogen Energy, Vol. 26, No. 11, (2001), pp. 1199-1208.

45. R. Mills, “Spectroscopic Identification of a Novel Catalytic Reaction of Atomic Hydrogen and the Hydride Ion Product”, Int. J. Hydrogen Energy, Vol. 26, No. 10, (2001), pp. 1041-1058.

46. R. Mills, N. Greenig, S. Hicks, “Optically Measured Power Balances of Glow Discharges of Mixtures of Argon, Hydrogen, and Potassium, Rubidium, Cesium, or Strontium Vapor”, Int. J. Hydrogen Energy, Vol. 27, No. 6, (2002), pp. 651-670.

47. R. Mills, “The Grand Unified Theory of Classical Quantum Mechanics”, Global Foundation, Inc. Orbis Scientiae entitled The Role of Attractive and Repulsive Gravitational Forces in Cosmic Acceleration of Particles The Origin of the Cosmic Gamma Ray Bursts, (29th Conference on High Energy Physics and Cosmology Since 1964) Dr. Behram N. Kursunoglu, Chairman, Dec. 14-17, 2000, Lago Mar Resort, Fort Lauderdale, Fla., Kluwer Academic/Plenum Publishers, New York, pp. 243-258.

48. R. Mills, “The Grand Unified Theory of Classical Quantum Mechanics”, Int. J. Hydrogen Energy, Vol. 27, No. 5, (2002), pp. 565-590.

49. R. Mills and M. Nansteel, P. Ray, “Argon-Hydrogen-Strontium Discharge Light Source”, IEEE Transactions on Plasma Science, Vol. 30, No. 2, (2002), pp. 639-653.

50. R. Mills, B. Dhandapani, M. Nansteel, J. He, A. Voigt, “Identification of Compounds Containing Novel Hydride Ions by Nuclear Magnetic Resonance Spectroscopy”, Int. J. Hydrogen Energy, Vol. 26, No. 9, (2001), pp. 965-979.

51. R. Mills, “BlackLight Power Technology-A New Clean Energy Source with the Potential for Direct Conversion to Electricity”, Global Foundation International Conference on “Global Warming and Energy Policy”, Dr. Behram N. Kursunoglu, Chairman, Fort Lauderdale, Fla., Nov. 26-28, 2000, Kluwer Academic/Plenum Publishers, New York, pp. 187-202.

52. R. Mills, “The Nature of Free Electrons in Superfluid Helium—a Test of Quantum Mechanics and a Basis to Review its Foundations and Make a Comparison to Classical Theory”, Int. J. Hydrogen Energy, Vol. 26, No. 10, (2001), pp. 1059-1096.

53. R. Mills, M. Nansteel, and Y. Lu, “Excessively Bright Hydrogen-Strontium Plasma Light Source Due to Energy Resonance of Strontium with Hydrogen”, J. of Plasma Physics, in press.

54. R. Mills, J. Dong, Y. Lu, “Observation of Extreme Ultraviolet Hydrogen Emission from Incandescently Heated Hydrogen Gas with Certain Catalysts”, Int. J. Hydrogen Energy, Vol. 25, (2000), pp. 919-943.

55. R. Mills, “Observation of Extreme Ultraviolet Emission from Hydrogen-KI Plasmas Produced by a Hollow Cathode Discharge”, Int. J. Hydrogen Energy, Vol. 26, No. 6, (2001), pp. 579-592.

56. R. Mills, “Temporal Behavior of Light-Emission in the Visible Spectral Range from a Ti—K2CO3-H-Cell”, Int. J. Hydrogen Energy, Vol. 26, No. 4, (2001), pp. 327-332.

57. R. Mills, T. Onuma, and Y. Lu, “Formation of a Hydrogen Plasma from an Incandescently Heated Hydrogen-Catalyst Gas Mixture with an Anomalous Afterglow Duration”, Int. J. Hydrogen Energy, Vol. 26, No. 7, July, (2001), pp. 749-762.

58. R. Mills, M. Nansteel, and Y. Lu, “Observation of Extreme Ultraviolet Hydrogen Emission from Incandescently Heated Hydrogen Gas with Strontium that Produced an Anomalous Optically Measured Power Balance”, Int. J. Hydrogen Energy, Vol. 26, No. 4, (2001), pp. 309-326.

59. R. Mills, B. Dhandapani, N. Greenig, J. He, “Synthesis and Characterization of Potassium Iodo Hydride”, Int. J. of Hydrogen Energy, Vol. 25, Issue 12, December, (2000), pp. 1185-1203.

60. R. Mills, “Novel Inorganic Hydride”, Int. J. of Hydrogen Energy, Vol. 25, (2000), pp. 669-683.

61. R. Mills, B. Dhandapani, M. Nansteel, J. He, T. Shannon, A. Echezuria, “Synthesis and Characterization of Novel Hydride Compounds”, Int. J. of Hydrogen Energy, Vol. 26, No. 4, (2001), pp. 339-367.

62. R. Mills, “Highly Stable Novel Inorganic Hydrides”, Journal of New Materials for Electrochemical Systems, in press.

63. R. Mills, “Novel Hydrogen Compounds from a Potassium Carbonate Electrolytic Cell”, Fusion Technology, Vol. 37, No. 2, March, (2000), pp. 157-182.

64. R. Mills, “The Hydrogen Atom Revisited”, Int. J. of Hydrogen Energy, Vol. 25, Issue 12, December, (2000), pp. 1171-1183.

65. Mills, R., Good, W., “Fractional Quantum Energy Levels of Hydrogen”, Fusion Technology, Vol. 28, No. 4, November, (1995), pp. 1697-1719.

66. Mills, R., Good, W., Shaubach, R., “Dihydrino Molecule Identification”, Fusion Technology, Vol. 25, 103 (1994).

67. R. Mills and S. Kneizys, Fusion Technol. Vol. 20, 65 (1991).

68. R. Mills, The Grand Unified Theory of Classical Quantum Mechanics, September 2001 Edition, BlackLight Power, Inc., Cranbury, N.J., Distributed by Amazon.com; September 2002 Edition posted at www.blacklightpower.com.

69. A. von Engel, Ionized Gases, American Institute of Physics, (1965).

70. M. S. Naidu and V. Kamaraju, High Voltage Engineering, McGraw-Hill, (1996).

71. N. V. Sidgwick, The Chemical Elements and Their Compounds, Volume I, Oxford, Clarendon Press, (1950), p. 17.

72. M. D. Lamb, Luminescence Spectroscopy, Academic Press, London, (1978), p. 68.

73. W. Kern, Semicond. Int., Vol. 7, No. 4, April, (1984), p. 94.

74. F. J. Grunthaner, P. J. Grunthaner, Mater. Sci. Rep., Vol. 1, (1986), p. 69.

75. M. Grudner, H. Jacob, Appl. Phys. A, Vol. 39, (1986), p. 73.

76. H. Ubara, T. Imura, A. Hiraki, Solid State Comm., Vol. 50, (1984), p. 673.

77. E. Yablonovitch, D. L. Allara, C. C. Chang, T. Gmitter, T. B. Bright, Phys. Rev. Lett., Vol. 57, (1986), p. 249.

78. R. A. Street, Hydrogenated amorphous silicon, Cambridge University Press, Cambridge, (1991). pp. 18-61.

79. F. F. Chen, “Electric Probes”, in Plasma Diagnostic Techniques, R. H. Huddleston and S. L. Leonard, Eds., Academic Press, NY, (1965).

80. I. R. Videnovic, N. Konjevic, M. M. Kuraica, “Spectroscopic investigations of a cathode fall region of the Grimm-type glow discharge”, Spectrochimica Acta, Part B, Vol. 51, (1996), pp. 1707-1731.

81. H. R. Griem, Principles of Plasma Spectroscopy, Cambridge University Press, (1997).

82. G. Sultan, G. Baravian, M. Gantois, G. Henrion, H. Michel, A. Ricard, “Doppler-broadened H_{α} line shapes in a dc low-pressure discharge for TiN deposition”, Chemical Physics, Vol. 123, (1988), pp. 423-429.

83. J. Tadic, I. Juranic, G. K. Moortgat, “Pressure dependence of the photooxidation of selected carbonyl compounds in air: n-butanal and n-pentanal”, J. Photochemistry and Photobiology A: Chemistry, Vol. 143, (2000), 169-179.

84. F. C. Fehsenfeld, K. M. Evenson, H. P. Broida, “Microwave discharges operating at 2450 MHz”, Review of Scientific Instruments, Vol. 35, No. 3, (1965), pp. 294-298.

85. B. McCarroll, “An improved microwave discharge cavity for 2450 MHz”, Review of Scientific Instruments, Vol. 41, (1970), p. 279.

86. Microsc. Microanal. Microstruct., Vol. 3, 1, (1992).

87. For recent specifications see PHI Trift II, ToF-SIMS Technical Brochure, (1999), Eden Prairie, Minn. 55344.

88. S. Djurovic, J. R. Roberts, “Hydrogen Balmer alpha line shapes for hydrogen-argon mixtures in low-pressure rf discharge”, J. Appl. Phys. Vol. 74, No. 11, (1993), pp. 6558-6565.

89. S. Alexiou, E. Leboucher-Dalimier, “Hydrogen Balmer-α in dense plasmas”, Phys, Rev. E, Vol. 60, No. 3, (1999), pp. 3436-3438.

90. S. B. Radovanov, K. Dzierzega, J. R. Roberts, J. K. Olthoff, Time-resolved Balmer-alpha emission from fast hydrogen atoms in low pressure, radio-frequency discharges in hydrogen”, Appl. Phys. Lett., Vol. 66, No. 20, (1995), pp. 2637-2639.

91. C. D. Wagner, W. M. Riggs, L. E. Davis, J. F. Moulder, G. E. Mulilenberg (Editor), Handbook of X-ray Photoelectron Spectroscopy, Perkin-Elmer Corp., Eden Prairie, Minn., (1997).

1. A crystalline or amorphous film comprising silicon and
at least one neutral, positive, or negative increased binding energy hydrogen species having a binding energy
(a) greater than the binding energy of the corresponding ordinary hydrogen species, or
(b) greater than the binding energy of any hydrogen species for which the corresponding ordinary hydrogen species is unstable or is not observed because the ordinary hydrogen species' binding energy is less than thermal energies at ambient conditions, or is negative.

2. A compound of claim 1 characterized in that the increased binding energy hydrogen species is selected from the group consisting of Hₙ, Hₙ⁻, and Hₙ⁺ where n is a positive integer, with the proviso that n is greater than 1 when H has a positive charge.

3. A compound of claim 1 characterized in that the increased binding energy hydrogen species is selected from the group consisting of (a) hydride ion having a binding energy that is greater than the binding of ordinary hydride ion (about 0.8 eV) for p=2 up to 23 in which the binding energy is represented by
$$Binding Energy = \frac{ℏ \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} )$$
where p is an integer greater than one, s=½, π is pi, [symbol] is Planck's constant bar, μₒ is the permeability of vacuum, mₑ is the mass of the electron, μₑ is the reduced electron mass given by
$${μ}_{e} = \frac{{m}_{e} {m}_{p}}{\frac{{m}_{e}}{\sqrt{\frac{3}{4}}} + {m}_{p}}$$
where mₚ is the mass of the proton, a_{H} is the radius of the hydrogen atom, aₒ is the Bohr radius, and e is the elementary charge; (b) hydrogen atom having a binding energy greater than about 13.6 eV; (c) hydrogen molecule having a first binding energy greater than about 15.3 eV; and (d) molecular hydrogen ion having a binding energy greater than about 16.3 eV.

4. A compound of claim 3 characterized in that the increased binding energy hydrogen species is a hydride ion having a binding energy of about 3, 6.6, 11.2, 16.7, 22.8, 29.3, 36.1, 42.8, 49.4, 55.5, 61.0, 65.6, 69.2, 71.6, 72.4, 71.6, 68.8, 64.0, 56.8, 47.1, 34.7, 19.3, and 0.69 eV.

5. A compound of claim 4 characterized in that the increased binding energy hydrogen species is a hydride ion having the binding energy:
$$Binding Energy = \frac{ℏ \sqrt{s ( s + 1 )}}{8 {μ}_{e} {{a}_{0}^{2} [ \frac{1 + \sqrt{s ( s + 1 )}}{p} ]}^{2}} - \frac{{πμ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} )$$
where p is an integer greater than one, s=½, π is pi, [symbol] is Planck's constant bar, μₒ is the permeability of vacuum, mₑ is the mass of the electron, μₑ is the reduced electron mass given by
$${μ}_{e} = \frac{{m}_{e} {m}_{p}}{\frac{{m}_{e}}{\sqrt{\frac{3}{4}}} + {m}_{p}}$$
where mₚ is the mass of the proton, a_{H} is the radius of the hydrogen atom, aₒ is the Bohr radius, and e is the elementary charge.

6. A compound of claim 1 characterized in that the increased binding energy hydrogen species is selected from the group consisting of
(a) a hydrogen atom having a binding energy of about
$$\frac{13.6 e V}{{( \frac{1}{p} )}^{2}}$$
where p is an integer,
(b) an increased binding energy hydride ion (H⁻) having a binding energy of about
$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{π {μ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} )$$
where p is an integer greater than one, s=½, π is pi, [symbol] is Planck's constant bar, μₒ is the permeability of vacuum, mₑ is the mass of the electron, μₑ is the reduced electron mass given by
$${μ}_{e} = \frac{{m}_{e} {m}_{p}}{\frac{{m}_{e}}{\sqrt{\frac{3}{4}}} + {m}_{p}}$$
where mₚ is the mass of the proton, a_{H} is the radius of the hydrogen atom, aₒ is the Bohr radius, and e is the elementary charge;
(c) an increased binding energy hydrogen species H₄⁺(1/p);
(d) an increased binding energy hydrogen species trihydrino molecular ion, H₃⁺(1/p), having a binding energy of about
$$\frac{22.6 }{{( \frac{1}{p} )}^{2}} e V$$
where p is an integer,
(e) an increased binding energy hydrogen molecule having a binding energy of about
$$\frac{15.3}{{( \frac{1}{p} )}^{2}} e V ;$$
and
(f) an increased binding energy hydrogen molecular ion with a binding energy of about
$$\frac{16.3 }{{( \frac{1}{p} )}^{2}} e V .$$

7. The compound of claim 1 comprising silicon that is terminated with an increased binding energy hydrogen species.

8. The compound of claim 1 comprising hydrino terminated silicon.

9. The compound of claim 7 comprising silicon that is terminated with
at least one neutral, positive, or negative increased binding energy hydrogen species having a binding energy
(a) greater than the binding energy of the corresponding ordinary hydrogen species, or
(b) greater than the binding energy of any hydrogen species for which the corresponding ordinary hydrogen species is unstable or is not observed because the ordinary hydrogen species' binding energy is less than thermal energies at ambient conditions, or is negative.

10. A compound of claim 7 characterized in that the increased binding energy hydrogen species is selected from the group consisting of Hₙ, Hₙ⁻, and Hₙ⁺ where n is a positive integer, with the proviso that n is greater than 1 when H has a positive charge.

11. A compound of claim 7 characterized in that the increased binding energy hydrogen species is selected from the group consisting of (a) hydride ion having a binding energy that is greater than the binding of ordinary hydride ion (about 0.8 eV) for p=2 up to 23 in which the binding energy is represented by
$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{π {μ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} )$$
where p is an integer greater than one, s=½, π is pi, [symbol] is Planck's constant bar, μₒ is the permeability of vacuum, mₑ is the mass of the electron, μₑ is the reduced electron mass given by
$${μ}_{e} = \frac{{m}_{e} {m}_{p}}{\frac{{m}_{e}}{\sqrt{\frac{3}{4}}} + {m}_{p}}$$
where mₚ is the mass of the proton, a_{H} is the radius of the hydrogen atom, aₒ is the Bohr radius, and e is the elementary charge; (b) hydrogen atom having a binding energy greater than about 13.6 eV; (c) hydrogen molecule having a first binding energy greater than about 15.3 eV; and (d) molecular hydrogen ion having a binding energy greater than about 16.3 eV.

12. A compound of claim 11 characterized in that the increased binding energy hydrogen species is a hydride ion having a binding energy of about 3, 6.6, 11.2, 16.7, 22.8, 29.3, 36.1, 42.8, 49.4, 55.5, 61.0, 65.6, 69.2, 71.6, 72.4, 71.6, 68.8, 64.0, 56.8, 47.1, 34.7, 19.3, and 0.69 eV.

13. A compound of claim 12 characterized in that the increased binding energy hydrogen species is a hydride ion having the binding energy:
$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{π {μ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} )$$
where p is an integer greater than one, s ½, π is pi, [symbol] is Planck's constant bar, μₒ is the permeability of vacuum, mₑ is the mass of the electron, μₑ is the reduced electron mass given by
$${μ}_{e} = \frac{{m}_{e} {m}_{p}}{\frac{{m}_{e}}{\sqrt{\frac{3}{4}}} + {m}_{p}}$$
where mₚ is the mass of the proton, a_{H} is the radius of the hydrogen atom, aₒ is the Bohr radius, and e is the elementary charge.

14. A compound of claim 7 characterized in that the increased binding energy hydrogen species is selected from the group consisting of
(a) a hydrogen atom having a binding energy of about
$$\frac{13.6 e V}{{( \frac{1}{p} )}^{2}}$$
where p is an integer,
(b) an increased binding energy hydride ion (H⁻) having a binding energy of about
$$Binding Energy = \frac{{ℏ}^{2} \sqrt{s ( s + 1 )}}{8 {μ}_{e} {{a}_{0}^{2} [ \frac{1 + \sqrt{s ( s + 1 )}}{p} ]}^{2}} - \frac{π {μ}_{0} {e}^{2} {ℏ}^{2}}{{m}_{e}^{2}} ( \frac{1}{{a}_{H}^{3}} + \frac{{2}^{2}}{{{a}_{0}^{3} [ \frac{1 + \sqrt{s ( s + 1 )}}{p} ]}^{3}} )$$
where p is an integer greater than one, s=½, π is pi, [symbol] is Planck's constant bar, μₒ is the permeability of vacuum, mₑ is the mass of the electron, μₑ is the reduced electron mass given by
$${μ}_{e} = \frac{{m}_{e} {m}_{p}}{\frac{{m}_{e}}{\sqrt{\frac{3}{4}}} + {m}_{p}}$$
where mₚ is the mass of the proton, a_{H} is the radius of the hydrogen atom, aₒ is the Bohr radius, and e is the elementary charge;
(c) an increased binding energy hydrogen species H₄⁺(1/p);
(d) an increased binding energy hydrogen species trihydrino molecular ion, H₃⁺(1/p), having a binding energy of about
$$\frac{22.6 }{{( \frac{1}{p} )}^{2}} e V$$
where p is an integer,
(e) an increased binding energy hydrogen molecule having a binding energy of about
$$\frac{15.3 }{{( \frac{1}{p} )}^{2}} e V ;$$
and
(f) an increased binding energy hydrogen molecular ion with a binding energy of about
$$\frac{16.3}{{( \frac{1}{p} )}^{2}} e V .$$

15. The film of claim 1 coating a substrate.

16. The substrate of claim 15 comprising silicon wafers, metals, plastics, aluminum, some glasses, nickel, steel and electronics materials such as GaAs.

17. A method to form a crystalline or amorphous SiH(1/p) film comprising silicon and
at least one neutral, positive, or negative increased binding energy hydrogen species having a binding energy
(a) greater than the binding energy of the corresponding ordinary hydrogen species, or
(b) greater than the binding energy of any hydrogen species for which the corresponding ordinary hydrogen species is unstable or is not observed because the ordinary hydrogen species' binding energy is less than thermal energies at ambient conditions, or is negative
comprising the steps of
providing a vessel, a source of atomic hydrogen, a catalyst capable of providing a net enthalpy of m·27.2±0.5 eV where m is an integer or m/2·27.2±0.5 eV where m is an integer greater than one, and a source of silicon;
forming atomic hydrogen in the plasma;
reacting the catalyst with the atomic hydrogen to form lower-energy-hydrogen species, and
reacting lower-energy-hydrogen species with silicon from the silicon source.

18. The method of claim 17 wherein the SIH(1/p) forms on a substrate.

19. The method of claim 17 wherein the cell comprises at least of the group of a microwave cell, RF cell, glow discharge cell, barrier electrode, or filament cell.

20. The method of claim 17 wherein the catalyst comprises at least one molecule selected from the group of C₂, N₂, O₂, CO₂, NO₂, and NO₃ or at least one atom, ion, or excimer selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He⁺, Na⁺, Rb⁺, Sr⁺, Fe³⁺, Mo²⁺, Mo⁴⁺, In³⁺, He⁺, Ne⁺, Ar⁺, Xe⁺, H, H(1/p), Ar²⁺ and H⁺, and Ne⁺ and H⁺, Ne₂*, He₂*.

21. The method of claim 17 wherein the cell comprises a plasma cell.

22. A method to form a crystalline or amorphous film comprising silicon and
at least one neutral, positive, or negative increased binding energy hydrogen species having a binding energy
(a) greater than the binding energy of the corresponding ordinary hydrogen species, or
(b) greater than the binding energy of any hydrogen species for which the corresponding ordinary hydrogen species is unstable or is not observed because the ordinary hydrogen species' binding energy is less than thermal energies at ambient conditions, or is negative
comprising the steps of
providing a vessel, a source of atomic hydrogen, a source of microwave power, a catalyst capable of providing a net enthalpy of m·27.2±0.5 eV where m is an integer or m/2·27.2±0.5 eV where m is an integer greater than one, and a source of silicon;
forming a plasma in the vessel with the source of microwave power;
forming atomic hydrogen in the plasma;
reacting the catalyst with the atomic hydrogen to form lower-energy-hydrogen species, and
reacting lower-energy-hydrogen species with silicon from the silicon source.

23. The method of claim 17 wherein the catalyst comprises one or more molecules wherein the energy to break the molecular bond and the ionization of t electrons from an atom from the dissociated molecule to a continuum energy level is such that the sum of the ionization energies of the t electrons is approximately m·27.2±0.5 eV where m is an integer or m/2·27.2±0.5 eV where m is an integer greater than one and t is an integer.

24. The method of claim 23 wherein the catalyst comprises at least one of C₂, N₂, O₂, CO₂, NO₂, and NO₃.

25. The method of claim 17 wherein a catalytic system is provided by the ionization of t electrons from a participating species such as an atom, an ion, a molecule, an ionic or molecular compound, and an excimer to a continuum energy level such that the sum of the ionization energies of the t electrons is approximately m·27.2±0.5 eV where m is an integer or m/2·27.2±0.5 eV where m is an integer greater than one and t is an integer.

26. The method of claim 25 wherein the catalyst is selected from the group of atom, ion, or excimer selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He⁺, Na⁺, Rb⁺, Sr⁺, Fe³⁺, Mo²⁺, Mo⁴⁺, In³⁺, He⁺, Ne⁺, Ar⁺, Xe⁺, H, H(1/p), Ar²⁺ and H⁺, and H⁺, and Ne^{e} and H⁺, Ne₂*, and He₂*.

27. The method of claim 17 wherein the catalyst is provided by the transfer of t electrons between participating ions; the transfer of t electrons from one ion to another ion provides a net enthalpy of reaction whereby the sum of the ionization energy of the electron donating ion minus the ionization energy of the electron accepting ion equals approximately m·27.2±0.5 eV where m is an integer or m/2·27.2±0.5 eV where m is an integer greater than one and t is an integer.

28. The method of claim 17 wherein a catalyst of atomic hydrogen capable of providing a net enthalpy of reaction of m·27.2±0.5 eV where m is an integer or m·27.2±0.5 eV where m is an integer greater than one and capable of forming a hydrogen atom having a binding energy of about
$$\frac{13.6 e V}{{( \frac{1}{p} )}^{2}}$$
where p is an integer wherein the net enthalpy is provided by the breaking of a molecular bond of the catalyst and the ionization of t electrons from an atom of the broken molecule each to a continuum energy level such that the sum of the bond energy and the ionization energies of the t electrons is approximately m/2·27.2±0.5 eV where m is an integer greater than one and t is an integer.

29. The method of claim 28 wherein the catalyst comprises at least one of C₂, N₂, O₂, CO₂, NO₂, and NO₃.

30. The method of claim 17 wherein the catalyst comprises a molecule in combination with an atom, ion, or excimer catalyst.

31. The method of claim 17 wherein a catalyst combination comprises at least one molecule selected from the group of C₂, N₂, O₂, CO₂, NO₂, and NO₃ in combination with at least one atom or ion selected from the group of atom, ion, or excimer selected from the group of Li, Be, K, Ca, Ti, V, Cr, Mn, Fe, Co, Ni, Cu, Zn, As, Se, Kr, Rb, Sr, Nb, Mo, Pd, Sn, Te, Cs, Ce, Pr, Sm, Gd, Dy, Pb, Pt, Kr, He⁺, Na⁺, Rb⁺, Sr⁺, Fe³⁺, Mo²⁺, Mo⁴⁺, In³⁺, He⁺, Ne⁺, Ar⁺, Xe⁺, H, H(1/p), Ar²⁺ and H⁺, and Ne⁺ and H⁺, Ne₂*, and He₂*.

32. The method of claim 17 wherein the cell comprises a microwave gas cell for the catalysis of atomic hydrogen to form increased-binding-energy-hydrogen species and silicon hydride comprising increased-binding-energy-hydrogen species;
the microwave cell comprises a vessel having a chamber capable of containing a vacuum or pressures greater than atmospheric, a source of atomic hydrogen, a source of microwave power to form a plasma, a catalyst capable of providing a net enthalpy of m·27.2±0.5 eV where m is an integer or m/2·27.2±0.5 eV where m is an integer greater than one, and a source of silicon.

33. The method of claim 17 wherein the silicon source comprises at least one of the group of solid silicon, silane, SiₙH₂ₙ₊₂ where 1<n<100, siloxanes, or other silicon containing compounds.

34. The method of claim 17 wherein the silicon or silicon precursor is supplied to the reactor as a solid.

35. The method of claim 34 wherein the solid silicon is placed in the reactor, and the hydrogen catalysis reaction is carried with the silicon present.

36. The method of claim 17 wherein the source of silicon is supplied as a gas from a gas supply line.

37. The method of claim 17 wherein the silicon is vapor deposited on a desired target such as a substrate in the presence of the hydrogen catalysis reaction.

38. The method of claim 17 wherein silicon and silicon precursors such as silanes are supplied to the hydrogen catalysis reaction to form SiH(1/p) by ion implantation, epitaxy, or vacuum deposition.

39. The method of claim 17 wherein the formation of SiH(1/p) films occurs by vapor deposition of silicon in the presence of a catalyst-hydrogen plasma such as a helium-hydrogen plasma or an argon-hydrogen plasma wherein He⁺ or Ar⁺ serves as a catalyst, respectively.

40. The method of claim 17 wherein the catalysis reaction forms increased binding energy hydrogen species which react with the silicon in the gas phase or on a substrate.

41. The method of claim 17 wherein SiH(1/p) films are formed on a substrate by the reaction of silicon from silane, SiₙH₂ₙ₊₂, or a silicon compound with increased binding energy species formed in a helium-hydrogen plasma or an argon-hydrogen plasma wherein He⁺ or Ar⁺ serves as a catalyst, respectively.

42. The method of claim 17 wherein the reaction of silicon with increased binding energy hydrogen species reaction occurs in the gas phase followed by substrate deposition of SiH(1/p), or the silicon or silicon precursors deposit on a substrate followed by reaction with increased binding energy hydrogen species.

43. The method of claim 18 wherein the silicon or silicon precursor deposition rate is in the range of 1 Å/hr to 100 cm/hr.

44. The method of claim 18 wherein the silicon or silicon precursor deposition rate is in the range of 10 Å/hr to 10 cm/hr.

45. The method of claim 18 wherein the silicon or silicon precursor deposition rate is in the range of 100 Å/hr to 1 mm/hr.

46. The method of claim 17 wherein the source of atomic hydrogen is molecular hydrogen and the source of silicon is silicon or a silicon compound.

47. The method of claim 46 wherein the silicon or silicon compound, molecular and atomic hydrogen partial pressures, as well as the catalyst partial pressure is preferably maintained in the range of about 1 mtorr to about 100 atm.

48. The method of claim 46 wherein the silicon or silicon compound, molecular and atomic hydrogen partial pressures, as well as the catalyst partial pressure is preferably maintained in the range of about 100 mtorr to about 1 atm.

49. The method of claim 46 wherein the silicon or silicon compound, molecular and atomic hydrogen partial pressures, as well as the catalyst partial pressure is preferably maintained in the range of about 100 mtorr to about 20 torr.

50. The method of claim 32 wherein the catalyst gas is selected from the group of neon, argon, helium, or mixtures thereof.

51. The method of claim 33 wherein the reaction gas mixture is supplied by flowing and mixing one or more of a catalyst gas, a hydrogen-catalyst gas mixture, a silicon compound gas, a hydrogen-silicon compound gas mixture, a hydrogen-silicon compound-catalyst gas mixture, and a silicon compound-catalyst gas mixture.

52. The method of claim 51 wherein the flow rate of the catalyst gas, hydrogen-catalyst gas mixture, silicon compound gas, hydrogen-silicon compound gas mixture, hydrogen-silicon compound-catalyst gas mixture, or silicon compound-catalyst gas mixture is about 0.0001-1 standard liters per minute per cm³ of vessel volume.

53. The method of claim 51 wherein the flow rate of the catalyst gas, hydrogen-catalyst gas mixture, silicon compound gas, hydrogen-silicon compound gas mixture, hydrogen-silicon compound-catalyst gas mixture, or silicon compound-catalyst gas mixture is about 0.001-10 sccm per cm³ of vessel volume.

54. The method of claim 51 wherein the flow rate of the catalyst gas, hydrogen-catalyst gas mixture, silicon compound gas, hydrogen-silicon compound gas mixture, hydrogen-silicon compound-catalyst gas mixture, or silicon compound-catalyst gas mixture is about 0.1-10 sccm per cm³ of vessel volume.

55. The method of claim 51 wherein the silicon or silicon compound gas is the molar percentage composition range of about 0.01-99% and the balance is due to catalyst-hydrogen gas mixture which is present in the relative amounts that achieves hydrogen catalysis.

56. The method of claim 51 wherein the silicon or silicon compound gas is in the molar percentage composition range of about 0.1-10% and the balance is due to catalyst-hydrogen gas mixture which is present in the relative amounts that achieves hydrogen catalysis.

57. The method of claim 51 wherein the silicon or silicon compound gas is in the range of about 0.5-5% and the balance is due to catalyst-hydrogen gas mixture which is present in the relative amounts that achieves hydrogen catalysis.

58. The method of claims 55-57 wherein the catalyst-hydrogen gas mixture added to the silicon or silicon compound gas comprises a catalyst gas molar percentage composition range of about 0.01 to 99.90%, and the balance is hydrogen.

59. The method of claims 55-57 wherein the catalyst-hydrogen gas mixture added to the silicon or silicon compound gas comprises a catalyst gas molar percentage composition range of about 10 to 99.9%, and the balance is hydrogen.

60. The method of claims 55-57 wherein the catalyst-hydrogen gas mixture added to the silicon or silicon compound gas comprises a catalyst gas molar percentage composition range of about 50 to 99.9%, and the balance is hydrogen.

61. The method of claim 50 wherein the flow rates per 10 cm of plasma reaction volume are about 0.1-100 standard cubic centimeters per minute (sccm) hydrogen, about 0.1-100 sccm silane, and about 10-1000 sccm helium, neon, or argon, with an microwave input power of about 10-500 W and a pressure range in the range of about 10 mTorr-10 Torr.

62. The method of claim 46 comprising a silane-helium-hydrogen mixture, silane-neon-hydrogen mixture, or silane-argon-hydrogen, wherein helium, neon, or argon is in the mole percentage range of about 50 to about 99%, and hydrogen and silane make up the balance.

63. The method of claim 46 comprising a silane-helium-hydrogen mixture, silane-neon-hydrogen mixture, or silane-argon-hydrogen, wherein helium, neon, or argon is in the mole percentage range of about 80 to about 99%, and hydrogen and silane make up the balance.

64. The method of claim 46 wherein the reaction mixture comprises a plasma.

65. The method of claim 64 wherein the plasma mixture comprises SiH₄ (0.1-5%)/He (90-99.8%)/H₂ (0.1-5%).

66. The method of claim 64 wherein the plasma mixture comprises SiH₄ (0.1-5%)/Ne (90-99.8%)/H₂ (0.1-5%).

67. The method of claim 64 wherein the plasma mixture comprises SiH₄ (0.1-5%)/Ar (90-99.8%)/H₂ (0.1-5%).

68. The method of claim 64 wherein the plasma is formed by the input of power.

69. The method of claim 68 wherein the power density of the source of plasma power is preferably in the range of about 0.01 W to about 100 W/cm³ vessel volume.

70. The method of claim 64 wherein the flow rate of the plasma gas mixture is in the range of about 0.1-50 sccm per cm³ of vessel volume.

71. The method of claim 64 wherein the pressure range is about 10 mTorr-10 Torr.

72. The method of claim 64 wherein the substrate is silicon wafers, metals, plastics, aluminum, some glasses, nickel, steel and electronics materials such as GaAs

73. The method of claim 72 wherein the substrate is coated by placing the substrate in the reactor during SiH(1/p) formation such that the SiH(1/p) material is deposited onto the substrate.

74. The method of claim 64 wherein the plasma is a catalyst-hydrogen plasma.

75. The method of claim 68 wherein the plasma cell is a microwave cell, RF cell, glow discharge cell, barrier electrode, or filament cell.

76. The method of claim 75 wherein the source of silicon is by sputter vapor deposition from a solid source by the plasma of the microwave cell, RF cell, glow discharge cell, or a barrier electrode cell.

77. The method of claim 75 wherein silicon is vapor deposited in the presence of a neon-hydrogen plasma, helium-hydrogen plasma, or an argon-hydrogen plasma wherein Ne⁺, He⁺, or Ar⁺ serves as a catalyst, respectively.

78. The method of claim 33 wherein the silicon compound is Si₃ H₈.

79. The method of claim 33 wherein the silicon compound is disilane.

80. The method of claim 33 wherein the silicon compound is silane.

81. The method of claim 64 wherein SiH₄ gas is introduced into a reservoir by a gas/vacuum line where it is mixed with premixed He (95-99.9%)/H₂ (0.1-5%) to obtain the reaction mixture SiH₄ (0.1-5%)/He (90-99.8%)/H₂ (0.1-5%) by controlling the individual gas pressures.

82. The method of claim 64 wherein the SiH₄ gas is introduced into a reservoir by a gas/vacuum line where it was mixed with premixed He (99%)/H₂ (1%) to obtain the reaction mixture SiH₄ (2.5%)/He (96.6%)/H₂ (0.9%) by controlling the individual gas pressures.

83. The method of claim 64 wherein SiH₄ gas is introduced into a reservoir by a gas/vacuum line where it is mixed with premixed Ne (95-99.9%)/H₂ (0.1-5%) to obtain the reaction mixture SiH₄ (0.1-5%)/Ne (90-99.8%)/H₂ (0.1-5%) by controlling the individual gas pressures.

84. The method of claim 64 wherein the SiH₄ gas is introduced into a reservoir by a gas/vacuum line where it was mixed with premixed Ne (99%)/H₂ (1%) to obtain the reaction mixture SiH₄ (2.5%)/Ne (96.6%)/H₂ (0.9%) by controlling the individual gas pressures.

85. The method of claim 64 wherein SiH₄ gas is introduced into a reservoir by a gas/vacuum line where it is mixed with premixed Ar (95-99.9%)/H₂ (0.1-5%) to obtain the reaction mixture SiH₄ (0.1-5%)/Ar (90-99.8%)/H₂ (0.1-5%) by controlling the individual gas pressures.

86. The method of claim 64 wherein the SiH₄ gas is introduced into a reservoir by a gas/vacuum line where it was mixed with premixed Ar (99%)/H₂ (1%) to obtain the reaction mixture SiH₄ (2.5%)/Ar (96.6%)/H₂ (0.9%) by controlling the individual gas pressures.

87. The method of claim 22 wherein the microwave cell comprises a vessel comprising a cavity that is an Evenson microwave cavity and the source of microwave power excites a plasma in the Evenson cavity.

88. The method of claim 22 wherein the microwave cell comprises a vessel comprising a cavity that is a Beenakker, McCarrol, or cylindrical microwave cavity and the source of microwave power excites a plasma in the cavity.

89. The method of claim 22 wherein the microwave frequency of the source of microwave power is in the range of 1 MHz to 100 GHz.

90. The method of claim 22 wherein the microwave frequency of the source of microwave power is in the range of 50 MHz to 10 GHz.

91. The method of claim 22 wherein the microwave frequency of the source of microwave power is in the range of 75 MHz±50 MHz.

92. The method of claim 22 wherein the microwave frequency of the source of microwave power is in the range of 2.4 GHz±1 GHz.

93. The method of claim 22 further comprising the step of collecting SiH(1/p) in a trap.

94. The method of claim 93 further comprising the step of maintaining a pressure gradient from the vessel to the trap to cause gas flow and transport of the lower-energy hydrogen species or lower-energy hydrogen compound.

95. The method for producing SiH(1/p) of claim 17 further comprising the steps of flowing a plasma gas that is a source of catalyst into the vessel.

96. The method for controlling the rate of reaction of claim 17 comprising the step of controlling the amount of gaseous catalyst.

97. The method for controlling the amount of gaseous catalyst of claim 96 comprising the step of controlling the plasma gas flow rate.

98. The method for controlling the rate of reaction of claim 17 comprising the step of controlling the amount of hydrogen.

99. The method for controlling the rate of reaction of claim 98 comprising the step of controlling the flow of hydrogen from the source of hydrogen.

100. The method for controlling the rate of reaction of claim 98 comprising the step of controlling the flow of hydrogen, catalyst, source of silicon, and the molar ratio of the reactants in a mixture.

101. A method of controlling the reaction rate of claim 100 by controlling the hydrogen flow rate, catalyst gas flow rate, and source of silicon gas flow rate with at least one of the group of a flow regulator, a gas mixer, flow rate controllers, and valves.

102. The method of controlling the reaction rate of claim 22 by controlling the temperature of the plasma with the power supplied by the source of microwave power.

103. The method of claim 17 further comprising the steps of providing a source of catalyst from a catalyst reservoir.

104. The method of providing a source of catalyst from a catalyst reservoir of claim 103 comprising the steps of controlling the temperature of the catalyst from a catalyst reservoir to control its vapor pressure.

105. The method of claim 17 further comprising the steps of providing a source of catalyst from a catalyst boat.

106. The method of providing a source of catalyst from a catalyst boat of claim 105 comprising the steps of controlling the temperature of the catalyst from a catalyst boat to control its vapor pressure.

107. The method of claim 18 wherein the substrate temperature is maintained in the range of about 0-3000° C.

108. The method of claim 18 wherein the substrate temperature is maintained in the range of about 100-1000° C.

109. The method of claim 18 wherein the substrate temperature is maintained in the range of about 100-500° C.
